(19) United States
(12) Patent Application Publication
(10) Pub. No.: US 2020/0159118 A1
(43) Pub. Date: May 21, 2020

(54) RESIST COMPOSITION AND METHOD OF FORMING RESIST PATTERN

(71) Applicant: TOKYO OHKA KOGYO CO., LTD., Kawasaki-shi (JP)

(72) Inventors: Tatsuya FUJII, Kawasaki-shi (JP); Yuki FUKUMURA, Kawasaki-shi (JP); Masahito YAHAGI, Kawasaki-shi (JP); Yoichi HORI, Kawasaki-shi (JP)

(21) Appl. No.: 16/678,136

(22) Filed: Nov. 8, 2019

(30) Foreign Application Priority Data
Nov. 15, 2018 (JP) 2018-214307

(51) Int. Cl. G03F 7/039; G03F 7/20; C08L 33/14; C08L 33/26

(52) U.S. Cl. CPC G03F 7/0397; G03F 7/2004; C08L 33/26; C08L 33/14; G03F 7/2059

(57) ABSTRACT

A resist composition including a structural unit represented by General Formula (a0-1), a structural unit represented by General Formula (a0-2), and a structural unit represented by General Formula (a0-3); in the Formula (a0-1), Rx⁰¹ is an acid dissociable group represented by General Formula (a01-r-1) or General Formula (a01-r-2) in Formula (a01-r-1) and Formula (a01-r-2), Xa and Ya, and Xaa and Yaa are groups that together form an aliphatic cyclic group having 3 to 5 carbon atoms; in Formula (a0-2), R¹ is a fluorinated alkyl group; in Formula (a0-3), Wa^{x3} is an aromatic hydrocarbon group.

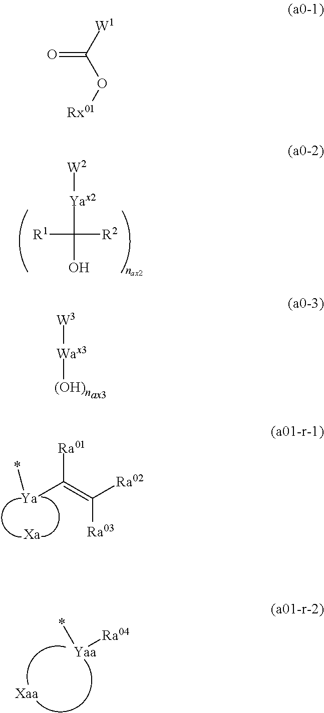

### BACKGROUND OF THE INVENTION

### Field of the Invention

The present invention relates to a resist composition and a method of forming a resist pattern.

Priority is claimed on Japanese Patent Application No. 2018-214307, filed on Nov. 15, 2018, the content of which is incorporated herein by reference.

### Description of Related Art

In lithography techniques, for example, a resist film formed of a resist material is formed on a substrate, and the resist film is subjected to selective exposure, followed by a development treatment, thereby forming a resist pattern having a predetermined shape on the resist film. A resist material in which exposed portions of a resist film change its characteristics to be soluble in a developing solution is called a positive tone, and a resist material in which exposed portions thereof change its characteristics to be insoluble in a developing solution is called a negative tone.

In recent years, in the production of semiconductor elements and liquid crystal display elements, advances in lithography techniques have led to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used. Currently, mass production of semiconductor elements using a KrF excimer laser or an ArF excimer laser has been started. In addition, studies have been made on extreme ultraviolet (EUV) rays, electron beams (EB), X-rays, and the like which have shorter wavelengths (higher energy) than those of these excimer lasers.

In resist materials, acid diffusion control has been a problem particularly in EUV exposure. In order to control acid diffusion, it is common to change an anion structure of an acid generator, and an acid generator having an anion structure in which a diffusion length of acid is short is applied.

In order to further control acid diffusion, a method of variously changing a design of a polymer compound has been adopted.

For example, Japanese Unexamined Patent Application, First Publication No. 2009-114381 discloses a resist composition that employs a specific polymer compound having a high acid-dissociable ability to improve reactivity with respect to an acid.

### SUMMARY OF THE INVENTION

In a case where a design of a polymer compound in a resist composition is changed variously to control acid diffusion, a structure having a norbornene group or an adamantyl group can be taken into consideration. However, in a case where structural units or protecting groups having these structures are introduced, the hydrophobicity is improved, and the dissolution rate of the exposed portion is lowered. Furthermore, the solubility in the developing solution is lowered, so that the resolution performance is reduced. There has been a problem of causing deterioration and deterioration of LWR.

The present invention has been made in the viewpoint of the above circumstances, and an object of the present invention is to provide a resist composition having an excellent sensitivity, roughness reduction performance, and resolution performance, and a method of forming a resist pattern.

In order to achieve the above-mentioned object, the present invention employs the following configuration.

That is, a first aspect of the present invention is a resist composition which generates an acid upon exposure and changes solubility thereof in a developing solution due to an action of the acid, the resist composition including a resin component (A1) that changes solubility thereof in the developing solution by the action of the acid, in which the resin component (A1) has a structural unit (a01) obtained from a compound represented by General Formula (a0-1), in which a polymerizable group at a W¹ moiety is converted into a main chain; a structural unit (a02) obtained from a compound represented by General Formula (a0-2), in which a polymerizable group at a W² moiety is converted into a main chain; and a structural unit (a03) obtained from a compound represented by General Formula (a0-3), in which a polymerizable group at a W³ moiety is converted into a main chain.

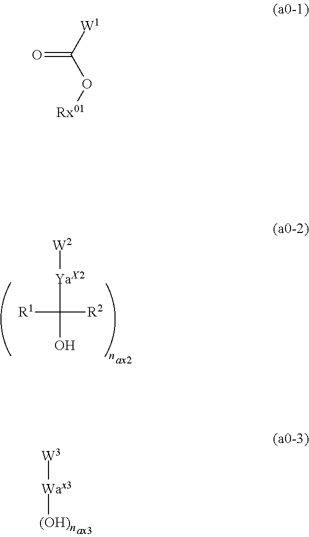

[In Formula (a0-1), W¹ is a polymerizable-group-containing group, and Rx⁰¹ is an acid dissociable group represented by General Formula (a01-r-1) or General Formula (a01-r-2); in Formula (a0-2), W² is a polymerizable-group-containing group, Ya^{x2} is a single bond or an (nₐₓ₂+1)-valent linking group, Ya^{x2} and W² may form a fused ring, R¹ is a fluorinated alkyl group having 1 to 12 carbon atoms, R² is a hydrogen atom or an organic group having 1 to 12 carbon atoms which may have a fluorine atom, and nₐₓ₂ is an integer of 1 to 3; and in Formula (a0-3), W³ is a polymerizable-group-containing group, Wa^{x3} is an (nₐₓ₃+1)-valent aromatic hydrocarbon group which may have a substituent, Wa^{x3} and W³ may form a fused ring, and nₐₓ₃ is an integer of 1 to 3.]

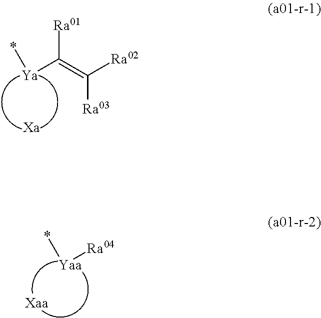

[In Formula (a01-r-1), Ya represents a carbon atom. Xa is a group that forms an aliphatic cyclic group together with Ya. Some or all of hydrogen atoms included in the aliphatic cyclic group may be substituted. Here, the aliphatic cyclic group to be formed by Xa and Ya is an aliphatic monocyclic group having 3 to 5 carbon atoms. Ra⁰¹ to Ra⁰³ each independently represent a hydrogen atom, a chain-like monovalent saturated hydrocarbon group having 1 to 10 carbon atoms, or a monovalent aliphatic cyclic saturated hydrocarbon group having 3 to 20 carbon atoms. Some or all hydrogen atoms in the chain-like saturated hydrocarbon group and the aliphatic cyclic saturated hydrocarbon group may be substituted. Two or more of Ra⁰¹ to Ra⁰³ may be bonded to one another to form an aliphatic cyclic structure. In Formula (a01-r-2), Yaa represents a carbon atom. Xaa represents a group that forms an aliphatic cyclic group together with Yaa. Some or all of hydrogen atoms included in the aliphatic cyclic group may be substituted. Here, the aliphatic cyclic group to be formed by Xaa and Yaa is an aliphatic monocyclic group having 3 to 5 carbon atoms. Ra⁰⁴ represents an aromatic hydrocarbon group which may have a substituent. The symbol “*” represents a bonding site.]

A second aspect of the present invention is a method of forming a resist pattern, the method including a step of forming a resist film on a support using the resist composition according to the first aspect; a step of exposing the resist film; and a step of developing the exposed resist film to form a resist pattern.

According to the resist composition of the present invention, it is possible to form a resist pattern having an excellent sensitivity, roughness reduction performance, and resolution performance.

### DETAILED DESCRIPTION OF THE INVENTION

In the present specification and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies to the alkyl group in an alkoxy group.

The term “alkylene group” includes linear, branched or cyclic, divalent saturated hydrocarbon, unless otherwise specified.

A “halogenated alkyl group” is a group in which some or all hydrogen atoms of an alkyl group is substituted with halogen atoms. Examples of the halogen atom include a fluorine atom, a chlorine atom, a bromine atom and an iodine atom.

A “fluorinated alkyl group” or a “fluorinated alkylene group” is a group in which some or all hydrogen atoms of an alkyl group or an alkylene group have been substituted with fluorine atoms.

The term “structural unit” indicates a monomer unit that contributes to the formation of a polymer compound (a resin, a polymer, or a copolymer).

The expression “may have a substituent” indicates a case where a hydrogen atom (—H) is substituted with a monovalent group or a case where a methylene (—CH₂—) group is substituted with a divalent group.

The term “exposure” is used as a general concept that includes irradiation with any form of radiation.

A “structural unit derived from acrylic acid ester” indicates a structural unit that is formed by the cleavage of the ethylenic double bond of acrylic acid ester.

The “acrylic acid ester” indicates a compound in which the terminal hydrogen atom of the carboxy group of acrylic acid (CH₂═CH—COOH) has been substituted with an organic group.

The acrylic acid ester may have the hydrogen atom bonded to the carbon atom at the α-position substituted with a substituent. The substituent (Ra⁰) that substitutes the hydrogen atom bonded to the carbon atom at the α-position is an atom other than hydrogen atom or a group, and examples thereof include an alkyl group having 1 to 5 carbon atoms and a halogenated alkyl group having 1 to 5 carbon atoms. Further, acrylic acid ester having the hydrogen atom bonded to the carbon atom at the α-position substituted with a substituent (Ra⁰) in which the substituent has been substituted with a substituent containing an ester bond (itaconic acid diester), or an acrylic acid having the hydrogen atom bonded to the carbon atom at the α-position substituted with a substituent (Ra⁰) in which the substituent has been substituted with a hydroxyalkyl group or a group in which the hydroxyl group in a hydroxyalkyl group has been modified (α-hydroxyalkyl acrylic acid ester) can be exemplified as acrylic acid ester having the hydrogen atom bonded to the carbon atom at the α-position substituted with a substituent. A carbon atom at the α-position of acrylic acid ester indicates the carbon atom bonded to the carbonyl group, unless specified otherwise.

Hereinafter, acrylic acid ester in which the hydrogen atom bonded to the carbon atom at the α-position is substituted with a substituent is also referred to as α-substituted acrylic acid ester. Further, acrylic acid ester and α-substituted acrylic acid ester are also collectively referred to as “(α-substituted) acrylic acid ester”.

A “structural unit derived from acrylamide” indicates a structural unit that is formed by the cleavage of the ethylenic double bond of acrylamide.

The acrylamide may have the hydrogen atom bonded to the carbon atom at the α-position substituted with a substituent, and may have either or both terminal hydrogen atoms on the amino group of acrylamide substituted with a substituent. A carbon atom at the α-position of an acrylamide indicates the carbon atom bonded to the carbonyl group of acrylamide, unless specified otherwise.

As the substituent which substitutes the hydrogen atom bonded to the carbon atom at the α-position of acrylamide, the same substituents as those described above for the substituent (Ra⁰) at the α-position of the above-described α-position of the above-described α-substituted acrylic acid ester can be exemplified.

A “structural unit derived from hydroxystyrene” indicates a structural unit that is formed by the cleavage of the ethylenic double bond of hydroxystyrene. A “structural unit derived from hydroxystyrene derivatives” indicates a structural unit that is formed by the cleavage of the ethylenic double bond of hydroxystyrene derivatives.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxyl group has been substituted with an organic group and may have the hydrogen atom at the α-position substituted with a substituent; and hydroxystyrene which has a substituent other than a hydroxyl group bonded to the benzene ring and may have the hydrogen atom at the α-position substituted with a substituent. Here, the α-position (carbon atom at the α-position) indicates the carbon atom having the benzene ring bonded thereto, unless specified otherwise.

As the substituent which substitutes the hydrogen atom at the α-position of hydroxystyrene, the same substituents as those described above for the substituent at the α-position of the above-described α-substituted acrylic acid ester can be exemplified.

A “structural unit derived from vinylbenzoic acid or a vinylbenzoic acid derivative” indicates a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include vinylbenzoic acid in which the hydrogen atom of the carboxy group has been substituted with an organic group and may have the hydrogen atom at the α-position substituted with a substituent; and vinylbenzoic acid which has a substituent other than a hydroxyl group and a carboxy group bonded to the benzene ring and may have the hydrogen atom at the α-position substituted with a substituent. Here, the α-position (carbon atom at the α-position) indicates the carbon atom having the benzene ring bonded thereto, unless specified otherwise.

The term “styrene derivative” is a concept including those obtained by substitution of a hydrogen atom at the α-position of styrene with other substituents such as an alkyl group and a halogenated alkyl group; and these derivatives. Examples of these derivatives include those obtained by bonding a substituent to a benzene ring of hydroxystyrene in which a hydrogen atom at the α-position may be substituted with a substituent. Here, the α-position (carbon atom at the α-position) indicates the carbon atom having the benzene ring bonded thereto, unless specified otherwise.

The term “structural unit derived from styrene” or “structural unit derived from a styrene derivative” indicates a structural unit formed by cleavage of an ethylenic double bond of styrene or a styrene derivative.

As the alkyl group as a substituent at the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group as the substituent at the α-position include groups in which some or all hydrogen atoms of the above-described “alkyl group as the substituent at the α-position” are substituted with halogen atoms. Examples of the halogen atom include a fluorine atom, a chlorine atom, a bromine atom and an iodine atom, and a fluorine atom is particularly preferable.

Specific examples of the hydroxyalkyl group as the substituent at the α-position include groups in which some or all hydrogen atoms of the above-described “alkyl group as the substituent at the α-position” are substituted with a hydroxyl group. The number of hydroxyl groups in the hydroxyalkyl group is preferably 1 to 5, and most preferably 1.

In the present specification and the scope of claims of the present patent application, depending on structures represented by Chemical Formulae, an asymmetric carbon, and an enantiomer or diastereomer may be present. In this case, these isomers are represented by one chemical formula. These isomers may be used alone or in the form of a mixture.

(Resist Composition)

The resist composition according to the first aspect of the present invention generates an acid upon exposure, changes its solubility in a developing solution due to the action of the acid, and includes a base material component (A) that changes its solubility in the developing solution by the action of the acid (hereinafter referred to as the “component (A)”).

As one embodiment of the resist composition, a resist composition containing the component (A), and an acid generator component (B) that generates an acid upon exposure (hereinafter referred to as a “component (B)”) is exemplified. A resist composition further containing, in addition to the component (A) and the component (B), a base component that traps an acid (that is, controls diffusion of an acid) which is generated from the component (B) upon exposure (hereinafter referred to as the “component (D)”) is preferably exemplified.

In the resist composition of the present embodiment, the component (A1) includes a resin component (A1) (hereinafter referred to as the “component (A1)”) has a structural unit (a01), in which a polymerizable group at a W¹ moiety is converted into a main chain, in a compound represented by General Formula (a0-1); a structural unit (a02), in which a polymerizable group at a W² moiety is converted into a main chain, in a compound represented by General Formula (a0-2); and a structural unit (a03), in which a polymerizable group at a W³ moiety is converted into a main chain, in a compound represented by General Formula (a0-3).

In a case where a resist film is formed using the resist composition according to the present embodiment and the formed resist film is subjected to a selective exposure, for example, acid is generated from the component (B) at exposed portions of the resist film, and the generated acid acts on the component (A) to change the solubility of the component (A) in a developing solution, whereas the solubility of the component (A) in a developing solution is not changed at unexposed portions of the resist film, thereby generating difference in solubility in a developing solution between exposed portions and unexposed portions. Therefore, by subjecting the resist film to development, the exposed portions of the resist film are dissolved and removed to form a positive tone resist pattern in a case of a positive tone resist composition, whereas the unexposed portions of the resist film are dissolved and removed to form a negative tone resist pattern in a case of a negative tone resist composition.

In the present specification, a resist composition which forms a positive tone resist pattern by dissolving and removing the exposed portions of the resist film is called a positive tone resist composition, and a resist composition which forms a negative tone resist pattern by dissolving and removing the unexposed portions of the resist film is called a negative tone resist composition.

The resist composition of the present embodiment may be a positive tone resist composition or a negative tone resist composition. Further, in the formation of a resist pattern, the resist composition according to the present embodiment may be applied to an alkali developing process using an alkali developing solution in the developing treatment, or a solvent developing process using a developing solution containing an organic solvent (organic developing solution) in the developing treatment.

The resist composition of the present embodiment has an acid generating ability capable of generating an acid upon exposure, and in addition to the component (B), the component (A) may generate an acid upon exposure.

In a case where the component (A) generates an acid upon exposure, this the component (A) is a “base material component that generates an acid upon exposure and changes its solubility in a developing solution due to the action of the acid.”

In a case where the component (A) is the base material component that generates an acid upon exposure and changes its solubility in a developing solution due to the action of the acid, the above-described component (A1) is preferably a polymer compound that generates an acid upon exposure and changes its solubility in a developing solution due to the action of an acid. Examples of such a polymer compound include a resin having a structural unit that generates an acid upon exposure. As a monomer deriving a structural unit that generates an acid by exposure, a well-known monomer can be used.

<Component (A)>

In the resist composition of the present embodiment, the component (A) is the base material component that changes its solubility in a developing solution due to the action of an acid, and includes the above-described component (A1). By using the component (A1), because a polarity of the base material component changes before and after exposure, a favorable development contrast can be obtained not only in an alkali developing process but also in a solvent developing process.

In a case of applying the alkali developing process, the base material component containing the component (A1) is hardly soluble in an alkali developing solution before exposure. For example, in a case where an acid is generated from the component (B) upon exposure, a polarity increases due to the action of the acid, and thereby a solubility in the alkali developing solution increases. For this reason, in formation of a resist pattern, in a case where a resist film obtained by applying the resist composition on a support is selectively exposed, an exposed portion of the resist film changes its state from a poorly-soluble state to a soluble state in an alkali developing solution, whereas an unexposed portion of the resist film does not change its state from a poorly-soluble state in an alkali developing solution. Accordingly, a positive tone resist pattern is formed by alkali development.

Meanwhile, in a case of applying the solvent developing process, the base material component containing the component (A1) is highly soluble in an organic developing solution before exposure. For example, in a case where an acid is generated from the component (B) upon exposure, a polarity increases due to the action of the acid, and thereby a solubility in the organic developing solution decreases. For this reason, in formation of a resist pattern, in a case where a resist film obtained by applying the resist composition on a support is selectively exposed, an exposed portion of the resist film changes its state from a soluble state to a poorly-soluble state in an organic developing solution, whereas an unexposed portion of the resist film does not change its state from a soluble state. Accordingly, by developing with an organic developing solution, a contrast can be provided between the exposed portion and the unexposed portion, and thereby a negative tone resist pattern is formed.

In the resist composition of the present embodiment, one kind of the component (A) may be used alone, or two or more kinds thereof may be used in combination.

In Regard to Component (A1)

The component (A1) is a resin component having a structural unit (a01), in which a polymerizable group at a W¹ moiety is converted into a main chain, in a compound represented by General Formula (a0-1); a structural unit (a02), in which a polymerizable group at a W² moiety is converted into a main chain, in a compound represented by General Formula (a0-2); and a structural unit (a03), in which a polymerizable group at a W³ moiety is converted into a main chain, in a compound represented by General Formula (a0-3).

In addition, the component (A1) may have other structural units as necessary in addition to the structural unit (a01), the structural unit (a02), and the structural unit (a03).

<<Structural Unit (a01)>>

The structural unit (a01) is a structural unit, in which a polymerizable group at a W¹ moiety is converted into a main chain, in a compound represented by General Formula (a0-1).

In the structural unit (a01), Rx⁰¹ in Formula (a0-1) is an acid dissociable group, and this acid dissociable group protects an oxy group (—O—) side of a carbonyloxy group [—C(═O)—O—] in Formula (a0-1).

The “acid dissociable group” referred herein has an acid-dissociable ability that can cleave the bond between the acid dissociable group and an oxygen atom (0) adjacent to the acid dissociable group due to the action of an acid. In a case where the acid dissociable group is dissociated due to the action of an acid, a polar group having a polarity higher than that of the acid dissociable group is generated, and thereby a polarity increases.

As a result, the polarity of the entire component (A1) is increased. By the increase in the polarity, relatively, the solubility in a developing solution changes, and the solubility in an alkali developing solution is increased, whereas the solubility in an organic developing solution is relatively decreased.

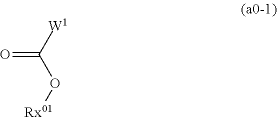

[In Formula (a0-1), W¹ is a polymerizable-group-containing group, and Rx⁰¹ is an acid dissociable group represented by General Formula (a01-r-1) or General Formula (a01-r-2).]

In Formula (a0-1), W¹ is a polymerizable-group-containing group.

The “polymerizable group” at the W¹ moiety is a group that allows a compound having a polymerizable group to be polymerized by radical polymerization or the like, and it refers to, for example, a group having a multiple bond between carbon atoms, such as an ethylenic double bond.

The phrase “polymerizable group being converted into a main chain” means that a multiple bond in the polymerizable group is cleaved to form the main chain. For example, in a case of a monomer having an ethylenic double bond, the phrase means that an ethylenic double bond is cleaved, and a single bond between carbon atoms forms a main chain.

Examples of polymerizable groups at the W¹ moiety include a vinyl group, an allyl group, an acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, a vinyl naphthyl group, a fluorine-containing styryl group, a fluorine-containing vinyl naphthyl group, a norbomenyl group, a fluorine-containing norbomenyl group, a silyl group, and the like.

The polymerizable-group-containing group may be a group composed only of a polymerizable group, or may be a group composed of a polymerizable group and a group other than the polymerizable group. Examples of groups other than the polymerizable group include a divalent hydrocarbon group which may have a substituent, a divalent linking group containing a hetero atom, and the like.

Preferable examples of W¹'s include a group represented by the chemical formula: C(R^{X11})(R^{X12})═C(R^{X13})-Ya^{x0}-.

In this chemical formula, R^{X11}, R^{X12}, and R^{X13} are each a hydrogen atom, an alkyl group having 1 to 5 carbon atoms, or a halogenated alkyl group having 1 to 5 carbon atoms, and Ya^{x0} is a single bond or a divalent linking group.

In the above chemical formula, an alkyl group having 1 to 5 carbon atoms in Rx^{X11}, R^{X12}, and R^{X13} is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms of the above-described alkyl group having 1 to 5 carbon atoms have been substituted with halogen atoms. Examples of the halogen atom include a fluorine atom, a chlorine atom, a bromine atom and an iodine atom, and a fluorine atom is particularly preferable.

Among them, R^{X11} and R^{X12} each respectively are preferably a hydrogen atom and an alkyl group having 1 to 5 carbon atoms or a fluorinated alkyl group having 1 to 5 carbon atoms, more preferably a hydrogen atom or a methyl group, and particularly preferably a hydrogen atom, from the viewpoint of industrial availability.

In addition, R^{X13} represents preferably a hydrogen atom, an alkyl group having 1 to 5 carbon atoms, or a fluorinated alkyl group having 1 to 5 carbon atoms, and more preferably a hydrogen atom or a methyl group from the viewpoint of industrial availability.

In the above chemical formula, the divalent linking group in Ya^{x0} is not particularly limited, and preferable examples thereof include a divalent hydrocarbon group which may have a substituent, a divalent linking group having hetero atoms, and the like.

Divalent Hydrocarbon Group which May have a Substituent:

In a case where Ya^{x0} represents a divalent hydrocarbon group which may have a substituent, the hydrocarbon group may be an aliphatic hydrocarbon group or an aromatic hydrocarbon group.

Aliphatic Hydrocarbon Group as Ya^{x0}

The aliphatic hydrocarbon group indicates a hydrocarbon group that has no aromaticity. The aliphatic hydrocarbon group may be saturated or unsaturated. In general, the aliphatic hydrocarbon group is preferably saturated.

Examples of the aliphatic hydrocarbon group include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable.

Specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

As the branched aliphatic hydrocarbon group, a branched alkylene group is preferred, and specific examples include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group in the alkylalkylene group, a linear alkyl group having 1 to 5 carbon atoms is preferable.

The linear or branched aliphatic hydrocarbon group may or may not have a substituent. Examples of the substituent include a fluorine atom, a fluorinated alkyl group having 1 to 5 carbon atoms which has been substituted with a fluorine atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. As the linear or branched aliphatic hydrocarbon group, the same groups as those described above can be used.

The cyclic aliphatic hydrocarbon group has preferably 3 to 20 carbon atoms and more preferably 3 to 12 carbon atoms.

The cyclic aliphatic hydrocarbon group may be a polycyclic group or a monocyclic group. As the monocyclic alicyclic hydrocarbon group, a group in which two hydrogen atoms have been removed from a monocycloalkane is preferable. The monocycloalkane has preferably 3 to 6 carbon atoms, and specific examples thereof include cyclopentane and cyclohexane. As a polycyclic alicyclic hydrocarbon group, a group in which two hydrogen atoms have been removed from a polycycloalkane is preferable. Specific examples of the polycycloalkane include polycycloalkanes having a polycyclic skeleton of a fused ring system such as a ring structure having a decalin, perhydroazulene, perhydroanthracene, or steroid skeleton.

In addition, as the aliphatic hydrocarbon group containing a ring in the above-described structure, Ya^{x0} may share a carbon atom in a polymerizable group at the W¹ moiety to form an aliphatic hydrocarbon group containing a ring in the above-described structure.

The cyclic aliphatic hydrocarbon group may or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom, and a fluorine atom is preferable.

Examples of the halogenated alkyl group as the substituent include groups in which some or all hydrogen atoms in the above-described alkyl groups have been substituted with the above-described halogen atoms.

In the cyclic aliphatic hydrocarbon group, some carbon atoms constituting the ring structure thereof may be substituted with a substituent containing a hetero atom. As the substituent containing a hetero atom, —O—, —C(═O)—O—, —S—, —S(═O)₂—, or —S(═O)₂—O— is preferable.

Aromatic Hydrocarbon Group as Ya^{x0}

The aromatic hydrocarbon group is a hydrocarbon group having at least one aromatic ring.

The aromatic ring is not particularly limited as long as it is a cyclic conjugated system having (4n+2)π electrons, and may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms. Here, the number of carbon atoms in a substituent is not included in the number of carbon atoms. Specific examples of the aromatic ring include aromatic hydrocarbon rings such as benzene, naphthalene, anthracene, and phenanthrene; and aromatic hetero rings in which some carbon atoms constituting the above-described aromatic hydrocarbon rings have been substituted with hetero atoms. Examples of the hetero atom in the aromatic hetero rings include an oxygen atom, a sulfur atom and a nitrogen atom. Specific examples of the aromatic hetero ring include a pyridine ring and a thiophene ring.

Specific examples of the aromatic hydrocarbon group include a group in which two hydrogen atoms have been removed from the above-described aromatic hydrocarbon ring or aromatic hetero ring (an arylene group or a heteroarylene group); a group in which two hydrogen atoms have been removed from an aromatic compound having two or more aromatic rings (biphenyl, fluorene or the like); and a group in which one hydrogen atom a group (an aryl group or a heteroaryl group) obtained by removing one hydrogen atom from of the above-described aromatic hydrocarbon ring or aromatic hetero ring has been substituted with an alkylene group (for example, a group in which one hydrogen atom has been further removed from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to an aryl group or heteroaryl group preferably has 1 to 4 carbon atoms, more preferably has 1 or 2 carbon atoms, and particularly preferably has 1 carbon atom.

With respect to the aromatic hydrocarbon group, the hydrogen atom in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and a methyl group, an ethyl group, a propyl group, an n-butyl group, or a tert-butyl group is most preferable.

As the alkoxy group, the halogen atom, and the halogenated alkyl group as the substituents, the same groups as the above-described substituent groups for substituting a hydrogen atom in the cyclic aliphatic hydrocarbon group can be exemplified.

Divalent Linking Group Containing Hetero Atom:

In a case where Ya^{x0} represents a divalent linking group containing a hetero atom, preferable examples of the linking group include —O—, —C(═O)—O—, —C(═O)—, —O—C(═O)—O—, —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula: —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²— [in the formulae, Y²¹ and Y²² each independently represent a divalent hydrocarbon group which may have a substituent, O represents an oxygen atom, and m″ represents an integer of 0 to 3].

In a case where the divalent linking group containing the hetero atom is —C(═O)—NH—, —C(═O)—NH—C(═O)—, —NH— or —NH—C(═NH)—, H may be substituted with a substituent such as an alkyl group, an acyl group, or the like. The substituent (an alkyl group, an acyl group, or the like) has preferably 1 to 10 carbon atoms, more preferably 1 to 8 carbon atoms, and particularly preferably 1 to 5 carbon atoms.

In General Formulae —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²—, Y²¹ and Y²² each independently represent a divalent hydrocarbon group which may have a substituent. Examples of the divalent hydrocarbon group include the same groups as those described above as the “divalent hydrocarbon group which may have a substituent” in the explanation of the above-described divalent linking group.

As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y²², a linear or branched aliphatic hydrocarbon group is preferable, and a methylene group, an ethylene group, or an alkylmethylene group is more preferable. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]_{m″}—Y²²—, m″ represents an integer of 0 to 3, preferably an integer of 0 to 2, more preferably 0 or 1, and particularly preferably 1. In other words, it is particularly preferable that the group represented by Formula —[Y²¹—C(═O)—O]_{m″}—Y²²— is a group represented by Formula —Y²¹—C(═O)—O—Y²²—. Among these, a group represented by Formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

Among them, as Ya^{x0}, an ester bond [—C(═O)—O—, —O—C(═O)—], an ether bond (—O—), a linear or branched alkylene group, or a combination thereof, or a single bond is preferable. Among them, an ester bond [—C(═O)—O—, —O—C(═O)—], a linear or branched alkylene group, a combination thereof, or a single bond is more preferable, and a single bond is particularly preferable.

In Formula (a0-1), Rx⁰¹ is an acid dissociable group represented by General Formula (a01-r-1) or General Formula (a01-r-2).

Because the acid dissociable group has high reactivity with respect to an acid, it is possible to improve lithography characteristics such as a sensitivity, resolution performance, and roughness improvement. In addition, because the aliphatic cyclic group included in the acid dissociable group is an aliphatic monocyclic group having 3 to 5 carbon atoms, a deterioration of a resolution performance and a deterioration of LWR due to a decrease of solubility in a developing solution do not occur.

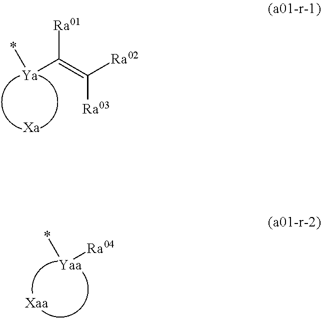

[In Formula (a01-r-1), Ya represents a carbon atom, Xa is a group that forms an aliphatic cyclic group together with Ya, some or all of hydrogen atoms included in the aliphatic cyclic group may be substituted, where the aliphatic cyclic group to be formed by Xa and Ya is an aliphatic monocyclic group having 3 to 5 carbon atoms, Ra⁰¹ to Ra⁰³ each independently represent a hydrogen atom, a chain-like monovalent saturated hydrocarbon group having 1 to 10 carbon atoms, or a monovalent aliphatic cyclic saturated hydrocarbon group having 3 to 20 carbon atoms.

Some or all hydrogen atoms in the chain-like saturated hydrocarbon group and the aliphatic cyclic saturated hydrocarbon group may be substituted, and two or more of Ra⁰¹ to Ra⁰³ may be bonded to one another to form an aliphatic cyclic structure; and in Formula (a01-r-2), Yaa represents a carbon atom, Xaa represents a group that forms an aliphatic cyclic group together with Yaa, some or all of hydrogen atoms included in the aliphatic cyclic group may be substituted, where the aliphatic cyclic group to be formed by Xaa and Yaa is an aliphatic monocyclic group having 3 to 5 carbon atoms, Ra⁰⁴ represents an aromatic hydrocarbon group which may have a substituent, and the symbol “*” represents a bonding site.]

In Formula (a01-r-1), Xa is a group that forms an aliphatic cyclic group together with Ya. Some or all of hydrogen atoms included in the aliphatic cyclic group may be substituted. Where, the aliphatic cyclic group to be formed by Xa and Ya is an aliphatic monocyclic group having 3 to 5 carbon atoms.

Specific examples of aliphatic monocyclic structures in the aliphatic monocyclic group having 3 to 5 carbon atoms formed by Xa and Ya include cyclopropane, cyclobutane, and cyclopentane. Among them, cyclopentane is particularly preferable.

Some or all of the hydrogen atoms of the aliphatic cyclic group may be substituted. Examples of substituents include —R^{P1}, —R^{P2}—O—R^{P1}, —R^{P2}—CO—R^{P1}, —R^{P2}—CO—OR^{P1}, —R^{P2}—O—CO—RP¹, —R^{P2}—OH, —R^{P2}—CN, and —R^{P2}—COOH (hereinafter, these substituents are also collectively referred to as “Ra⁰⁵”).

Here, RP¹ represents a chain-like monovalent saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. Further, R^{P2} represents a single bond, a chain-like divalent saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms.

Here, some or all hydrogen atoms in the chain-like saturated hydrocarbon group, the aliphatic cyclic saturated hydrocarbon group, and the aromatic hydrocarbon group as R^{P1} and R^{P2} may be substituted with fluorine atoms. The aliphatic cyclic hydrocarbon group may have one or more of one kind of substituents or one or more of each of plural kinds of the substituents.

Examples of the chain-like monovalent saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of monovalent aliphatic cyclic saturated hydrocarbon groups having 3 to 20 carbon atoms include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, or a cyclododecyl group; polycyclic aliphatic saturated hydrocarbon groups such as decalin, perhydroazulene, and perhydroanthracene; and the like.

Examples of the monovalent aromatic hydrocarbon group having 6 to 30 carbon atoms include a group formed by removing one hydrogen atom from an aromatic hydrocarbon ring, such as benzene, biphenyl, fluorene, naphthalene, anthracene, or phenanthrene.

In Formula (a01-r-1), examples of the chain-like monovalent saturated hydrocarbon group having 1 to 10 carbon atoms as Ra⁰¹ to Ra⁰³ include a methyl group, an ethyl group, a propyl group, a butyl group, a pentyl group, a hexyl group, a heptyl group, an octyl group, a nonyl group, and a decyl group.

Examples of monovalent aliphatic cyclic saturated hydrocarbon groups having 3 to 20 carbon atoms in Ra⁰¹ to Ra⁰³ include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, or a cyclododecyl group; polycyclic aliphatic saturated hydrocarbon groups such as decalin, perhydroazulene, and perhydroanthracene; and the like.

From the viewpoint of easily synthesizing a monomer compound from which the structural unit (a1) is derived, it is preferable that Ra⁰¹ to Ra⁰³ represents a hydrogen atom or a chain-like monovalent saturated hydrocarbon group having 1 to 10 carbon atoms. Among these, a hydrogen atom, a methyl group, or an ethyl group is more preferable, and a hydrogen atom is particularly preferable.

Examples of the substituent included in the chain-like saturated hydrocarbon group or the aliphatic cyclic saturated hydrocarbon group represented by Ra⁰¹ to Ra⁰³ are the same as those exemplified as Ra⁰⁵.

Examples of the group having a carbon-carbon double bond generated by two or more of Ra⁰¹ to Ra⁰³ being bonded to one another to form a cyclic structure include a cyclopentenyl group, a cyclohexenyl group, a methylcyclopentenyl group, a methylcyclohexenyl group, a cyclopentylidenethenyl group, and a cyclohexylidenethenyl group.

In Formula (a01-r-2), specific examples of aliphatic monocyclic structures in the aliphatic monocyclic group having 3 to 5 carbon atoms formed by Xaa and Yaa include cyclopropane, cyclobutane, and cyclopentane. Among them, cyclopentane is particularly preferable.

In Formula (a01-r-2), examples of the aromatic hydrocarbon group as Ra⁰⁴ include a group formed by removing one or more hydrogen atoms from an aromatic hydrocarbon ring having 5 to 30 carbon atoms. Among the examples, Ra⁰⁴ represents preferably a group formed by removing one or more hydrogen atoms from an aromatic hydrocarbon ring having 6 to 15 carbon atoms, more preferably a group formed by removing one or more hydrogen atoms from benzene, naphthalene, anthracene, or phenanthrene, still more preferably a group formed by removing one or more hydrogen atoms from benzene, naphthalene, or anthracene, particularly preferably a group formed by removing one or more hydrogen atoms from benzene or naphthalene, and most preferably a group formed by removing one or more hydrogen atoms from benzene.

Examples of the substituent which may be included in Ra⁰⁴ in Formula (a01-r-2) include an alkyl group, a hydroxy group, a carboxyl group, a halogen atom (such as a fluorine atom, a chlorine atom, or a bromine atom), an alkoxy group (such as a methoxy group, an ethoxy group, a propoxy group, or a butoxy group), and an alkyloxycarbonyl group.

The alkyl group as the substituent is preferably an alkyl group having 1 to 5 carbon atoms, and is more preferably a methyl group or a tert-butyl group.

Specific examples of acid dissociable groups represented by General Formula (a01-r-1) are as below. The symbol “*” represents a bonding site.

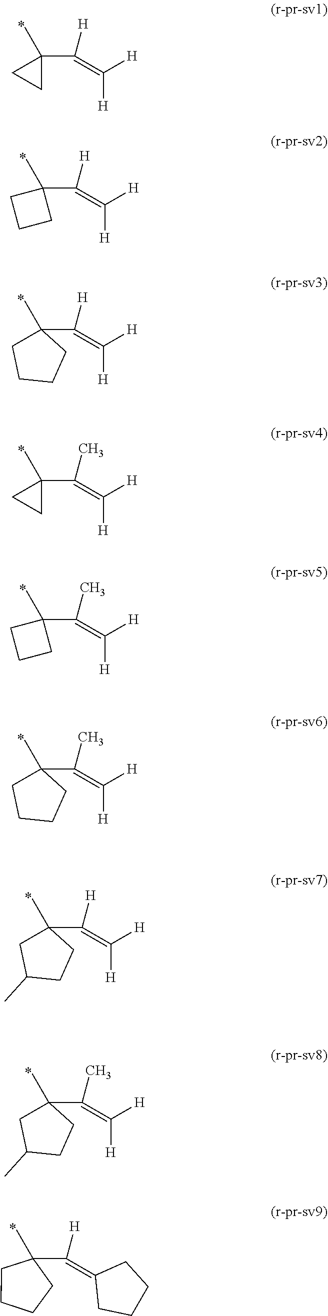

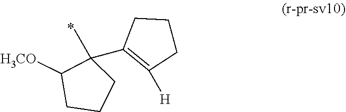

Specific examples of acid dissociable groups represented by General Formula (a01-r-2) are as below. The symbol “*” represents a bonding site.

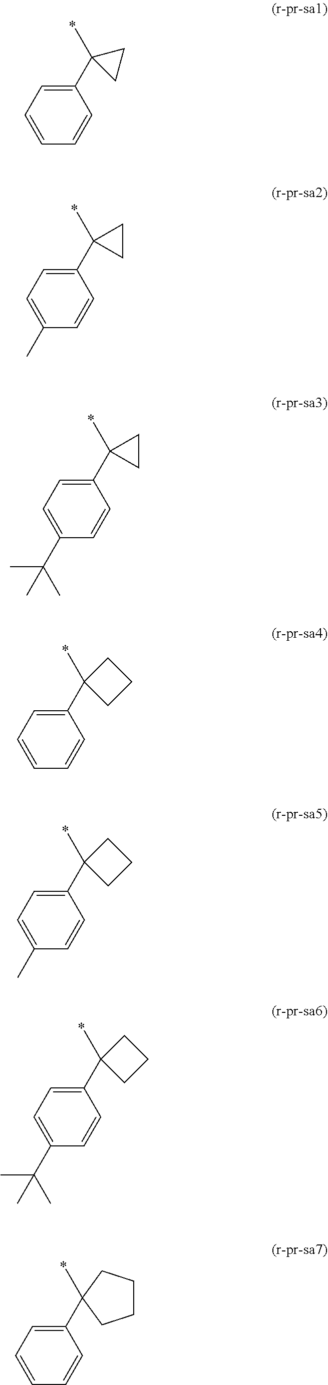

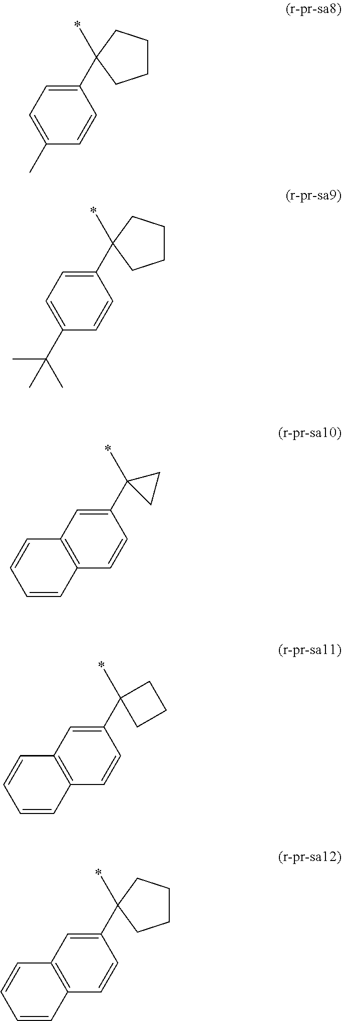

Specific examples of structural units (a01) are shown below.

In the formula below, R^{α} represents a hydrogen atom, a methyl group, or a trifluoromethyl group.

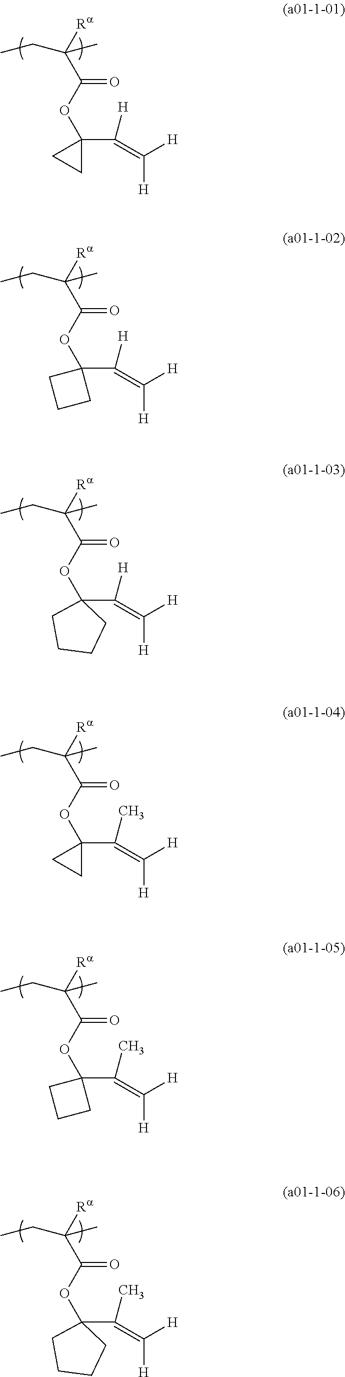

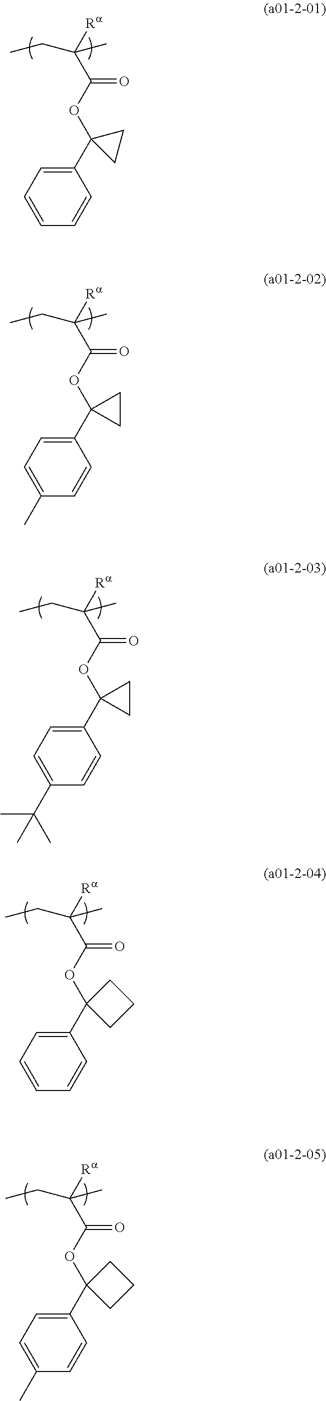

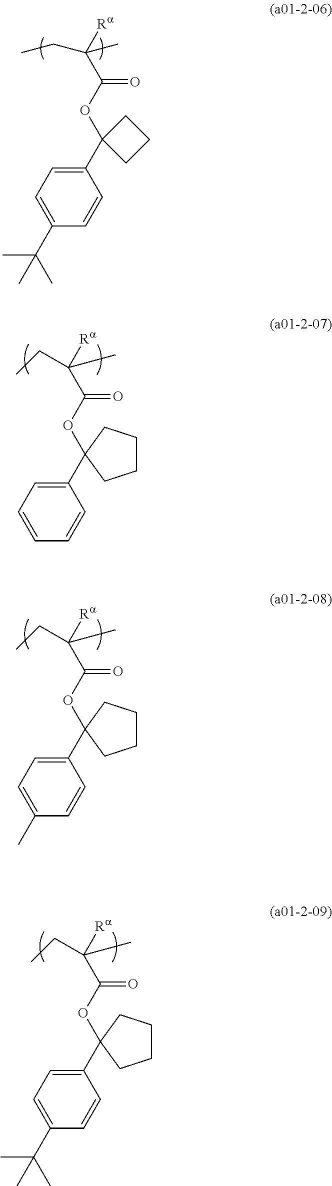

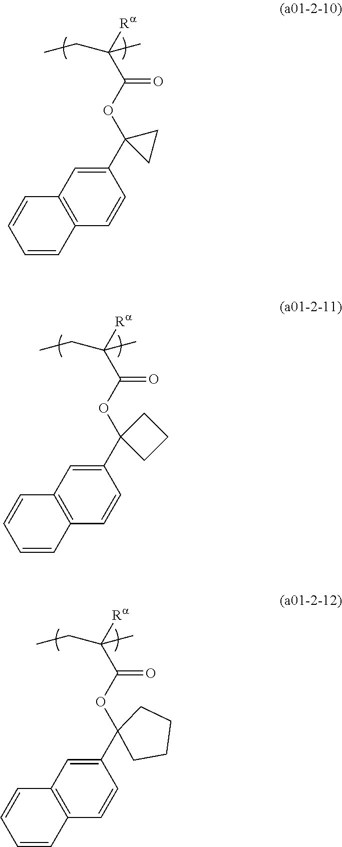

Among the above-mentioned examples, the structural unit (a0-1) is preferably at least one kind selected from the group consisting of structural units respectively represented by Chemical Formulae (a01-1-03), (a01-1-06), (a01-2-07) to (a01-2-09), and (a01-2-12).

One kind of the structural unit (a01) included in the component (A1) may be used alone, or two or more kinds thereof may be used.

A proportion of the structural unit (a01) in the component (A1) is preferably within a range of 30% to 85% by mole, more preferably within a range of 40% to 80% by mole, and particularly preferably within a range of 50% to 60% by mole with respect to the total amount (100% by mole) of all structural units constituting the component (A1).

By setting a ratio of the structural unit (a01) to be equal to or more than the lower limit value of the above preferable range, lithography characteristics such as a resolution performance and roughness improvement are improved. In addition, by setting a ratio to be equal to or less than the upper limit value, it is possible to balance it with other structural units, and thereby various lithography characteristics become favorable.

<<Structural Unit (a02)>>

The structural unit (a02) is a structural unit, in which a polymerizable group at a W² moiety is converted into a main chain, in a compound represented by General Formula (a0-2). When the component (A1) has the structural unit (a02), and in a case where the component (A1) is used for forming a resist film, it is possible to improve adhesiveness of a resist film to a substrate and to appropriately adjust a solubility during development.

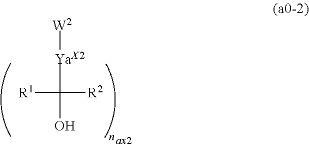

[In Formula (a0-2), W² is a polymerizable-group-containing group, Ya^{x2} is a single bond or an (nₐₓ₂+1)-valent linking group, Ya^{x2} and W² may form a fused ring, R¹ is a fluorinated alkyl group having 1 to 12 carbon atoms, R² is a hydrogen atom or an organic group having 1 to 12 carbon atoms which may have a fluorine atom, and nₐₓ₂ is an integer of 1 to 3.]

In Formula (a0-2), the polymerizable-group-containing group at W² is the same as the polymerizable-group-containing group at W¹ in Formula (a0-1).

In Formula (a0-2), Ya^{x2} is a single bond or an (nₐₓ₂+1)-valent, that is a divalent, a trivalent, or a tetravalent linking group.

Examples of divalent linking groups in Ya^{x2} include the same examples as the contents described for the divalent linking groups in Ya^{x0} of W¹ in General Formula (a0-1). As the trivalent linking group as Ya^{x2}, a group in which one hydrogen atom has been removed from the above-described divalent linking group and a group in which the divalent linking group has been bonded to another divalent linking group can be exemplified. Examples of tetravalent linking groups include groups in which two hydrogen atoms have been removed from the divalent linking group.

Ya^{x2} and W² may form a fused ring.

In a case where Ya^{x2} and W² form a fused ring, examples of ring structures thereof include a fused ring of an alicyclic hydrocarbon and an aromatic hydrocarbon. The fused ring formed by Ya^{x2} and W² may have a hetero atom.

An alicyclic hydrocarbon moiety in the fused ring formed by Ya^{x2} and W² may be monocyclic or polycyclic.

Examples of fused rings formed by Ya^{x2} and W² include a fused ring formed by a polymerizable group at the W² moiety, and Ya^{x2}, and a fused ring formed by Ya^{x2} and a group other than the polymerizable group at the W² moiety. Specific examples thereof include a bicyclic fused ring of a cycloalkene and an aromatic ring, a tricyclic fused ring of a cycloalkene and two aromatic rings, a bicyclic fused ring of an aromatic ring and a cycloalkane having a polymerizable group as a substituent, a tricyclic fused ring of an aromatic ring and a cycloalkane having a polymerizable group as a substituent, and the like.

The fused ring formed by Ya^{x2} and W² may have a substituent. Examples of substituents include a methyl group, an ethyl group, a propyl group, a hydroxy group, a hydroxyalkyl group, a carboxy group, a halogen atom (such as a fluorine atom, a chlorine atom, or a bromine atom), an alkoxy group (such as a methoxy group, an ethoxy group, a propoxy group, or a butoxy group), an acyl group, an alkyloxycarbonyl group, an alkylcarbonyloxy group, and the like.

Specific examples of fused rings formed by Ya^{x2} and W² are shown below. W^{α} represents a polymerizable group.

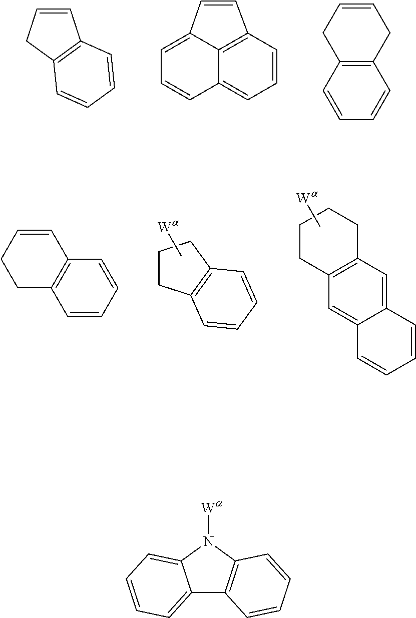

In Formula (a0-2), R¹ is a fluorinated alkyl group having 1 to 12 carbon atoms.

The fluorinated alkyl group having 1 to 12 carbon atoms is a group in which some or all hydrogen atoms of the above-described alkyl group having 1 to 12 carbon atoms have been substituted with fluorine atoms. The alkyl group may be linear or branched.

Specific examples of linear fluorinated alkyl groups having 1 to 12 carbon atoms include a group in which some or all of hydrogen atoms of a methyl group, an ethyl group, a propyl group, a butyl group, a pentyl group, a hexyl group, a heptyl group, an octyl group, a nonyl group, a decyl group, an undecyl group, and a dodecyl group are substituted by fluorine atoms. Specific examples of branched fluorinated alkyl groups having 1 to 12 carbon atoms include a group in which some or all of hydrogen atoms of a 1-methylethyl group, a 1,1-dimethylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group are substituted by fluorine atoms.

Among them, a fluorinated alkyl group having 1 to 12 carbon atoms of R¹ is more preferably a fluorinated alkyl group having 1 to 5 carbon atoms, and specifically, it is particularly preferably a trifluoromethyl group.

In Formula (a0-2), R² is a hydrogen atom or an organic group having 1 to 12 carbon atoms which may have a fluorine atom.

Examples of organic groups having 1 to 12 carbon atoms which may have a fluorine atom of R² include monovalent hydrocarbon groups having 1 to 12 carbon atoms which may have a fluorine atom.

Examples of hydrocarbon groups include a linear or branched alkyl group, or a cyclic hydrocarbon group.

Specific examples of linear alkyl groups include a methyl group, an ethyl group, a propyl group, a butyl group, a pentyl group, a hexyl group, a heptyl group, an octyl group, a nonyl group, a decyl group, an undecyl group, and a dodecyl group.

Specific examples of branched alkyl groups include a 1-methylethyl group, a 1,1-dimethylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, a 4-methylpentyl group, and the like.

In a case where R² represents a cyclic hydrocarbon group, the cyclic hydrocarbon group may be an aliphatic hydrocarbon group or an aromatic hydrocarbon group, and may be polycyclic or monocyclic.

As the monocyclic aliphatic hydrocarbon group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable, and the polycyclic group has preferably 7 to 12 carbon atoms, and specific examples of the polycycloalkane include adamantane, norbomane, isobomane, tricyclodecane, and tetracyclododecane.

In a case where the cyclic hydrocarbon group as R² becomes an aromatic hydrocarbon group, the aromatic hydrocarbon group is a hydrocarbon group having at least one aromatic ring. Specific examples of aromatic hydrocarbon groups include groups in which one hydrogen atom has been removed from an aromatic hydrocarbon ring such as benzene, naphthalene, anthracene, phenanthrene, biphenyl, and fluorene.

The organic group having 1 to 12 carbon atoms of R² may have a substituent other than a fluorine atom. Examples of substituents thereof include a hydroxy group, a carboxy group, a halogen atom (such as a chlorine atom and a bromine atom), an alkoxy group (such as a methoxy group, an ethoxy group, a propoxy group, and a butoxy group), an alkyloxycarbonyl group, and the like.

R² is preferably a fluorinated alkyl group having 1 to 12 carbon atoms, is more preferably a fluorinated alkyl group having 1 to 5 carbon atoms, and is even more preferably a trifluoromethyl group.

In Formula (a0-2), nₐₓ₂ represents an integer of 1 to 3, preferably 1 or 2, and more preferably 1.

The structural unit (a02) is preferably a structural unit (a021), in which a polymerizable group at a W² moiety is converted into a main chain, in a compound represented by General Formula (a0-2-1).

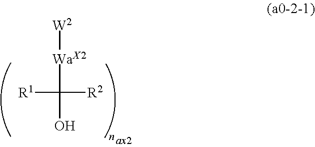

[In Formula (a0-2-1), W² is a polymerizable-group-containing group, Wa^{x2} is an (nₐₓ₂+1)-valent cyclic group, W² and Wa^{x2} may form a fused ring, R¹ is a fluorinated alkyl group having 1 to 12 carbon atoms, R² is a hydrogen atom or an organic group having 1 to 12 carbon atoms which may have a fluorine atom, and nₐₓ₂ is an integer of 1 to 3.]

W², R¹, R², and nₐₓ₂ in Formula (a0-2-1) are the same as W², R¹, R², and nₐₓ₂ in General Formula (a0-2).

In Formula (a0-2-1), Wa^{x2} is an (nₐₓ₂+1)-valent cyclic group.

Examples of cyclic groups in Wa^{x2} include an aliphatic cyclic group and an aromatic cyclic group, and a cyclic group may be monocyclic or polycyclic.

As the aliphatic cyclic group which is a monocyclic group, a group in which one hydrogen atom has been removed from a monocycloalkane is preferable. The monocycloalkane has preferably 3 to 6 carbon atoms, and specific examples thereof include cyclopentane and cyclohexane.

As an aliphatic cyclic group which is a polycyclic group, a group in which one hydrogen atom has been removed from a polycycloalkane is preferable. The polycycloalkane preferably has 7 to 12 carbon atoms. Specific examples thereof include groups in which one or more hydrogen atoms have been removed from a polycycloalkane such as decalin, perhydroazulene, and perhydroanthracene, and the like.

The aromatic cyclic group is a hydrocarbon group having at least one aromatic ring. The aromatic ring is not particularly limited as long as it is a cyclic conjugated system having (4n+2) nt electrons. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic hetero rings in which some carbon atoms constituting the above-described aromatic hydrocarbon rings have been substituted with hetero atoms. Examples of the hetero atom in the aromatic hetero rings include an oxygen atom, a sulfur atom and a nitrogen atom. Specific examples of the aromatic hetero ring include a pyridine ring and a thiophene ring. Specific examples of the aromatic hydrocarbon group include a group in which one hydrogen atom has been removed from the above-described aromatic hydrocarbon ring or aromatic hetero ring (an aryl group or a heteroaryl group); a group in which one hydrogen atom has been removed from an aromatic compound having two or more aromatic rings (biphenyl, fluorene or the like); and a group in which one hydrogen atom of the above-described aromatic hydrocarbon ring or aromatic hetero ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group which is bonded to the above-described aromatic hydrocarbon ring or aromatic hetero ring has preferably 1 to 4 carbon atoms, more preferably 1 or 2 carbon atoms, and particularly preferably 1 carbon atom.

Examples of substituents that may be included in the cyclic group in Wa^{x2} include a carboxy group, a halogen atom (such as a fluorine atom, a chlorine atom, or a bromine atom), an alkoxy group (such as a methoxy group, an ethoxy group, a propoxy group, or a butoxy group), an alkyloxycarbonyl group, and the like.

W² and Wa^{x2} may form a fused ring, and they are the same as the contents described for the fused ring formed by Ya^{x2} and W² in Formula (a0-2).

Specific examples of structural units (a02) are shown below.

In the formula below, R^{α} represents a hydrogen atom, a methyl group, or a trifluoromethyl group.

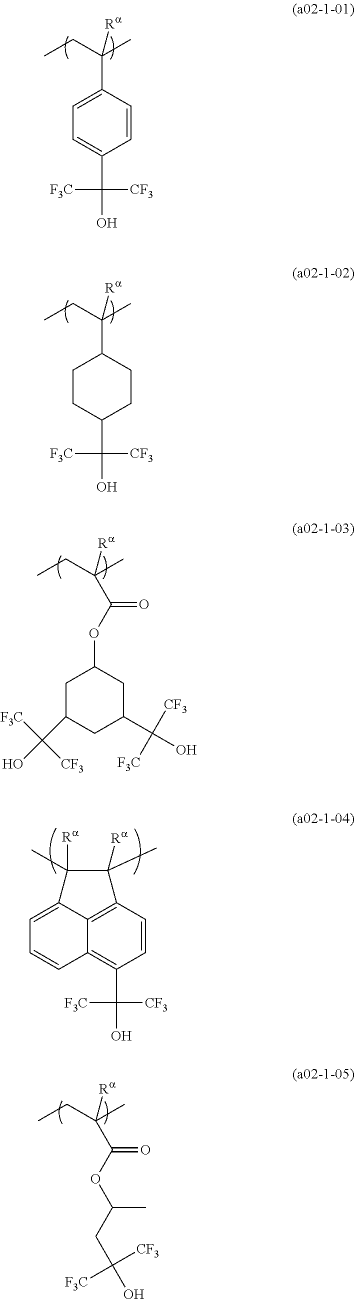

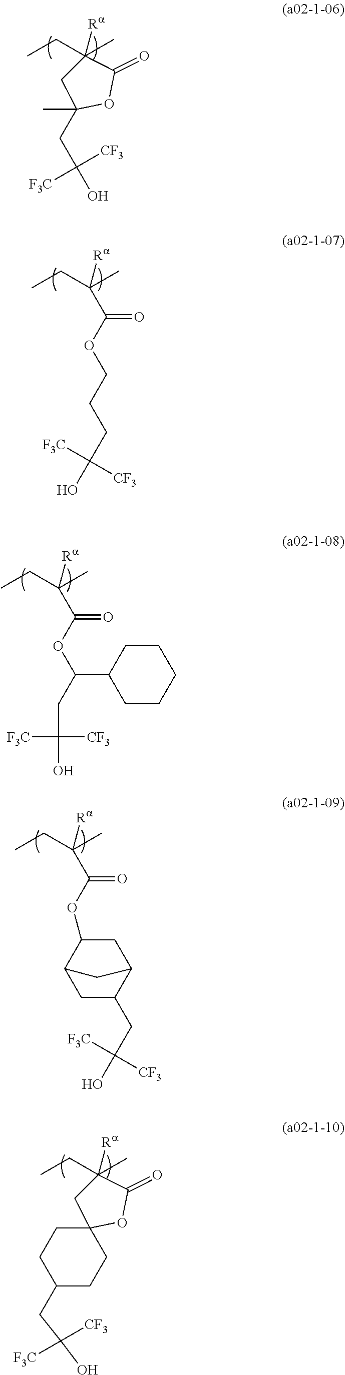

Among the above examples, the structural unit (a02) is preferably at least one kind selected from the group consisting of structural units respectively represented by Chemical Formulae (a02-1-01) to (a01-1-04), (a02-1-06), (a02-1-08), (a02-1-09), and (a02-1-10), and is more preferably at least one kind selected from the group consisting of structural units respectively represented by Chemical Formulae (a02-1-01) to (a01-1-04).

One kind of the structural unit (a02) included in the component (A1) may be used alone, or two or more kinds thereof may be used.

In a case where the component (A1) has the structural unit (a02), a proportion of the structural unit (a02) in the component (A1) is preferably within a range of 1% to 50% by mole, more preferably within a range of 5% to 45% by mole, and still more preferably in a range of 10% to 45% by mole with respect to the total amount (100% by mole) of all structural units constituting the component (A1).

By setting a ratio of the structural unit (a02) to be equal to or more than the preferable lower limit value, the effect of incorporating the structural unit (a02) is sufficiently obtained, and by setting a ratio thereof to be equal to or less than the upper limit value, it is possible to balance it with other structural units, and thereby various lithography characteristics become favorable.

<<Structural Unit (a03)>>

The structural unit (a03) is a structural unit, in which a polymerizable group at a W³ moiety is converted into a main chain, in a compound represented by General Formula (a0-3). When the component (A1) has the structural unit (a03), and in a case where the component (A1) is used for forming a resist film, it is possible to appropriately adjust a solubility during development. In addition, because the structural unit (a03) has an aromatic ring hydroxy group, it can serve as a proton source and improve sensitivity in formation of a resist pattern.

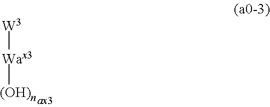

[In Formula (a0-3), W³ is a polymerizable-group-containing group, Wa^{x3} is an (nₐₓ₃+1)-valent aromatic hydrocarbon group which may have a substituent, Wa^{x3} and W³ may form a fused ring, and nₐₓ₃ is an integer of 1 to 3.]

In Formula (a0-3), the polymerizable-group-containing group at W³ is the same as the polymerizable-group-containing group at W¹ in Formula (a0-1).

In Formula (a0-3), Wa^{x3} is an (nₐₓ₃+1)-valent aromatic hydrocarbon group which may have a substituent.

Examples of cyclic groups having aromaticity in Wa^{x3} include groups in which (nₐₓ₀+1) hydrogen atoms have been removed from an aromatic ring. The aromatic ring is not particularly limited as long as it is a cyclic conjugated system having (4n+2) n electrons, and may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms. Specific examples of the aromatic ring include aromatic hydrocarbon rings such as benzene, naphthalene, anthracene, and phenanthrene; and aromatic hetero rings in which some carbon atoms constituting the above-described aromatic hydrocarbon rings have been substituted with hetero atoms. Examples of the hetero atom in the aromatic hetero rings include an oxygen atom, a sulfur atom and a nitrogen atom. Specific examples of the aromatic hetero ring include a pyridine ring and a thiophene ring.

Examples of substituents that may be included in Wa^{x3} include a carboxy group, a halogen atom (such as a fluorine atom, a chlorine atom, or a bromine atom), an alkoxy group (such as a methoxy group, an ethoxy group, a propoxy group, or a butoxy group), an alkyloxycarbonyl group, and the like.

In Formula (a0-3), Wa^{x3} and W³ may form a fused ring.

In a case where Wa^{x3} and W³ form a fused ring, examples of ring structures thereof include a fused ring of an alicyclic hydrocarbon and an aromatic hydrocarbon. The fused ring formed by Wa^{x3} and W³ may have a hetero atom.

An alicyclic hydrocarbon moiety in the fused ring formed by Wa^{x3} and W³ may be monocyclic or polycyclic.

Examples of fused rings formed by Wa^{x3} and W³ include a fused ring formed by a polymerizable group at the W³ moiety, and Wa^{x3}, and a fused ring formed by Wa^{x3} and a group other than the polymerizable group at the W³ moiety.

The fused ring formed by Wa^{x3} and W³ may have a substituent. Examples of substituents include a methyl group, an ethyl group, a propyl group, a hydroxy group, a hydroxyalkyl group, a carboxy group, a halogen atom (such as a fluorine atom, a chlorine atom, or a bromine atom), an alkoxy group (such as a methoxy group, an ethoxy group, a propoxy group, or a butoxy group), an acyl group, an alkyloxycarbonyl group, an alkylcarbonyloxy group, and the like.

Specific examples of fused rings formed by Wa^{x3} and W³ are shown below. W^{α} represents a polymerizable group.

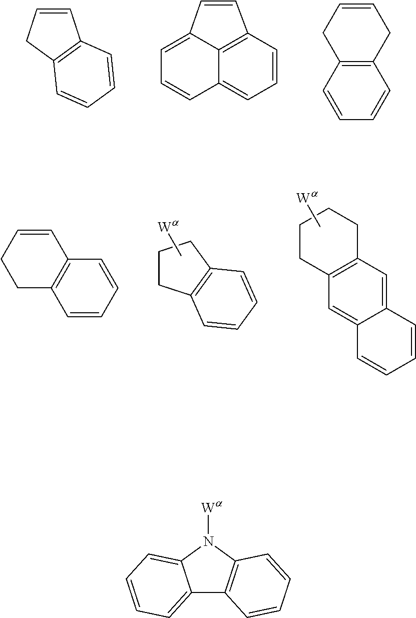

In Formula (a0-3), nₐₓ₃ represents an integer of 1 to 3, preferably 1 or 2, and more preferably 1.

Specific examples of structural units represented by the structural unit (a03) are shown below.

In the formula below, R^{α} represents a hydrogen atom, a methyl group, or a trifluoromethyl group.

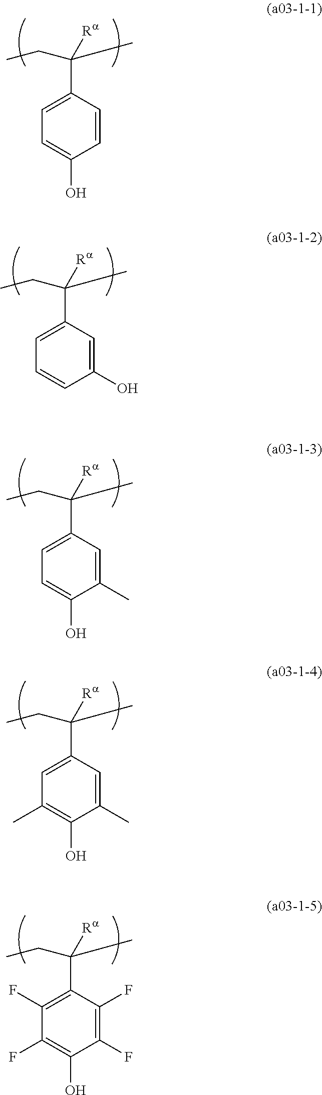

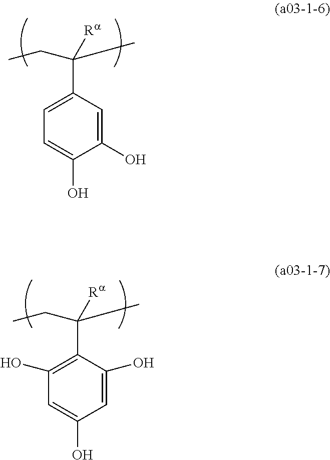

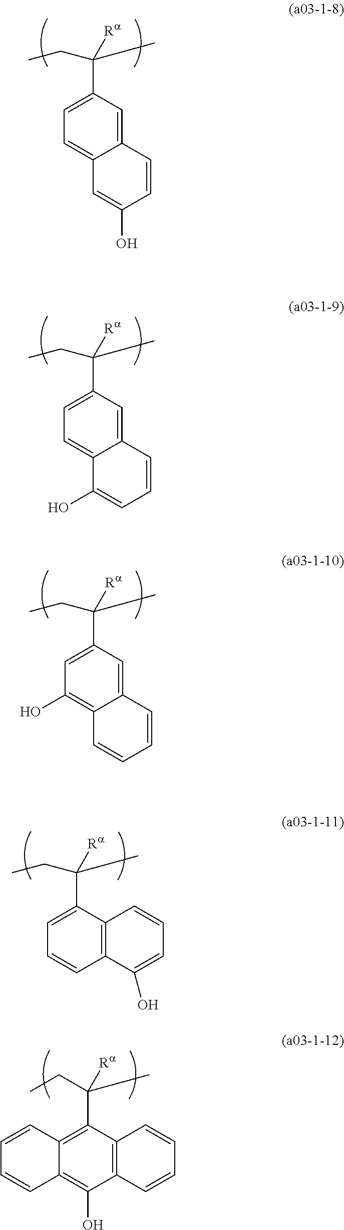

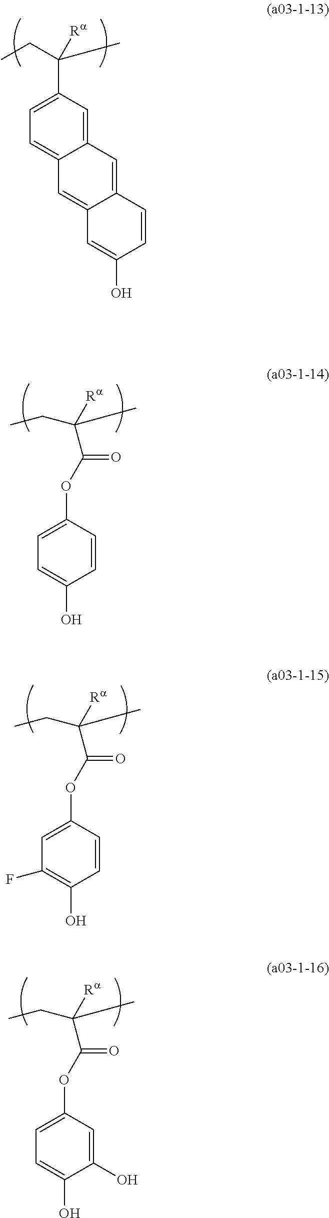

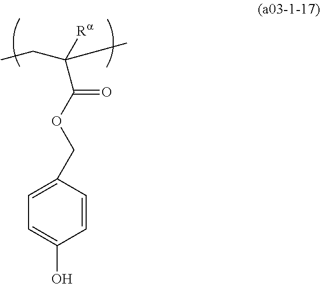

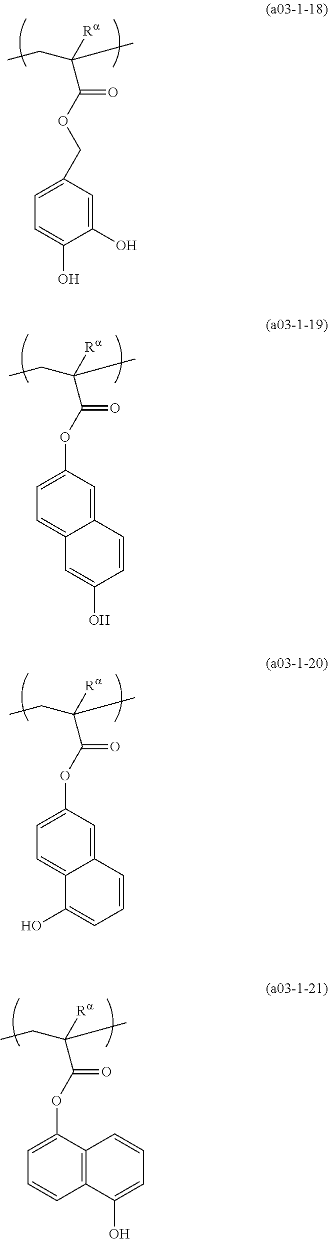

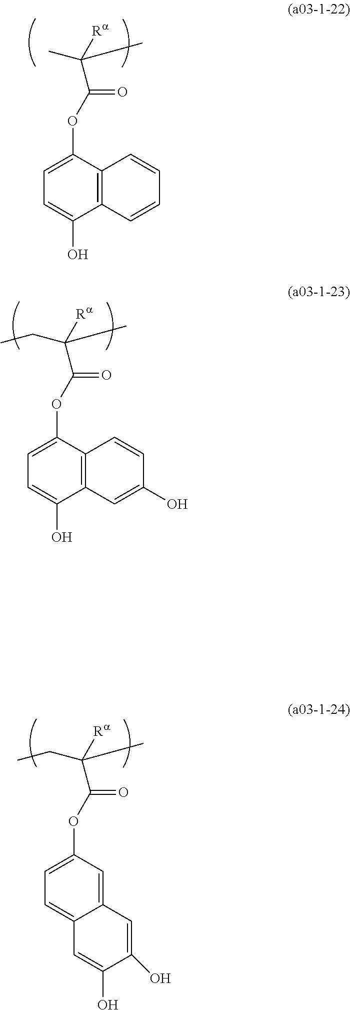

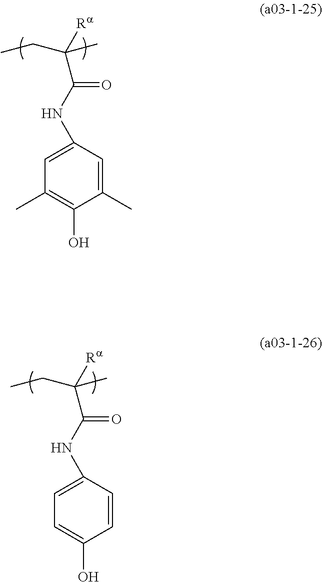

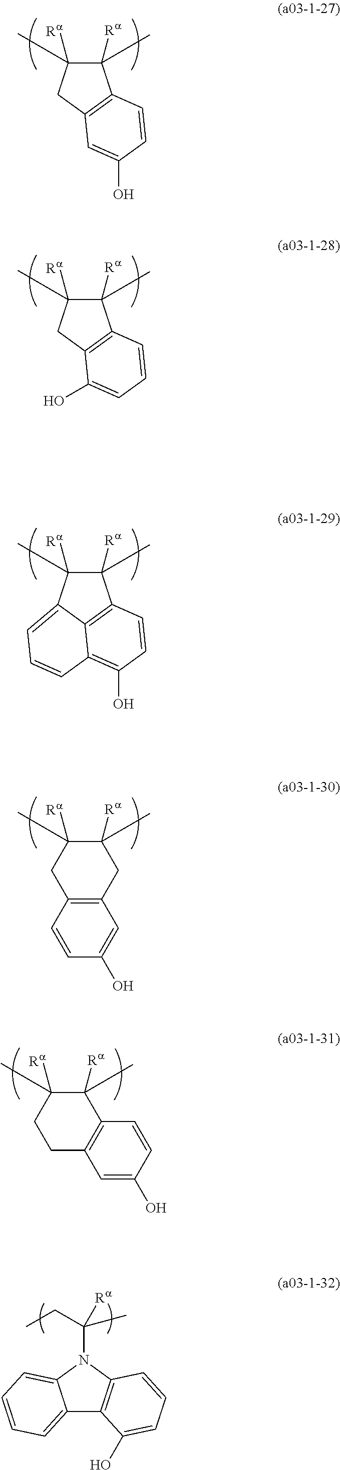

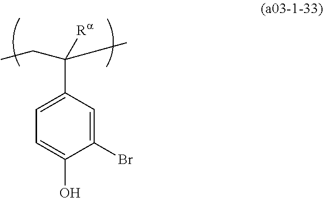

Among the above examples, the structural unit (a03) is preferably at least one selected from the group consisting of structural units respectively represented by Chemical Formulae (a03-1-1) to (a03-1-26), is more preferably at least one selected from the group consisting of structural units respectively represented by Chemical Formulae (a03-1-1) to (a03-1-7), is even more preferably at least one selected from the group consisting of structural units respectively represented by Chemical Formulae (a03-1-1), (a03-1-2), and (a03-1-6), and is particularly preferable a structural unit represented by Chemical Formula (a03-1-1).

One kind of the structural unit (a03) included in the component (A1) may be used alone, or two or more kinds thereof may be used.

A proportion of the structural unit (a03) in the component (A1) is preferably within a range of 1% to 50% by mole, more preferably within a range of 10% to 40% by mole, and still more preferably within a range of 20% to 40% by mole with respect to the total amount (100% by mole) of all structural units constituting the component (A1).

By adjusting the ratio of structural unit (a03) to be equal to or more than the lower limit value of the above-mentioned preferable range, the lithography characteristics become favorable due to effects of, for example, appropriately adjusting a solubility during development, improving sensitivity, improving etching resistance, and the like. In addition, by setting a ratio to be equal to or lower than the upper limit value, it is possible to balance it with other structural units, and thereby various lithography characteristics become favorable.

<<Other Structural Units>>

The component (A1) may have other structural units other than the structural unit (a01), the structural unit (a02), and the structural unit (a03) described above. Examples of other structural units include a structural unit (a1) containing an acid decomposable group whose polarity increases due to the action of an acid (excluding structural units corresponding to the structural unit (a01)); a structural unit (a2) containing a lactone-containing cyclic group, —SO₂-containing cyclic group, or a carbonate-containing cyclic group (where structural units corresponding to the structural unit (a1) and the structural unit (a01) being excluded); a structural unit (a3) containing a polar group-containing aliphatic hydrocarbon group (where structural units corresponding to the structural unit (a01), the structural unit (a02), the structural unit (a03), the structural unit (a1), or the structural unit (a2)) being excluded); a structural unit (a9) represented by General Formula (a9-1) to be described later; and the like.

Structural Unit (a1):

In addition to the structural unit (a01), the structural unit (a02), and the structural unit (a03), the component (A1) may further have the structural unit (a1) containing an acid decomposable group whose polarity increases due to the action of an acid (where structural units corresponding to the structural unit (a01) being excluded).

The term “acid decomposable group” indicates a group in which at least a part of a bond in the structure of the acid decomposable group can be cleaved due to the action of an acid.

Examples of the acid decomposable group whose polarity is increased due to the action of an acid include groups which are decomposed due to the action of an acid to generate a polar group.

Examples of polar groups include a carboxy group, a hydroxyl group, an amino group, a sulfo group (—SO₃H), and the like. Among these, a polar group containing —OH in the structure thereof (hereinafter, also referred to as a “OH-containing polar group”) is preferable, a carboxy group or a hydroxyl group is more preferable, and a carboxy group is particularly preferable.

More specific examples of the acid decomposable group include a group in which the above-described polar group has been protected with an acid dissociable group (such as a group in which a hydrogen atom of the OH-containing polar group has been protected with an acid dissociable group).

Here, the “acid dissociable group” indicates both (i) group in which a bond between the acid dissociable group and an atom adjacent to the acid dissociable group can be cleaved due to the action of an acid; and (ii) group in which some bonds are cleaved due to the action of an acid, and then a decarboxylation reaction occurs, thereby cleaving the bond between the acid dissociable group and the atom adjacent to the acid dissociable group.

It is necessary that the acid dissociable group that constitutes the acid decomposable group is a group which exhibits a lower polarity than the polar group generated by the dissociation of the acid dissociable group. Thus, in a case where the acid dissociable group is dissociated by the action of an acid, a polar group exhibiting a higher polarity than that of the acid dissociable group is generated, thereby increasing the polarity. As a result, the polarity of the entire component (A1) is increased. By the increase in the polarity, relatively, the solubility in a developing solution changes, and the solubility in an alkali developing solution is increased, whereas the solubility in an organic developing solution is relatively decreased.

The acid dissociable group in the structural unit (a1) is an acid dissociable group excluding the acid dissociable group represented by General Formula (a01-r-1) or the acid dissociable group represented by General Formula (a01-r-2), and examples thereof include groups that have been proposed as acid dissociable groups of base resins for chemically amplified resist composition.

Specific examples of acid dissociable groups of the base resin for a known chemically amplified resist composition include an “acetal type acid dissociable group”, a “tertiary alkyl ester type acid dissociable group”, and a “tertiary alkyloxycarbonyl acid dissociable group” described below.

Acetal Type Acid Dissociable Group:

Examples of the acid dissociable group for protecting a carboxy group or a hydroxyl group as a polar group include the acid dissociable group represented by General Formula (a1-r-1) shown below (hereinafter, also referred to as “acetal type acid dissociable group”).

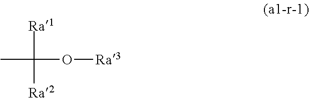

[In the Formula, Ra′¹ and Ra′² are a hydrogen atom or an alkyl group, Ra′³ is a hydrocarbon group, and Ra′³ may be bonded to any of Ra′¹ or Ra′² to form a ring.]

In General Formula (a1-r-1), it is preferable that at least one of Ra′¹ and Ra′² represents a hydrogen atom and more preferable that both of Ra′¹ and Ra′² represent a hydrogen atom.

In a case where Ra′¹ or Ra′² represents an alkyl group, examples of the alkyl group include the same alkyl groups exemplified as the substituent which may be bonded to the carbon atom at the α-position in the description on α-substituted acrylic acid ester. Among these, an alkyl group having 1 to 5 carbon atoms is preferable. Specific examples thereof preferably include linear or branched alkyl groups. Specific examples of the alkyl group preferably include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is preferable, and a methyl group is particularly preferable.

In General Formula (a1-r-1), examples of the hydrocarbon group as Ra′³ include a linear or branched alkyl group, or a cyclic hydrocarbon group.

The linear alkyl group preferably has 1 to 5 carbon atoms, more preferably has 1 to 4 carbon atoms, and still more preferably has 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group, and preferably include an isopropyl group.

In a case where Ra′³ represents a cyclic hydrocarbon group, the cyclic hydrocarbon group may be an aliphatic hydrocarbon group or an aromatic hydrocarbon group, and may be polycyclic or monocyclic.

As the monocyclic aliphatic hydrocarbon group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable, and the polycyclic group has preferably 7 to 12 carbon atoms, and specific examples of the polycycloalkane include adamantane, norbomane, isobomane, tricyclodecane, and tetracyclododecane.

In a case where the cyclic hydrocarbon group as Ra′³ becomes an aromatic hydrocarbon group, the aromatic hydrocarbon group is a hydrocarbon group having at least one aromatic ring.

The aromatic ring is not particularly limited as long as it is a cyclic conjugated system having (4n+2)π electrons, and may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms.

Specific examples of the aromatic ring include aromatic hydrocarbon rings such as benzene, naphthalene, anthracene, and phenanthrene; and aromatic hetero rings in which some carbon atoms constituting the above-described aromatic hydrocarbon rings have been substituted with hetero atoms. Examples of the hetero atom in the aromatic hetero rings include an oxygen atom, a sulfur atom and a nitrogen atom. Specific examples of the aromatic hetero ring include a pyridine ring and a thiophene ring.

Specific examples of the aromatic hydrocarbon group as Ra′³ include a group in which one hydrogen atom has been removed from the above-described aromatic hydrocarbon ring or aromatic hetero ring (an aryl group or a heteroaryl group); a group in which one hydrogen atom has been removed from an aromatic compound having two or more aromatic rings (biphenyl, fluorene or the like); and a group in which one hydrogen atom of the above-described aromatic hydrocarbon ring or aromatic hetero ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group which is bonded to the above-described aromatic hydrocarbon ring or aromatic hetero ring has preferably 1 to 4 carbon atoms, more preferably 1 or 2 carbon atoms, and particularly preferably 1 carbon atom.

The cyclic hydrocarbon group as Ra′³ may include a substituent. Examples of the substituent include —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are also collectively referred to as “Ra⁰⁵”).

Here, R^{P1} represents a chain-like monovalent saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. Further, R^{P2} represents a single bond, a chain-like divalent saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms.

Here, some or all hydrogen atoms in the chain-like saturated hydrocarbon group, the aliphatic cyclic saturated hydrocarbon group, and the aromatic hydrocarbon group as R^{P1} and R^{P2} may be substituted with fluorine atoms. The aliphatic cyclic hydrocarbon group may have one or more of one kind of substituents or one or more of each of plural kinds of the substituents.

Examples of the chain-like monovalent saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, or a cyclododecyl group; and a polycyclic aliphatic saturated hydrocarbon group such as a bicycle[2.2.2]octanyl group, a tricycle[5.2.1.02,6]decanyl group, a tricycle[3.3.1.13,7] decanyl group, a tetracyclo[6.2.1.13,6.02,7]dodecanyl group, or an adamantyl group.

Examples of the monovalent aromatic hydrocarbon group having 6 to 30 carbon atoms include a group formed by removing one hydrogen atom from an aromatic hydrocarbon ring, such as benzene, biphenyl, fluorene, naphthalene, anthracene, or phenanthrene.

In a case where Ra′³ is bonded to Ra′¹ or Ra′² to form a ring, the cyclic group is preferably a 4- to 7-membered ring, and more preferably a 4- to 6-membered ring. Specific examples of the cyclic group include a tetrahydropyranyl group and a tetrahydrofuranyl group.

Tertiary Alkyl Ester Type Acid Dissociable Group:

Examples of the acid dissociable group for protecting the carboxy group as a polar group include the acid dissociable group represented by General Formula (a1-r-2) shown below.

Among the acid dissociable groups represented by General Formula (a1-r-2), for convenience, a group which is constituted of alkyl groups is referred to as “tertiary alkyl ester type acid dissociable group”.

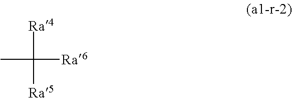

[In the formula, Ra′⁴ to Ra′⁶ each independently represent a hydrocarbon group, provided that Ra′⁵ and Ra′⁶ may be mutually bonded to form a ring.]

Examples of the hydrocarbon group as Ra′⁴ include a linear or branched alkyl group, a chain-like or cyclic alkenyl group, and a cyclic hydrocarbon group.

Examples of the linear or branched alkyl group and the cyclic hydrocarbon group (an aliphatic hydrocarbon group which is a monocyclic group, an aliphatic hydrocarbon group which is a polycyclic group, or an aromatic hydrocarbon group) as Ra′⁴ are the same as those exemplified above as Ra′³.

As the chain-like or cyclic alkenyl group as Ra′⁴, an alkenyl group having 2 to 10 carbon atoms is preferable.

Examples of the hydrocarbon group as Ra′⁵ or Ra′⁶ are the same as those exemplified above as Ra′³.

In a case where Ra′⁵ and Ra′⁶ are bonded to form a ring, preferable examples thereof include a group represented by General Formula (a1-r2-1), a group represented by General Formula (a1-r2-2), and a group represented by General Formula (a1-r2-3). Where, the acid dissociable group represented by (a01-r-1) or the acid dissociable group represented by General Formula (a01-r-2) is excluded from the examples.

Meanwhile, in a case where Ra′⁴ to Ra′⁶ are not bonded to one another and represent an independent hydrocarbon group, preferable examples thereof include a group represented by General Formula (a1-r2-4).

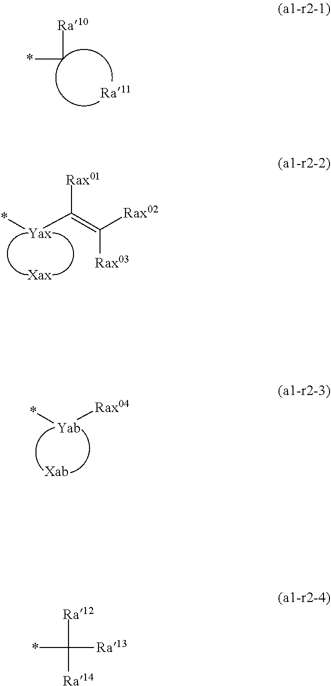

[In General Formula (a1-r2-1), Ra′¹⁰ represents an alkyl group having 1 to 10 carbon atoms or a group represented by General Formula (a1-r2-r1), and Ra′¹¹ represents a group that forms an aliphatic cyclic group together with a carbon atom to which Ra′¹⁰ is bonded; in General Formula (a1-r2-2), Yax is a carbon atom, Xax represents a group that forms a cyclic hydrocarbon group together with Yax, some or all hydrogen atoms in the chain-like saturated hydrocarbon group may be substituted, where the cyclic hydrocarbon group formed by Xax and Yax excludes an aliphatic monocyclic group having 3 to 5 carbon atoms, Rax⁰¹ to Rax⁰³ each independently represent a hydrogen atom, a chain-like monovalent saturated hydrocarbon group having 1 to 10 carbon atoms, or a monovalent aliphatic cyclic saturated hydrocarbon group having 3 to 20 carbon atoms, some or all hydrogen atoms in the chain-like saturated hydrocarbon group and the aliphatic cyclic saturated hydrocarbon group may be substituted, and two or more of Rax⁰¹ to Rax⁰³ may be bonded to one another to form a cyclic structure; in General Formula (a1-r2-3), Yab is a carbon atom, Xab represents a group that forms an aliphatic cyclic group together with Yab, where the aliphatic cyclic group to be formed by Xab and Yab excludes an aliphatic monocyclic group having 3 to 5 carbon atoms, and Rax⁰⁴ represents an aromatic hydrocarbon group which may have a substituent; and in General Formula (a1-r2-4), Ra′¹² and Ra′¹³ each independently represent a chain-like monovalent saturated hydrocarbon having 1 to 10 carbon atoms or a hydrogen atom, some or all hydrogen atoms in the chain-like saturated hydrocarbon group may be substituted, Ra′¹⁴ represents a hydrocarbon group which may have a substituent, and the symbol * represents a bonding site (hereinafter the same applies).]

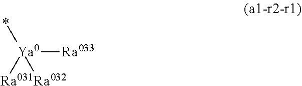

[In Formula, Ya⁰ is a quaternary carbon atom, and Ra⁰³¹, Ra⁰³², and Ra⁰³³ each independently represent a hydrocarbon group which may have a substituent, where one or more of Ra⁰³¹, Ra⁰³², and Ra⁰³³ are hydrocarbon groups having at least one polar group.]

In General Formula (a1-r2-1), as the alkyl group having 1 to 10 carbon atoms as Ra′¹⁰, a group exemplified as the linear or branched alkyl group represented by Ra′³ in General Formula (a1-r-1) is preferable. It is preferable that Ra′¹⁰ represents an alkyl group having 1 to 5 carbon atoms.

In Formula (a1-r2-r1), Ya⁰ represents a quaternary carbon atom. That is, there are four adjacent carbon atoms bonded to Ya⁰ (carbon atom).

In Formula (a1-r2-r1), Ra⁰³¹, Ra⁰³², and Ra⁰³³ each independently represent a hydrocarbon group which may have a substituent. Examples of hydrocarbon groups in Ra⁰³¹, Ra⁰³², and Ra⁰³³ each independently include a linear or branched alkyl group, a chain-like or cyclic alkenyl group, and a cyclic hydrocarbon group.

The linear alkyl group in Ra⁰³¹, Ra⁰³², and Ra⁰³³ preferably has 1 to 5 carbon atoms, more preferably has 1 to 4 carbon atoms, and still more preferably has 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group in Ra⁰³¹, Ra⁰³², and Ra⁰³³ preferably has 3 to 10 carbon atoms, and more preferably has 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group, and preferably include an isopropyl group.

The chain-like or cyclic alkenyl group in Ra⁰³¹, Ra⁰³², and Ra⁰³³ is preferably an alkenyl group having 2 to 10 carbon atoms.

A cyclic hydrocarbon group in Ra⁰³¹, Ra⁰³², and Ra⁰³³ may be an aliphatic hydrocarbon group or an aromatic hydrocarbon group, or may be a polycyclic group or a monocyclic group.

As the monocyclic aliphatic hydrocarbon group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable, and the polycyclic group has preferably 7 to 12 carbon atoms, and specific examples of the polycycloalkane include adamantane, norbomane, isobomane, tricyclodecane, and tetracyclododecane.

The aromatic hydrocarbon group in Ra⁰³¹, Ra⁰³², and Ra⁰³³ is a hydrocarbon group having at least one aromatic ring. The aromatic ring is not particularly limited as long as it is a cyclic conjugated system having (4n+2) nt electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic hetero rings in which some carbon atoms constituting the above-described aromatic hydrocarbon rings have been substituted with hetero atoms. Examples of the hetero atom in the aromatic hetero rings include an oxygen atom, a sulfur atom and a nitrogen atom. Specific examples of the aromatic hetero ring include a pyridine ring and a thiophene ring. Specific examples of the aromatic hydrocarbon group include a group in which one hydrogen atom has been removed from the above-described aromatic hydrocarbon ring or aromatic hetero ring (an aryl group or a heteroaryl group); a group in which one hydrogen atom has been removed from an aromatic compound having two or more aromatic rings (biphenyl, fluorene or the like); and a group in which one hydrogen atom of the above-described aromatic hydrocarbon ring or aromatic hetero ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group which is bonded to the above-described aromatic hydrocarbon ring or aromatic hetero ring has preferably 1 to 4 carbon atoms, more preferably 1 or 2 carbon atoms, and particularly preferably 1 carbon atom.

In a case where the hydrocarbon groups represented by Ra⁰³¹, Ra⁰³², and Ra⁰³³ are substituted, examples of substituents thereof include an alkyl group, a hydroxy group, a carboxy group, a halogen atom (such as a fluorine atom, a chlorine atom, or a bromine atom), an alkoxy group (such as a methoxy group, an ethoxy group, a propoxy group, or a butoxy group), an alkyloxycarbonyl group, and the like.

Among them, the hydrocarbon group which may have a substituent in Ra⁰³¹, Ra⁰³², and Ra⁰³³ is preferably a linear or branched alkyl group which may have a substituent, and is more preferably a linear alkyl group.

Where, one or more of Ra⁰³¹, Ra⁰³², and Ra⁰³³ are hydrocarbon groups having at least a polar group.

The “hydrocarbon group having a polar group” includes any of a hydrocarbon group in which a methylene group (—CH₂—) constituting the hydrocarbon group is substituted by a polar group, and a hydrocarbon group in which at least one hydrogen atom constituting the hydrocarbon group is substituted by a polar group.

Such a “hydrocarbon group having a polar group” is preferably a functional group represented by General Formula (a1-p1).

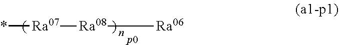

[In the formula, Ra⁰⁷ represents a divalent hydrocarbon group having 2 to 12 carbon atoms, Ra⁰⁸ represents a divalent linking group containing a hetero atom, Ra⁰⁶ represents a monovalent hydrocarbon group having 1 to 12 carbon atoms, and nₚ₀ is an integer of 1 to 6.]

In Formula (a1-p1), Ra⁰⁷ represents a divalent hydrocarbon group having 2 to 12 carbon atoms.

Ra⁰⁷ has 2 to 12 carbon atoms, preferably has 2 to 8 carbon atoms, more preferably has 2 to 6 carbon atoms, even more preferably has 2 to 4 carbon atoms, and particularly preferably has 2 carbon atoms.

The hydrocarbon group in Ra⁰⁷ is preferably a chain or cyclic aliphatic hydrocarbon group, and is more preferably a chain hydrocarbon group.

Examples of Ra⁰⁷'s include linear alkanediyl groups such an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, a undecane-1,11-diyl group, and a dodecane-1,12-diyl group; branched alkanediyl groups such as a propane-1,2-diyl group, a 1-methylbutane-1,3-diyl group, a 2-methylpropane-1,3-diyl group, a pentane-1,4-diyl group, and a 2-methylbutane-1,4-diyl group; cycloalkanediyl groups such as a cyclobutane-1,3-diyl group, a cyclopentane-1,3-diyl group, a cyclohexane-1,4-diyl group, and a cyclooctane-1,5-diyl group; polycyclic divalent alicyclic hydrocarbon groups such as a norbomane-1,4-diyl group, a norbomane-2,5-diyl group, an adamantane-1,5-diyl group, and an adamantane-2,6-diyl group; and the like.

Among them, an alkanediyl group is preferable, and a linear alkanediyl group is more preferable.

In Formula (a1-p1), Ra⁰⁸ represents a divalent linking group containing a hetero atom.

Examples of Ra⁰⁸'s include —O—, —C(═O)—O—, —C(═O)—, —O—C(═O)—O—, —C(═O)—NH—, —NH—, —NH—C(═NH)— (H may be substituted by a substituent such as an alkyl group and an acyl group), —S—, —S(═O)₂—, —S(═O)₂—O—, and the like.

Among them, —O—, —C(═O)—O—, —C(═O)—, and —O—C(═O)—O— are preferable, and —O— and —C(═O)— are particularly preferable from the viewpoint of solubility in a developing solution.

In Formula (a1-p1), Ra⁰⁶ represents a monovalent hydrocarbon group having 1 to 12 carbon atoms.

Ra⁰⁶ has 1 to 12 carbon atoms, preferably has 1 to 8 carbon atoms, more preferably has 1 to 5 carbon atoms, still more preferably has 1 to 3 carbon atoms, particularly preferably has 1 or 2 carbon atoms, and most preferably has 1 carbon atom from the viewpoint of solubility in a developing solution.

Examples of hydrocarbon groups in Ra⁰⁶ include a chain hydrocarbon group or a cyclic hydrocarbon group, or a hydrocarbon group in which a chain hydrocarbon group and a cyclic hydrocarbon group are combined.

Examples of chain hydrocarbon groups include a methyl group, an ethyl group, an n-propyl group, an isopropyl group, an n-butyl group, a sec-butyl group, a tert-butyl group, an n-pentyl group, an n-hexyl group, an n-heptyl group, a 2-ethylhexyl group, an n-octyl group, an n-nonyl group, an n-decyl group, an n-undecyl group, an n-dodecyl group, and the like.

The cyclic hydrocarbon group may be an alicyclic hydrocarbon group or an aromatic hydrocarbon group.

The alicyclic hydrocarbon group may be monocyclic or polycyclic, and examples of monocyclic alicyclic hydrocarbon groups include cycloalkyl groups such as a cyclopropyl group, a cyclobutyl group, a cyclopentyl group, a cyclohexyl group, a methylcyclohexyl group, a dimethylcyclohexyl group, a cycloheptyl group, a cyclooctyl group, a cycloheptyl group, a cyclodecyl group, and the like. Examples of polycyclic alicyclic hydrocarbon groups include a decahydronaphthyl group, an adamantyl group, a 2-alkyladamantan-2-yl group, a 1-(adamantan-1-yl) alkane-1-yl group, a norbomyl group, a methylnorbomyl group, an isobornyl group, and the like.

Examples of aromatic hydrocarbon groups include a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, a 2-methyl-6-ethylphenyl group, and the like.

Ra⁰⁶ is preferably a chain hydrocarbon group, is more preferably an alkyl group, and is still more preferably a linear alkyl group from the viewpoint of solubility in a developing solution.

In Formula (a1-p1), nₚ₀ is an integer of 1 to 6, is preferably an integer of 1 to 3, is more preferably an integer of 1 or 2, and is even more preferably an integer of 1.

Specific examples of hydrocarbon groups having at least a polar group are shown below.

In the formulae below, the symbol * is a bonding site bonded to a quaternary carbon atom (Ya⁰).

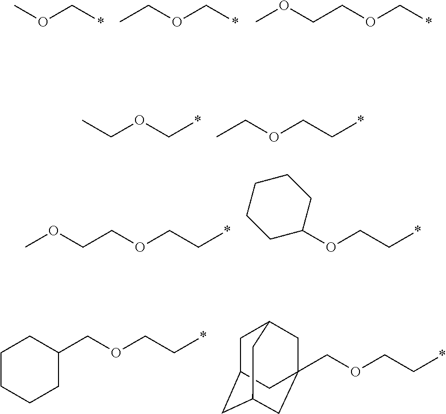

In Formula (a1-r2-r1), among Ra⁰³¹, Ra⁰³², and Ra⁰³³, the number of hydrocarbon groups having at least a polar group is one or more, but it may be appropriated determined in consideration of solubility in a developing solution during formation of a resist pattern. For example, the number thereof is preferably one or two and is particularly preferable one in Ra⁰³¹, Ra⁰³², and Ra⁰³³.

The hydrocarbon group having at least a polar group may have a substituent other than the polar group.

Examples of substituents thereof include a halogen atom (a fluorine atom, a chlorine atom, a bromine atom, and the like) and a halogenated alkyl group having 1 to 5 carbon atoms.

In General Formula (a1-r2-1), as the aliphatic cyclic group that is formed by Ra′¹¹ together with the carbon atom to which Ra′¹⁰ is bonded, a group exemplified as the aliphatic hydrocarbon group which is a monocyclic group or a polycyclic group as Ra′³ in General Formula (a1-r-1) is preferable.

In General Formula (a1-r2-2), as the cyclic hydrocarbon group that is formed by Xax together with Yax, a group formed by further removing one or more hydrogen atoms from the cyclic monovalent hydrocarbon group (an aliphatic hydrocarbon group) as Ra′³ in General Formula (a1-r-1) is exemplified. Where, the cyclic hydrocarbon group formed by Xax and Yax excludes an aliphatic monocyclic group having 3 to 5 carbon atoms.

The cyclic hydrocarbon group that is formed by Xax together with Yax may have a substituent. Examples of the substituent are the same as those exemplified as the substituents which may be included in the cyclic hydrocarbon group as Ra′³.

In General Formula (a1-r2-2), examples of the chain-like monovalent saturated hydrocarbon group having 1 to 10 carbon atoms as Rax⁰¹ to Rax⁰³ include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms as Rax⁰¹ to Rax⁰³ include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, or a cyclododecyl group; and a polycyclic aliphatic saturated hydrocarbon group such as a bicycle[2.2.2]octanyl group, a tricycle[5.2.1.02,6]decanyl group, a tricycle[3.3.1.13,7]decanyl group, a tetracyclo[6.2.1.13,6.02,7]dodecanyl group, or an adamantyl group.

From the viewpoint of easily synthesizing a monomer compound from which the structural unit (a1) is derived, it is preferable that Rax⁰¹ to Rax⁰³ represents a hydrogen atom or a chain-like monovalent saturated hydrocarbon group having 1 to 10 carbon atoms. Among these, a hydrogen atom, a methyl group, or an ethyl group is more preferable, and a hydrogen atom is particularly preferable.

Examples of the substituent included in the chain-like saturated hydrocarbon group or the aliphatic cyclic saturated hydrocarbon group represented by Rax⁰¹ to Rax⁰³ are the same as those exemplified as Ra⁰⁵.

Examples of the group having a carbon-carbon double bond generated by two or more of Rax⁰¹ to Rax⁰³ being bonded to one another to form a cyclic structure include a cyclopentenyl group, a cyclohexenyl group, a methylcyclopentenyl group, a methylcyclohexenyl group, a cyclopentylidenethenyl group, and a cyclohexylidenethenyl group. Among these, from the viewpoint of easily synthesizing a monomer compound from which the structural unit (a1) is derived, a cyclopentenyl group, a cyclohexenyl group, or a cyclopentylidenethenyl group is preferable.

In General Formula (a1-r2-3), as the aliphatic cyclic group that is formed by Xab together with Yab, a group exemplified as the aliphatic hydrocarbon group which is a monocyclic or polycyclic group as Ra′³ in General Formula (a1-r-1) is preferable. Where, the aliphatic cyclic group to be formed by Xab and Yab excludes an aliphatic monocyclic group having 3 to 5 carbon atoms.

In General Formula (a1-r2-3), examples of the aromatic hydrocarbon group as Rax⁰⁴ include a group formed by removing one or more hydrogen atoms from an aromatic hydrocarbon ring having 5 to 30 carbon atoms. Among the examples, Rax⁰⁴ represents preferably a group formed by removing one or more hydrogen atoms from an aromatic hydrocarbon ring having 6 to 15 carbon atoms, more preferably a group formed by removing one or more hydrogen atoms from benzene, naphthalene, anthracene, or phenanthrene, still more preferably a group formed by removing one or more hydrogen atoms from benzene, naphthalene, or anthracene, particularly preferably a group formed by removing one or more hydrogen atoms from benzene or naphthalene, and most preferably a group formed by removing one or more hydrogen atoms from benzene.

Examples of the substituent which may be included in Rax⁰⁴ in General Formula (a1-r2-3) include a methyl group, an ethyl group, a propyl group, a hydroxy group, a carboxyl group, a halogen atom (such as a fluorine atom, a chlorine atom, or a bromine atom), an alkoxy group (such as a methoxy group, an ethoxy group, a propoxy group, or a butoxy group), and an alkyloxycarbonyl group.

In General Formula (a1-r2-4), Ra′¹² and Ra′¹³ each independently represent a chain-like monovalent saturated hydrocarbon group having 1 to 10 carbon atoms or a hydrogen atom. Examples of the chain-like monovalent saturated hydrocarbon group having 1 to 10 carbon atoms as Ra′¹² and Ra′¹³ are the same as those exemplified as the chain-like monovalent saturated hydrocarbon group having 1 to 10 carbon atoms as Ra⁰¹ to Ra⁰³. Some or all hydrogen atoms in the chain-like saturated hydrocarbon group may be substituted.

Ra′¹² and Ra′¹³ represent preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon group represented by Ra′¹² and Ra′¹³ is substituted, examples of the substituent are the same as those exemplified as Ra⁰⁵.

In General Formula (a1-r2-4), Ra′¹⁴ represents a hydrocarbon group which may have a substituent. Examples of hydrocarbon groups in Ra′¹⁴ include a linear or branched alkyl group, or a cyclic hydrocarbon group.

The linear alkyl group in Ra′¹⁴ preferably has 1 to 5 carbon atoms, more preferably has 1 to 4 carbon atoms, and still more preferably has 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group in Ra′¹⁴ preferably has 3 to 10 carbon atoms, and more preferably has 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group, and preferably include an isopropyl group.

In a case where Ra′¹⁴ represents a cyclic hydrocarbon group, the cyclic hydrocarbon group may be an aliphatic hydrocarbon group or an aromatic hydrocarbon group, and may be polycyclic or monocyclic.

As the monocyclic aliphatic hydrocarbon group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable, and the polycyclic group has preferably 7 to 12 carbon atoms, and specific examples of the polycycloalkane include adamantane, norbomane, isobomane, tricyclodecane, and tetracyclododecane.

Examples of the aromatic hydrocarbon group as Ra′¹⁴ are the same as those exemplified as the aromatic hydrocarbon group as Ra⁰⁴. Among these, Ra′¹⁴ represents preferably a group formed by removing one or more hydrogen atoms from an aromatic hydrocarbon ring having 6 to 15 carbon atoms, more preferably a group formed by removing one or more hydrogen atoms from benzene, naphthalene, anthracene, or phenanthrene, still more preferably a group formed by removing one or more hydrogen atoms from benzene, naphthalene, or anthracene, particularly preferably a group formed by removing one or more hydrogen atoms from naphthalene or anthracene, and most preferably a group formed by removing one or more hydrogen atoms from naphthalene.

Examples of the substituent which may be included in Ra′¹⁴ are the same as those exemplified as the substituent which may be included in Rax⁰⁴.

In a case where Ra′¹⁴ in General Formula (a1-r2-4) represents a naphthyl group, the position bonded to the tertiary carbon atom in General Formula (a1-r2-4) may be the first position or the second position of the naphthyl group.

In a case where Ra′¹⁴ in General Formula (a1-r2-4) represents an anthryl group, the position bonded to the tertiary carbon atom in General Formula (a1-r2-4) may be the first position, the second position, or the ninth position of the anthryl group.

Specific examples of the group represented by General Formula (a1-r2-1) are shown below.

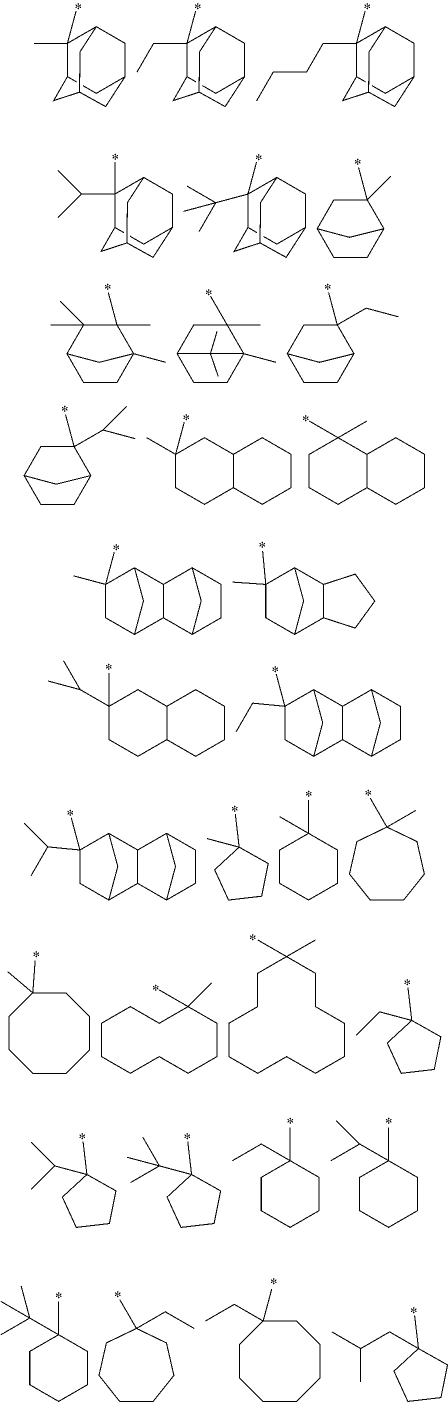

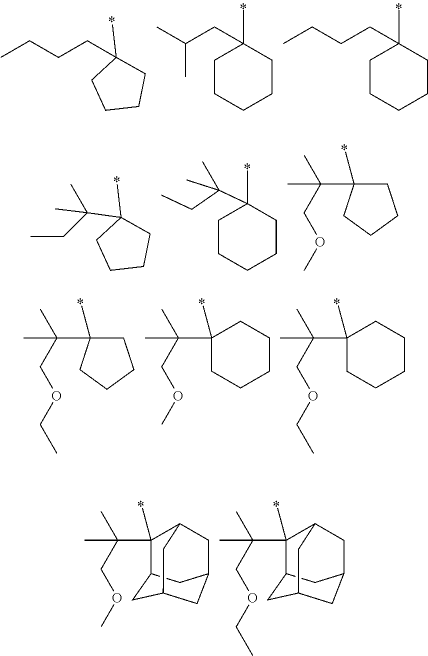

Specific examples of the group represented by General Formula (a1-r2-2) are shown below.

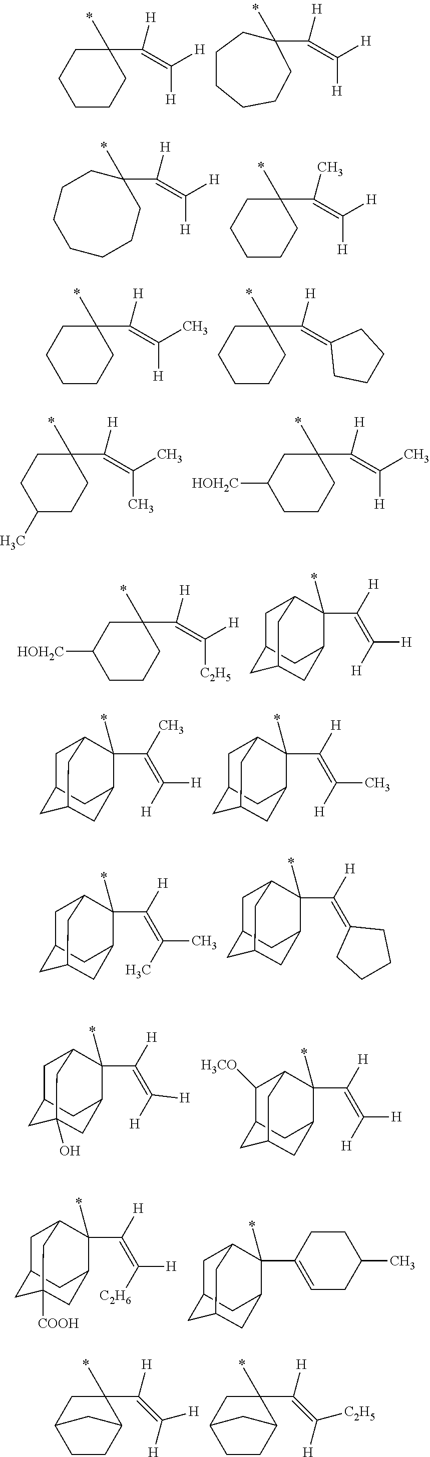

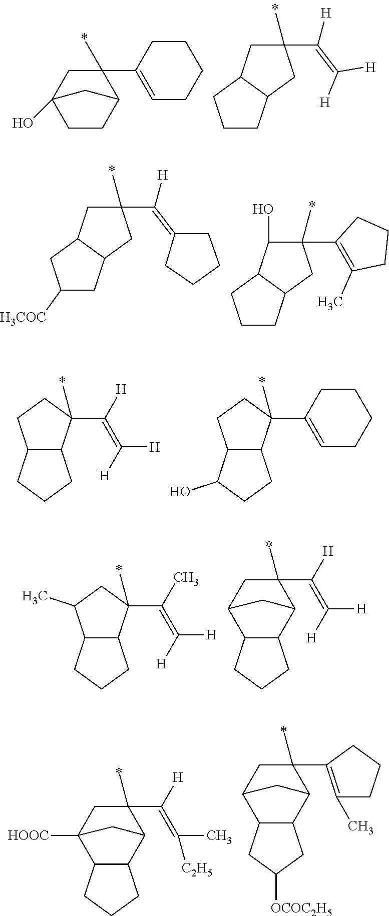

Specific examples of the group represented by General Formula (a1-r2-3) are shown below.

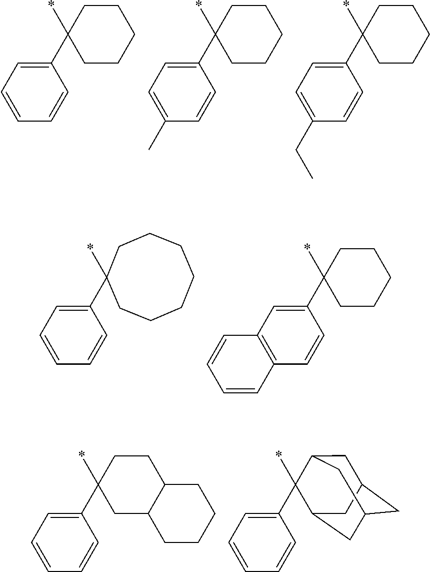

Specific examples of the group represented by General Formula (a1-r2-4) are shown below.

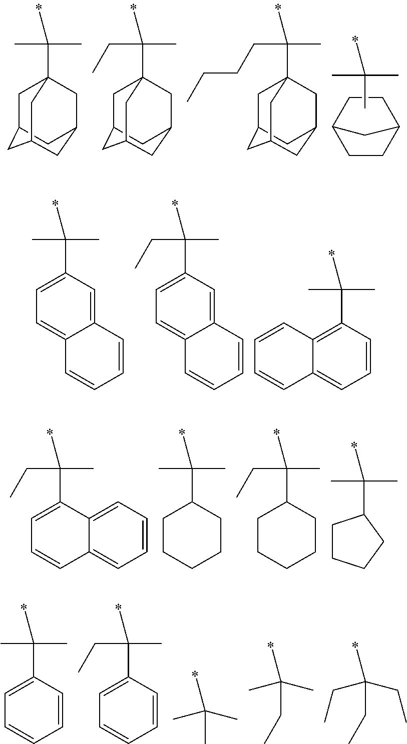

Tertiary alkyloxycarbonyl acid dissociable group:

Examples of the acid dissociable group for protecting a hydroxyl group as a polar group include an acid dissociable group (hereinafter, for convenience, also referred to as “tertiary alkyloxycarbonyl acid dissociable group”) represented by General Formula (a1-r-3) shown below.

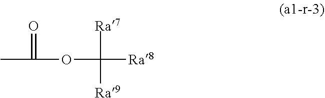

[In the formula, Ra′⁷ to Ra′⁹ each independently represent an alkyl group.]

In General Formula (a1-r-3), Ra′⁷ to Ra′⁹ are each preferably an alkyl group having 1 to 5 carbon atoms, and more preferably an alkyl group having 1 to 3 carbon atoms.

Further, the total number of carbon atoms in each alkyl group is preferably in a range of 3 to 7, more preferably in a range of 3 to 5, and most preferably 3 or 4.

Examples of the structural unit (a1) include a structural unit derived from acrylic acid ester in which the hydrogen atom bonded to the carbon atom at the α-position may be substituted with a substituent; a structural unit derived from acrylamide; a structural unit in which at least some hydrogen atoms in a hydroxyl group of a structural unit derived from hydroxystyrene or a hydroxystyrene derivative are protected by a substituent containing the acid decomposable group; and a structural unit in which at least some hydrogen atoms in —C(═O)—OH of a structural unit derived from vinylbenzoic acid or a vinylbenzoic acid derivative are protected by a substituent containing the acid decomposable group.

Among the examples, as the structural unit (a1), a structural unit derived from acrylic acid ester in which the hydrogen atom bonded to the carbon atom at the α-position may be substituted with a substituent is preferable.

Specific preferable examples of such a structural unit (a1) include structural units represented by General Formula (a1-1) or (a1-2) shown below.

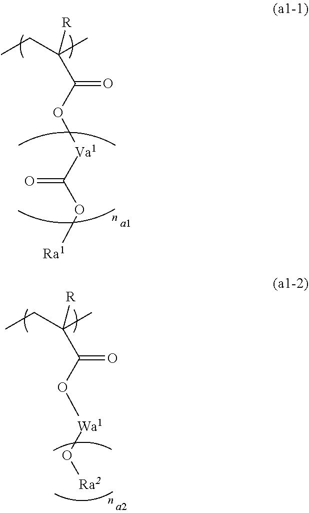

[In the formulae, R represents a hydrogen atom, an alkyl group having 1 to 5 carbon atoms, or a halogenated alkyl group having 1 to 5 carbon atoms. Va¹ is a divalent hydrocarbon group which may have an ether bond, nₐ₁ represents an integer of 0 to 2. Ra¹ is an acid dissociable group represented by General Formula (a1-r-1) or (a1-r-2). Wa¹ represents a (nₐ₂+1)-valent hydrocarbon group, nₐ₂ represents an integer of 1 to 3, and Ra² represents an acid dissociable group represented by General Formula (a1-r-1) or (a1-r-3)].

In General Formula (a1-1), as the alkyl group having 1 to 5 carbon atoms as R, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms of the above-described alkyl group having 1 to 5 carbon atoms have been substituted with halogen atoms. Examples of the halogen atom include a fluorine atom, a chlorine atom, a bromine atom and an iodine atom, and a fluorine atom is particularly preferable.

R represents preferably a hydrogen atom, an alkyl group having 1 to 5 carbon atoms, or a fluorinated alkyl group having 1 to 5 carbon atoms and particularly preferably a hydrogen atom or a methyl group from the viewpoint of industrial availability.

In General Formula (a1-1), the divalent hydrocarbon group as Va¹ may be an aliphatic hydrocarbon group or an aromatic hydrocarbon group.

The aliphatic hydrocarbon group as a divalent hydrocarbon group represented by Va¹ may be saturated or unsaturated. In general, it is preferable that the aliphatic hydrocarbon group is saturated.

As specific examples of the aliphatic hydrocarbon group, a linear or branched aliphatic hydrocarbon group, and an aliphatic hydrocarbon group containing a ring in the structure thereof.

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

As the branched aliphatic hydrocarbon group, a branched alkylene group is preferred, and specific examples include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group in the alkylalkylene group, a linear alkyl group having 1 to 5 carbon atoms is preferable.

Examples of the aliphatic hydrocarbon group containing a ring in the structure thereof include an alicyclic hydrocarbon group (a group in which two hydrogen atoms have been removed from an aliphatic hydrocarbon ring), a group in which the alicyclic hydrocarbon group is bonded to the terminal of the above-described linear or branched aliphatic hydrocarbon group, and a group in which the alicyclic hydrocarbon group is interposed in the above-described linear or branched aliphatic hydrocarbon group. The linear or branched aliphatic hydrocarbon group is the same as defined for the above-described linear aliphatic hydrocarbon group or the above-described branched aliphatic hydrocarbon group.

The alicyclic hydrocarbon group has preferably 3 to 20 carbon atoms and more preferably 3 to 12 carbon atoms.

The alicyclic hydrocarbon group may be monocyclic or polycyclic. As the monocyclic alicyclic hydrocarbon group, a group in which two hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which two hydrogen atoms have been removed from a polycycloalkane is preferable. As the polycycloalkane, a group having 7 to 12 carbon atoms is preferable. Specific examples of the polycycloalkane include adamantane, norbornane, isobomane, tricyclodecane, and tetracyclododecane.

The aromatic hydrocarbon group as the divalent hydrocarbon group represented by Va¹ is a hydrocarbon group having an aromatic ring.

The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. Here, the number of carbon atoms in a substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and aromatic hetero rings in which some carbon atoms constituting the above-described aromatic hydrocarbon rings have been substituted with hetero atoms. Examples of the hetero atom in the aromatic hetero rings include an oxygen atom, a sulfur atom and a nitrogen atom.

Specific examples of the aromatic hydrocarbon group include a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (a group formed by removing one more hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

In General Formula (a1-1), Ra¹ represents an acid dissociable group represented by General Formula (a1-r-1) or (a1-r-2).

In Formula (a1-2), the (nₐ₂+1)-valent hydrocarbon group as Wa¹ may be an aliphatic hydrocarbon group or an aromatic hydrocarbon group. The aliphatic hydrocarbon group indicates a hydrocarbon group that has no aromaticity, and may be saturated or unsaturated, but is preferably saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof.

The valency of nₐ₂+1 is preferably divalent, trivalent or tetravalent, and divalent or trivalent is more preferable.

In Formula (a1-2), Ra2 represents an acid dissociable group represented by General Formula (a1-r-1) or (a1-r-3).

Specific examples of the structural unit represented by General Formula (a1-1) are shown below. In each formula, R^{α} represents a hydrogen atom, a methyl group, or a trifluoromethyl group.

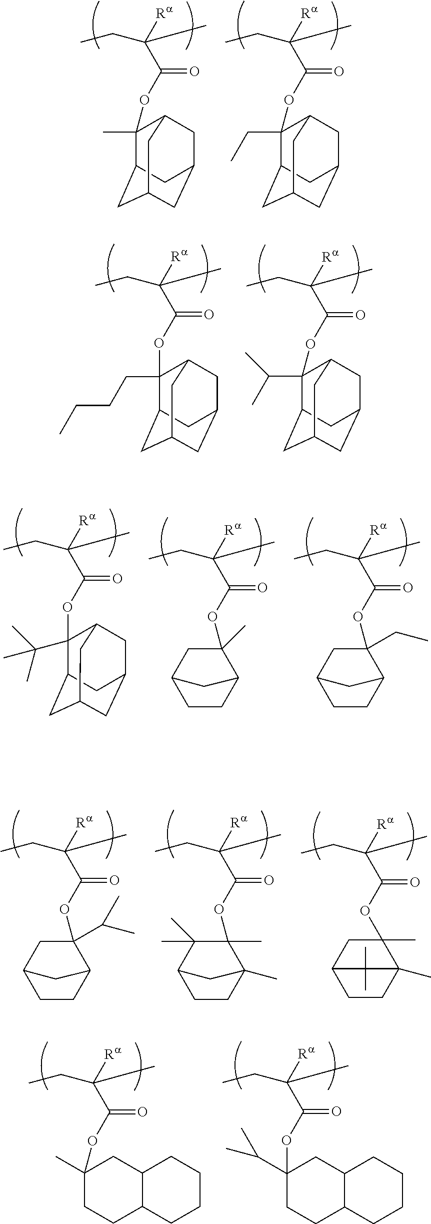

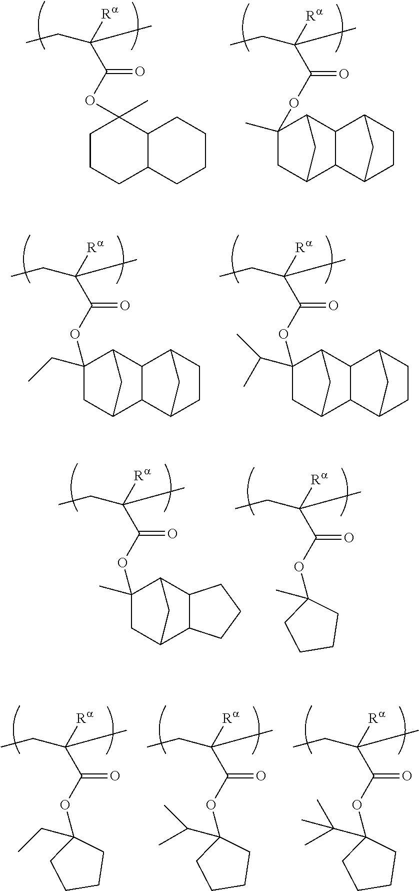

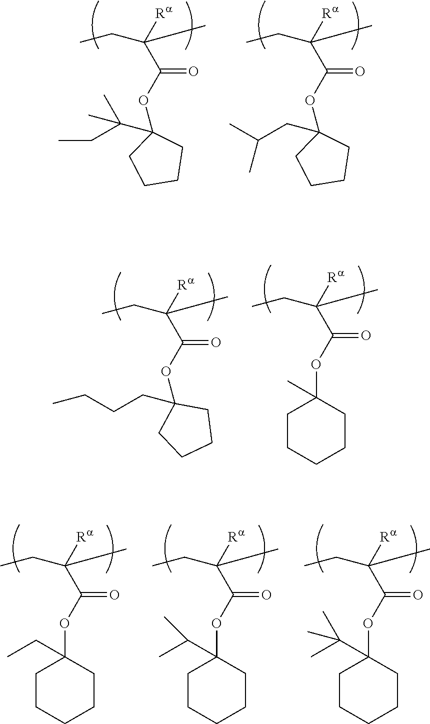

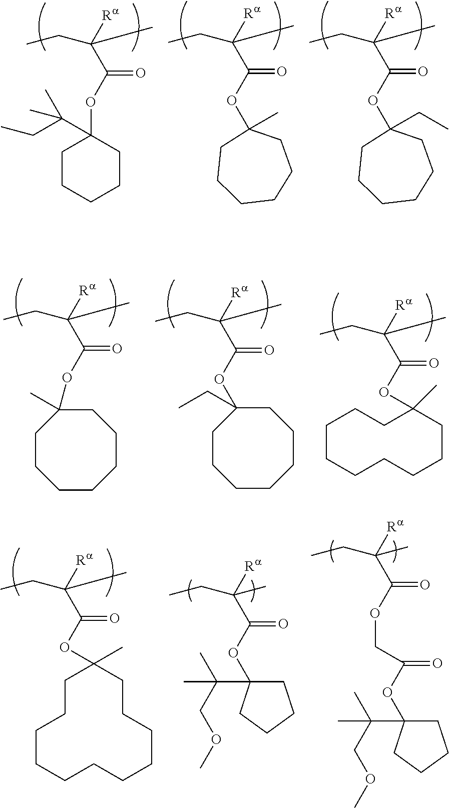

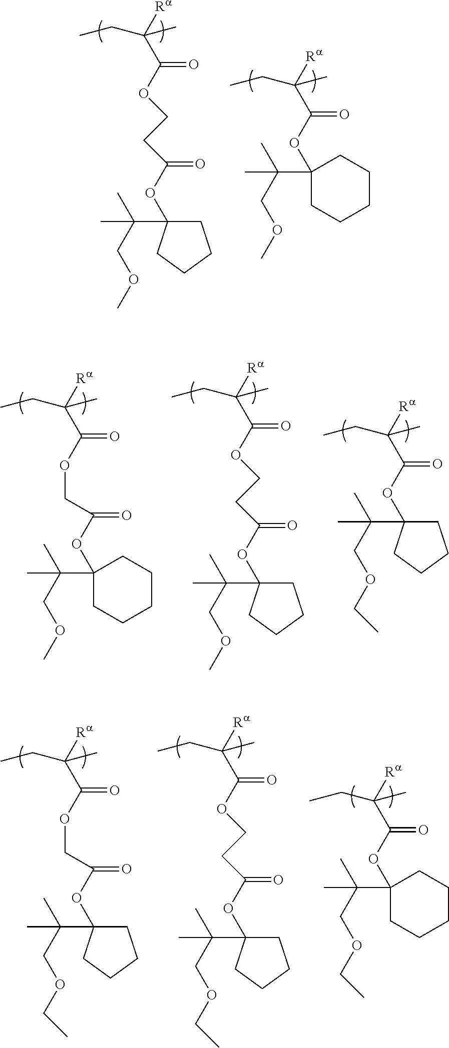

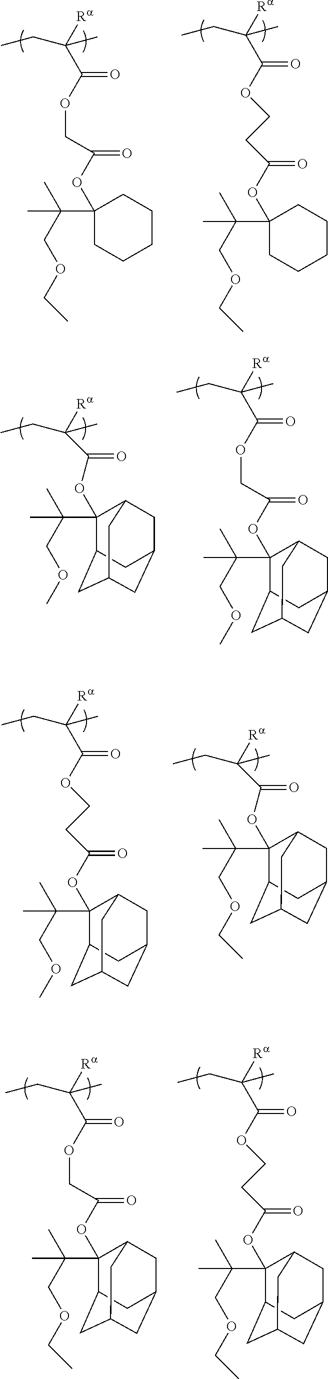

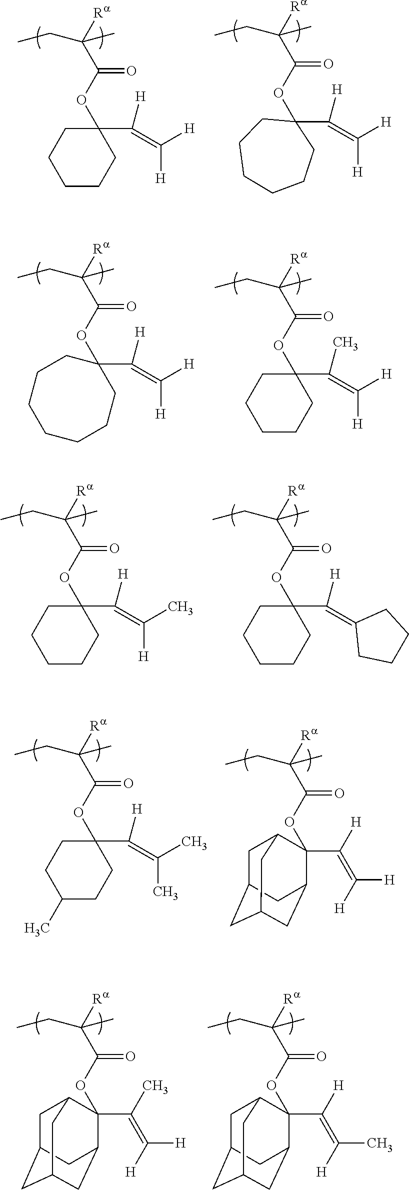

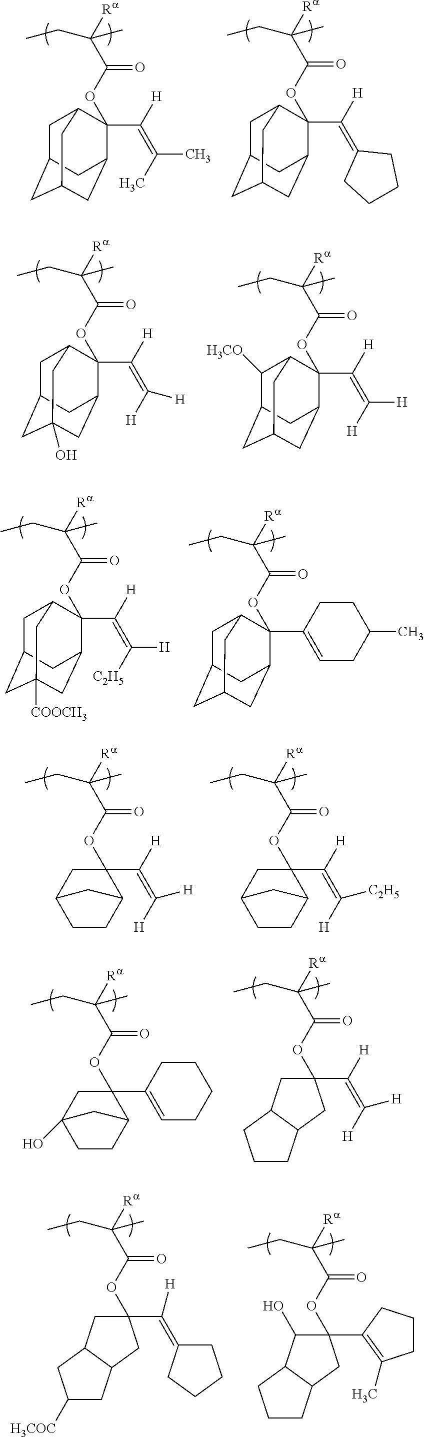

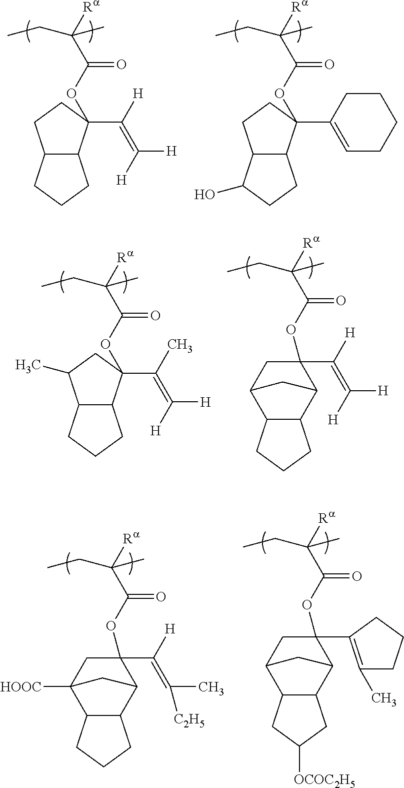

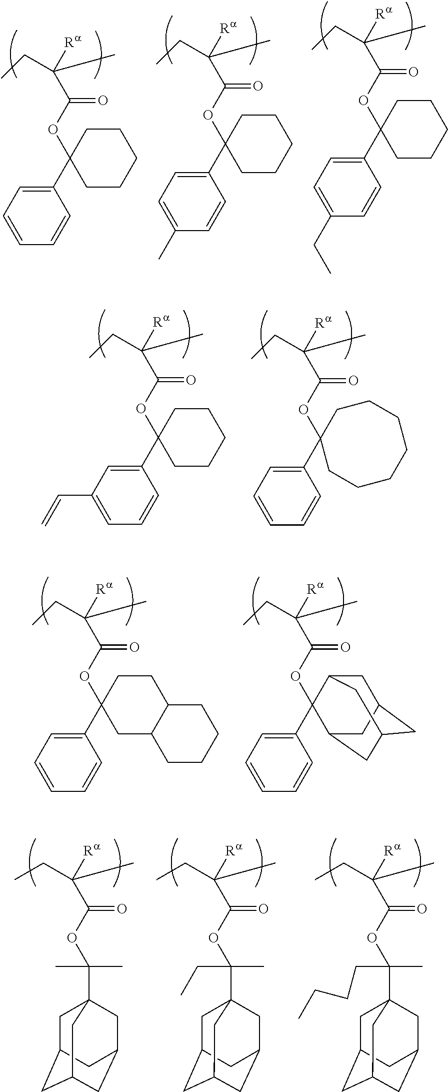

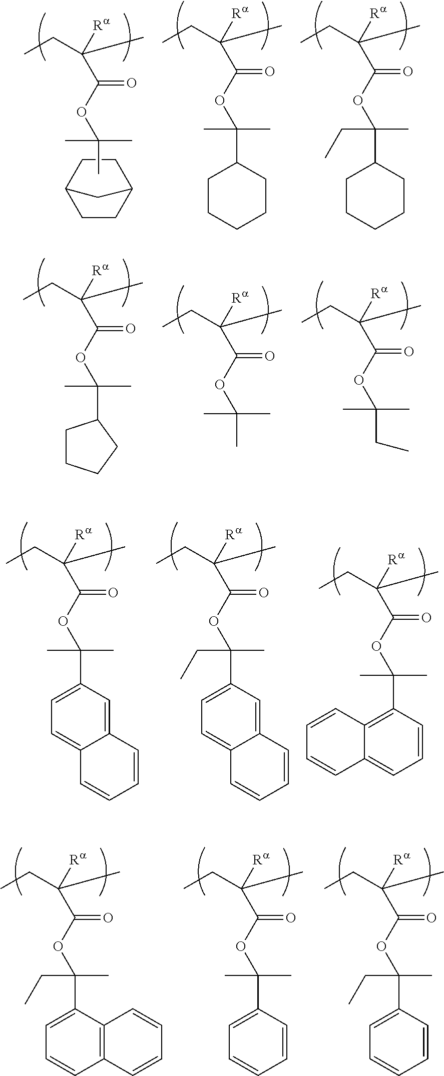

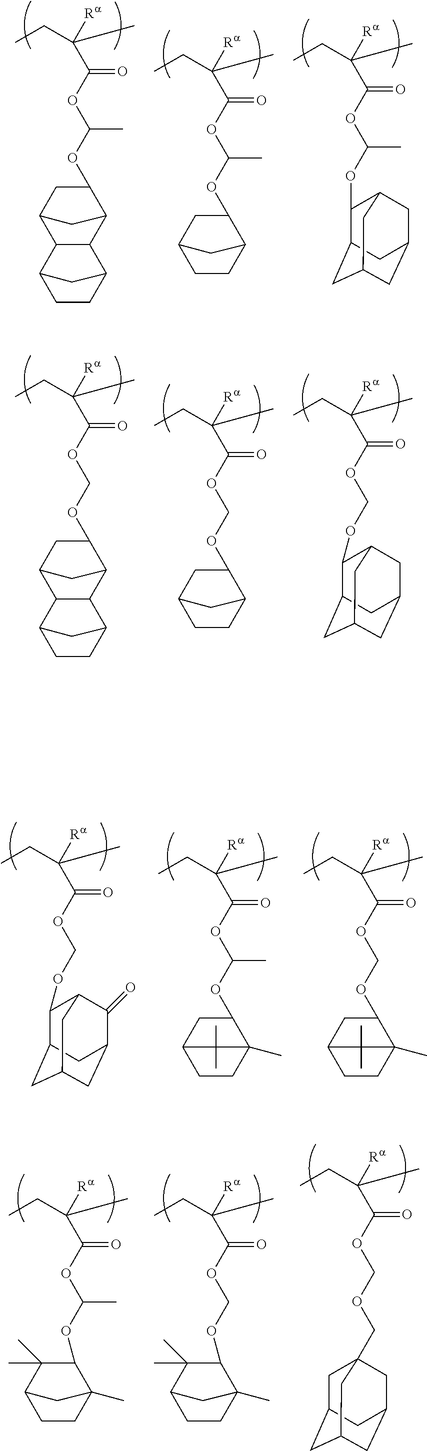

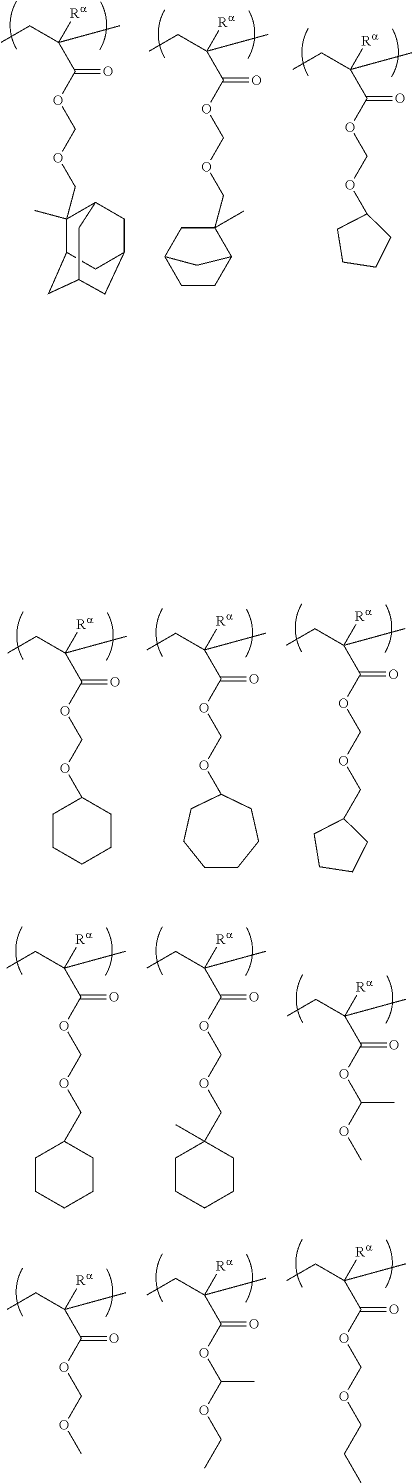

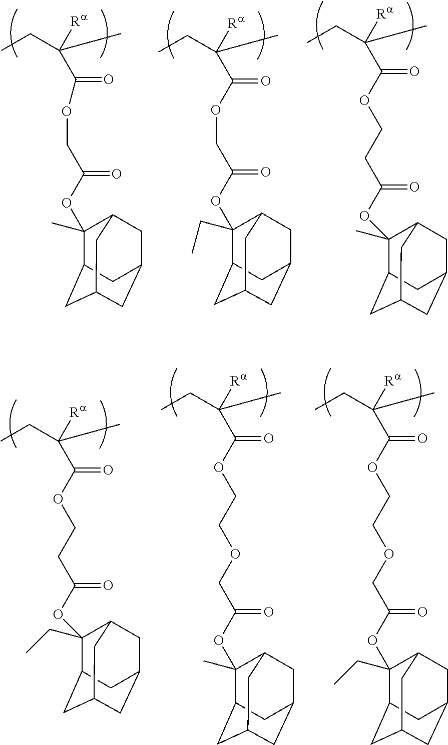

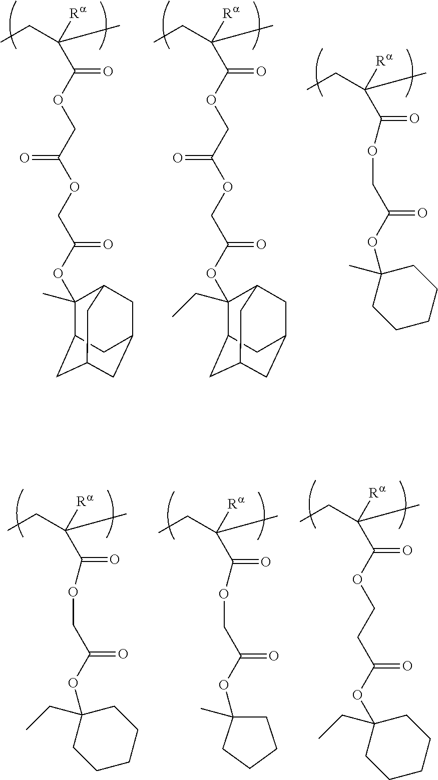

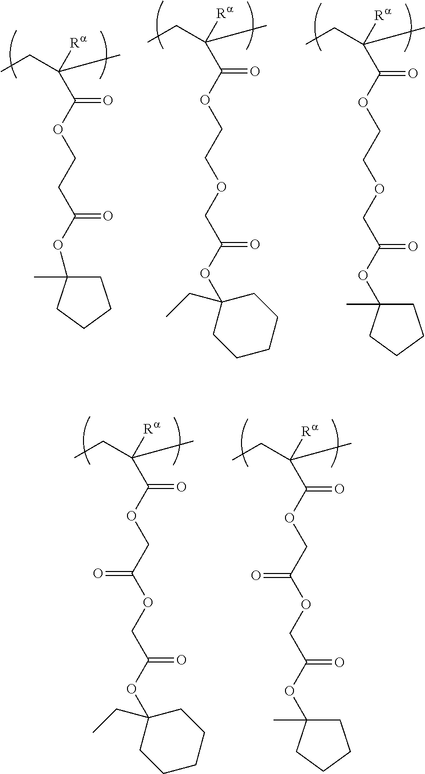

Specific examples of the structural unit represented by Formula (a1-2) are shown below.

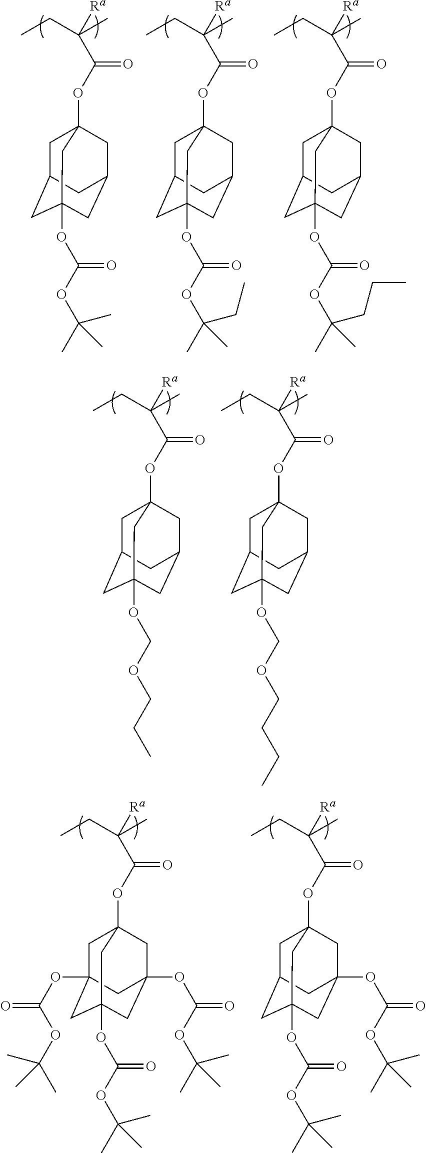

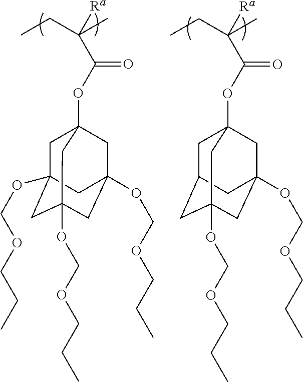

The component (A1) may have one or two or more kinds of structural units (a1).

As the structural unit (a1), the structural unit represented by General Formula (a1-1) is more preferable because the characteristics (sensitivity, shape, and the like) in lithography by electron beam or EUV can be further improved.

Structural Unit (a2):

In addition to the structural unit (a01), the structural unit (a02), and the structural unit (a03), the component (A1) may further include a structural unit (a2) containing a lactone-containing cyclic group, an —SO₂-containing cyclic group, or a carbonate-containing cyclic group (excluding structural units corresponding to the structural unit (a1) and the structural unit (a01)).

In a case where the component (A1) is used for forming a resist film, the lactone-containing cyclic group, the —SO₂-containing cyclic group, or the carbonate-containing cyclic group in the structural unit (a2) is effective for improving the adhesiveness of the resist film to the substrate. In addition, by incorporating the structural unit (a2), the lithography characteristics become favorable due to effects of, for example, appropriately adjusting an acid diffusion length, improving adhesiveness of a resist film to a substrate, appropriately adjusting a solubility during development, and the like.

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as a monocyclic group. Further, in a case where the group has other ring structures, the group is referred to as a polycyclic group regardless of the structures. The lactone-containing cyclic group may be a monocyclic group or a polycyclic group.

The lactone-containing cyclic group for the structural unit (a2) is not particularly limited, and an optional structural unit may be used. Specific examples thereof include groups represented by General Formulae (a2-r-1) to (a2-r-7) shown below.

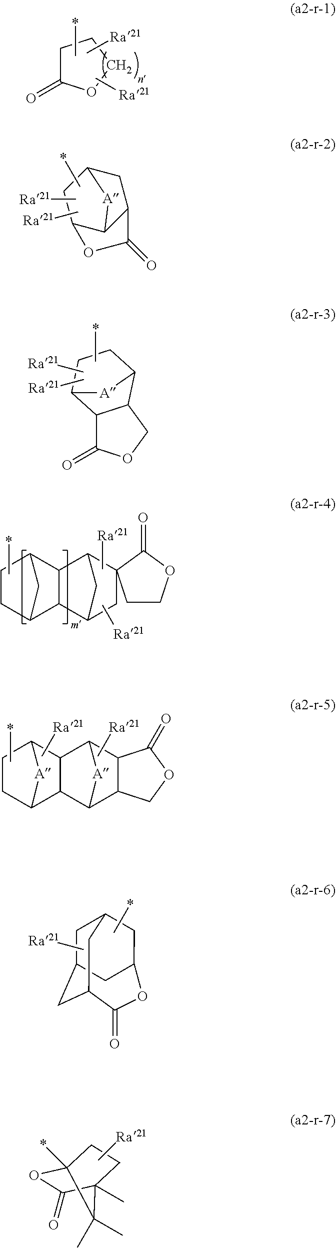

[In the formulae, each Ra′²¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; and R″ represents a hydrogen atom, an alkyl group, a lactone-containing cyclic group, a carbonate-containing cyclic group, or a —SO₂-containing cyclic group; A″ represents an oxygen atom (—O—), a sulfur atom (—S—) or an alkylene group having 1 to 5 carbon atoms which may contain an oxygen atom or a sulfur atom; n′ represents an integer of 0 to 2; and m′ represents 0 or 1.]

In General Formulae (a2-r-1) to (a2-r-7), the alkyl group as Ra′²¹ is preferably an alkyl group having 1 to 6 carbon atoms. Further, the alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly preferable.

The alkoxy group as Ra′²¹ is preferably an alkoxy group having 1 to 6 carbon atoms.

Further, the alkoxy group is preferably a linear or branched alkoxy group. Specific examples of the alkoxy groups include a group formed by linking the above-described alkyl group as Ra′²¹ to an oxygen atom (—O—).

Examples of the halogen atom as Ra′²¹ include a fluorine atom, a chlorine atom, a bromine atom, and an iodine atom. Among these, a fluorine atom is preferable.

Examples of the halogenated alkyl group as Ra′²¹ include groups in which some or all hydrogen atoms in the above-described alkyl group as Ra′²¹ have been substituted with the above-described halogen atoms. As the halogenated alkyl group, a fluorinated alkyl group is preferable, and a perfluoroalkyl group is particularly preferable.

In —COOR″ and —OC(═O)R″ as Ra′²¹, R″ represents a hydrogen atom, an alkyl group, a lactone-containing cyclic group, a carbonate-containing cyclic group, or a —SO₂-containing cyclic group.

The alkyl group as R″ may be linear, branched, or cyclic, and preferably has 1 to 15 carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the number of carbon atoms thereof is preferably in a range of 3 to 15, more preferably in a range of 4 to 12, and most preferably in a range of 5 to 10. Specific examples thereof include groups in which one or more hydrogen atoms have been removed from a monocycloalkane, which may or may not be substituted with a fluorine atom or a fluorinated alkyl group; and groups in which one or more hydrogen atoms have been removed from a polycycloalkane such as bicycloalkane, tricycloalkane, or tetracycloalkane. More specific examples thereof include groups in which one or more hydrogen atoms have been removed from a monocycloalkane such as cyclopentane or cyclohexane; and groups in which one or more hydrogen atoms have been removed from a polycycloalkane such as adamantane, norbomane, isobomane, tricyclodecane, or tetracyclododecane.

Examples of the lactone-containing cyclic group as R″ include those exemplified as the groups represented by General Formulae (a2-r-1) to (a2-r-7).

The carbonate-containing cyclic group as R″ has the same definition as that for the carbonate-containing cyclic group described below. Specific examples of the carbonate-containing cyclic group include groups represented by General Formulae (ax3-r-1) to (ax3-r-3).

The —SO₂-containing cyclic group as R″ has the same definition as that for the —SO₂-containing cyclic group described below. Specific examples of the —SO₂-containing cyclic group include groups represented by General Formulae (a5-r-1) to (a5-r-4).

The hydroxyalkyl group as Ra′²¹ has preferably 1 to 6 carbon atoms, and specific examples thereof include a group in which at least one hydrogen atom in the alkyl group as Ra′²¹ has been substituted with a hydroxyl group.

In General Formulae (a2-r-2), (a2-r-3) and (a2-r-5), as the alkylene group having 1 to 5 carbon atoms as A″, a linear or branched alkylene group is preferable, and examples thereof include a methylene group, an ethylene group, an n-propylene group, and an isopropylene group. Examples of alkylene groups that contain an oxygen atom or a sulfur atom include groups in which —O— or —S— is interposed in the terminal of the alkylene group or between the carbon atoms of the alkylene group, and examples thereof include —O—CH₂—, —CH₂—O—CH₂—, —S—CH₂—, and —CH₂—S—CH₂—. As A″, an alkylene group having 1 to 5 carbon atoms or —O— is preferable, an alkylene group having 1 to 5 carbon atoms is more preferable, and a methylene group is most preferable.

Specific examples of the groups represented by General Formulae (a2-r-1) to (a2-r-7) are shown below.

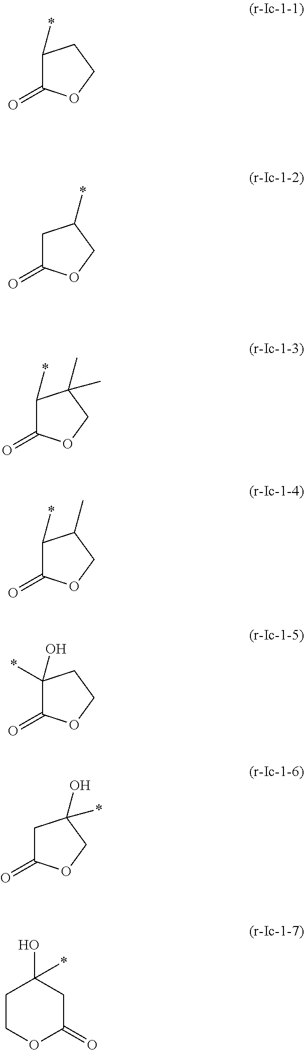

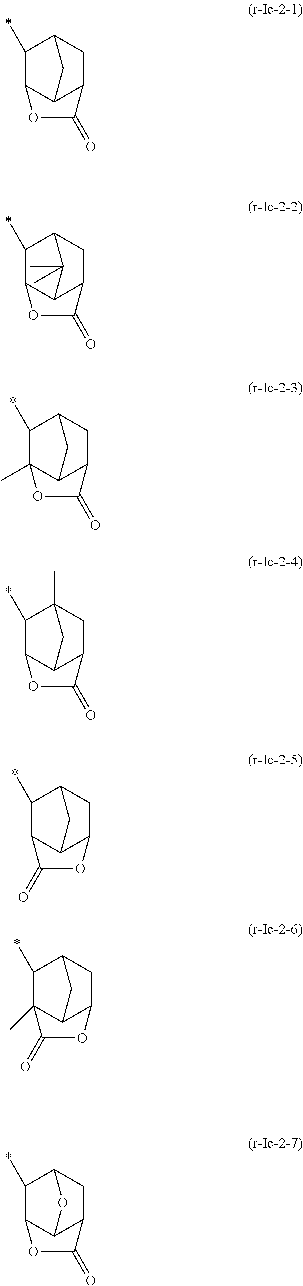

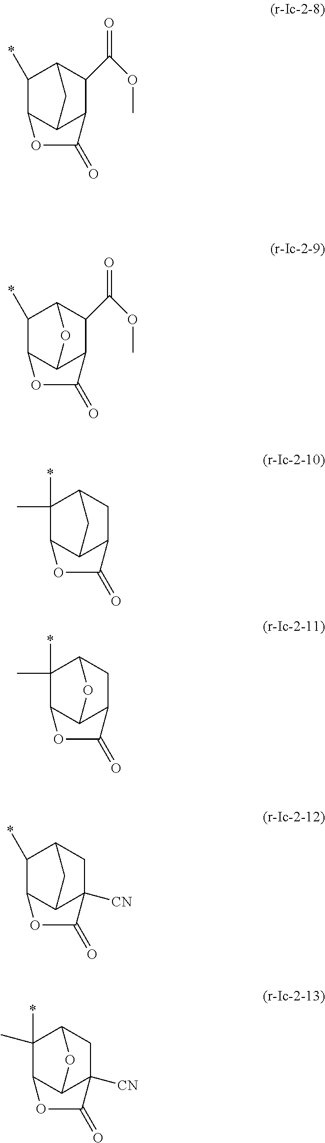

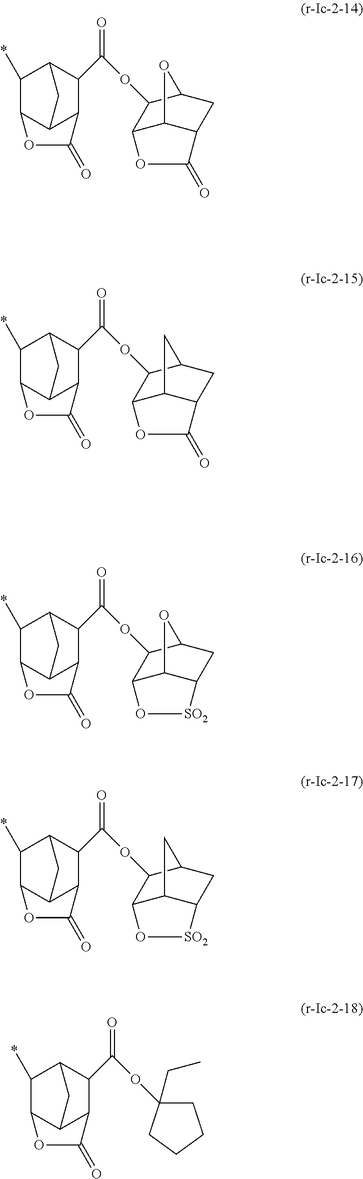

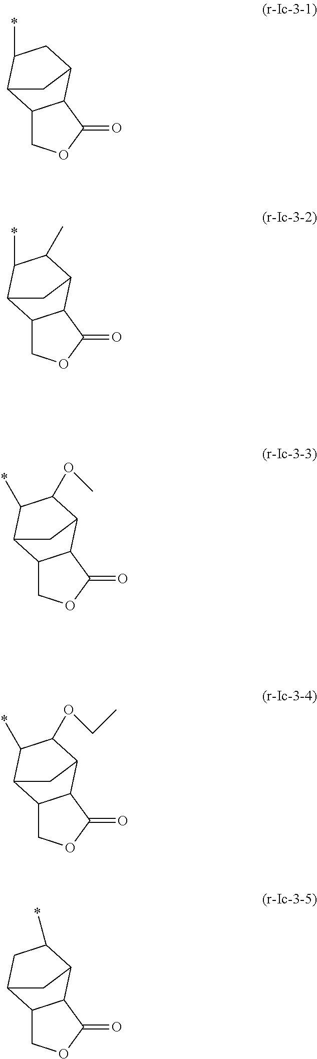

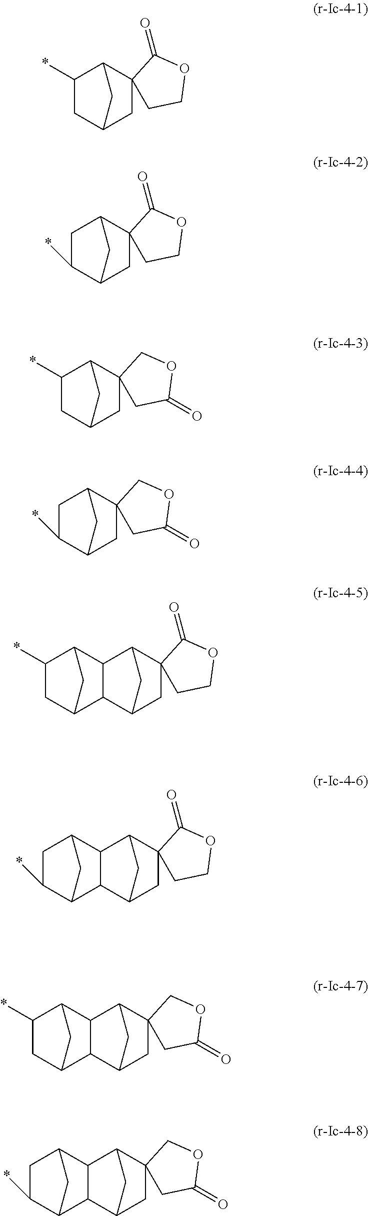

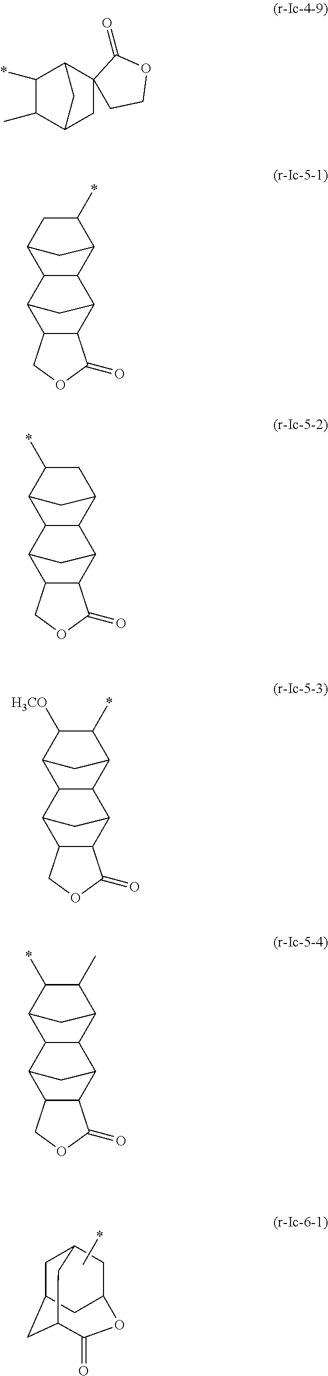

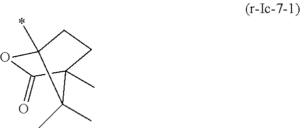

The “—SO₂-containing cyclic group” indicates a cyclic group having a ring containing —SO₂— in the ring skeleton thereof. Specifically, the —SO₂-containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as a monocyclic group. Further, in a case where the group has other ring structures, the group is referred to as a polycyclic group regardless of the structures. The —SO₂-containing cyclic group may be a monocyclic group or a polycyclic group.

As the —SO₂-containing cyclic group, a cyclic group containing —O—SO₂— in the ring skeleton thereof, in other words, a cyclic group containing a sultone ring in which —O—S— in the —O—SO₂— group forms a part of the ring skeleton thereof is particularly preferable.

More specific examples of the —SO₂-containing cyclic group include groups represented by General Formulae (a5-r-1) to (a5-r-4) shown below.

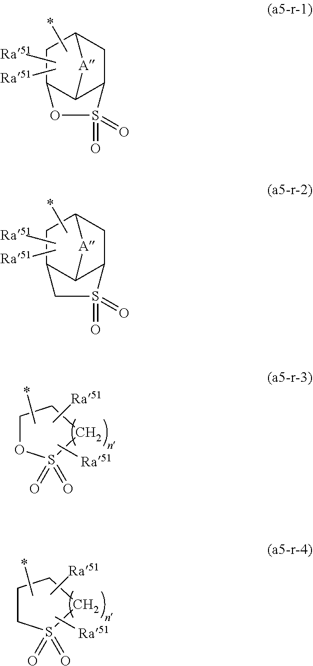

[In the formulae, each Ra′⁵¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group. R″ represents a hydrogen atom, an alkyl group, a lactone-containing cyclic group, a carbonate-containing cyclic group, or a —SO₂-containing cyclic group. A″ represents an oxygen atom, a sulfur atom or an alkylene group having 1 to 5 carbon atoms which may contain an oxygen atom or a sulfur atom. n′ represents an integer of 0 to 2.]

In General Formulae (a5-r-1) and (a5-r-2), A″ has the same definition as that for A″ in Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′⁵¹ include the same groups as those described above in the explanation of Ra′²¹ in General Formulae (a2-r-1) to (a2-r-7).

Specific examples of the groups represented by General Formulae (a5-r-1) to (a5-r-4) are shown below. In the formulae shown below, “Ac” represents an acetyl group.

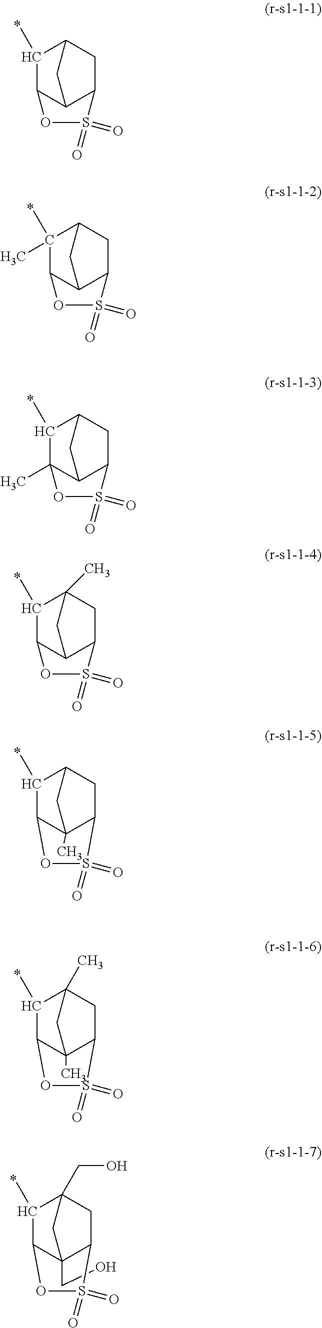

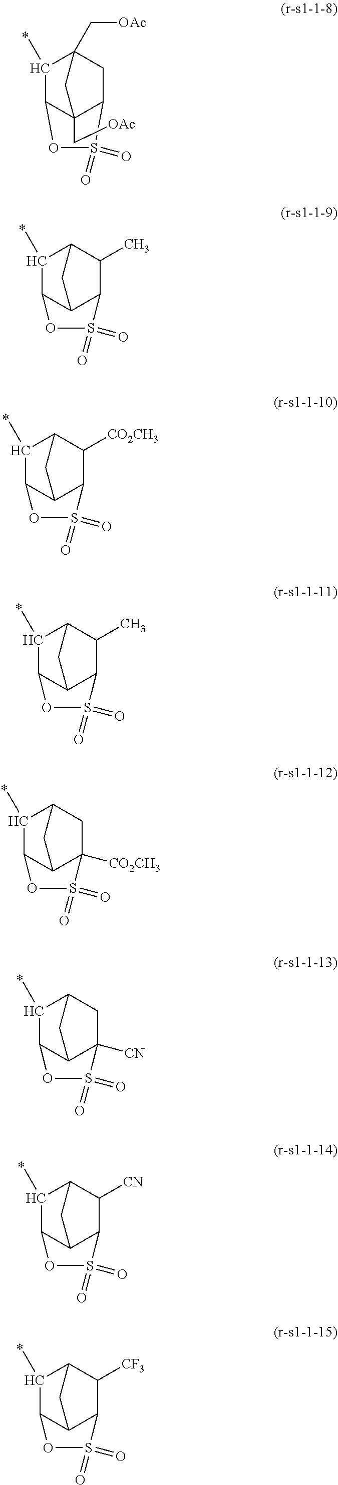

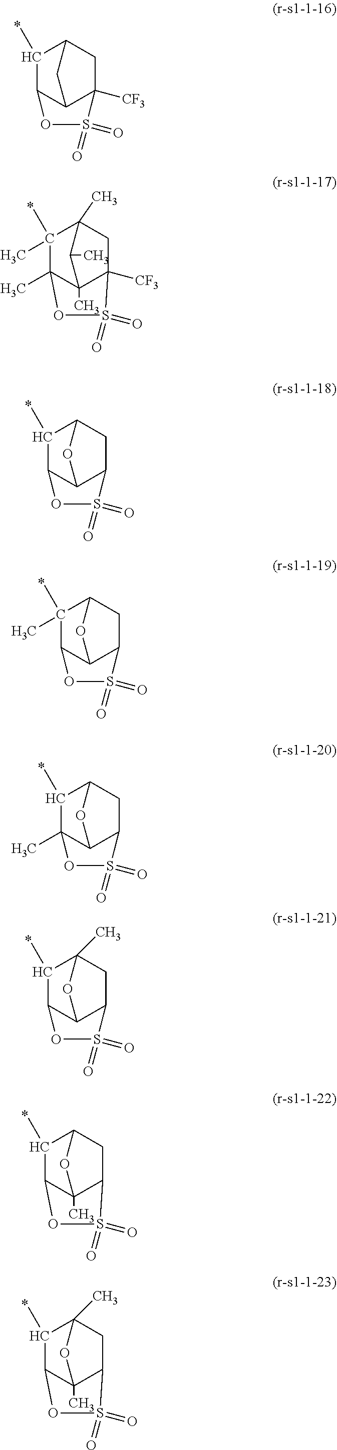

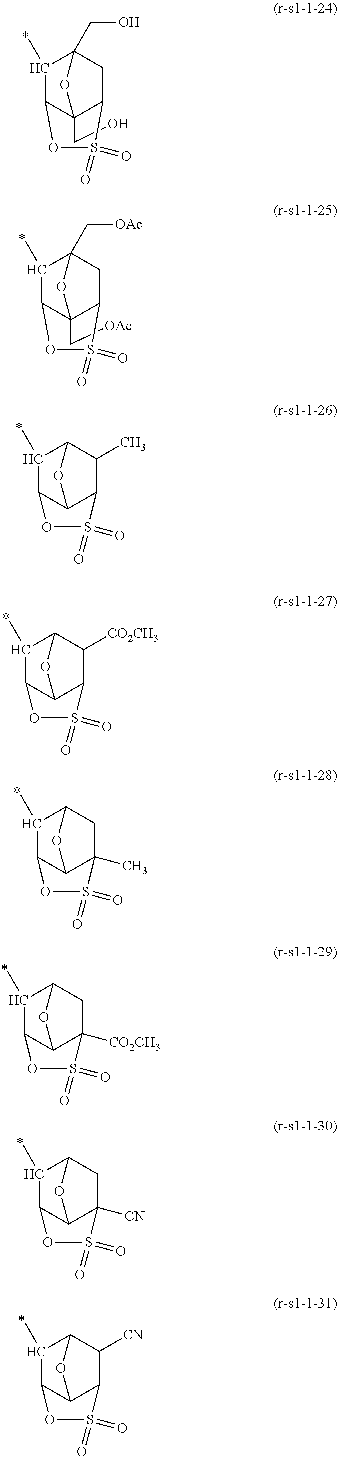

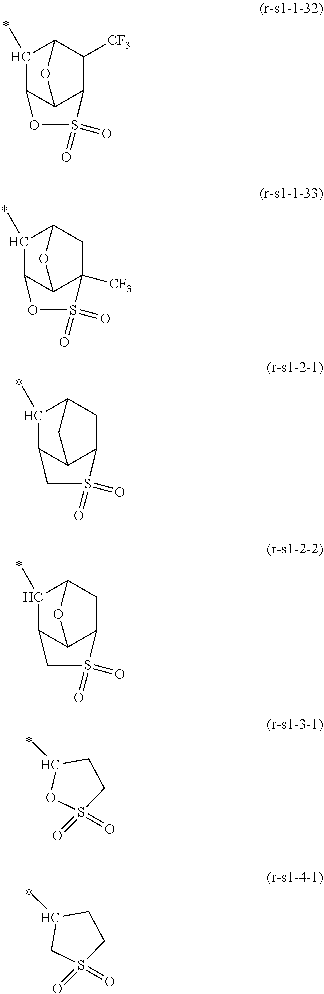

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as a monocyclic group. Further, in a case where the group has other ring structures, the group is referred to as a polycyclic group regardless of the structures. The carbonate-containing cyclic group may be a monocyclic group or a polycyclic group.

The carbonate ring-containing cyclic group is not particularly limited, and an optional group may be used. Specific examples thereof include groups represented by General Formulae (ax3-r-1) to (ax3-r-3) shown below.

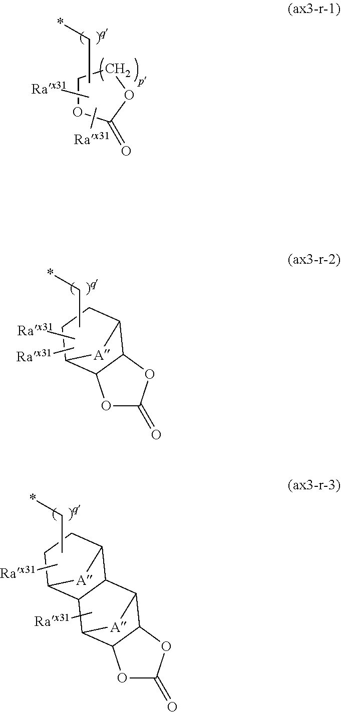

[In the formulae, each Ra′^{x31} independently represents a hydrogen atom, an alkyl group, an alkoxy group, a halogen atom, a halogenated alkyl group, a hydroxyl group, —COOR″, —OC(═O)R″, a hydroxyalkyl group, or a cyano group. R″ represents a hydrogen atom, an alkyl group, a lactone-containing cyclic group, a carbonate-containing cyclic group, or a —SO₂-containing cyclic group. A″ represents an oxygen atom, a sulfur atom or an alkylene group having 1 to 5 carbon atoms which may contain an oxygen atom or a sulfur atom. p′ represents an integer of 0 to 3, and q′ represents 0 or 1.]

In General Formulae (ax3-r-2) and (ax3-r-3), A″ has the same definition as that for A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′³¹ include the same groups as those described above in the explanation of Ra′²¹ in General Formulae (a2-r-1) to (a2-r-7).

Specific examples of the groups represented by General Formulae (ax3-r-1) to (ax3-r-3) are shown below.

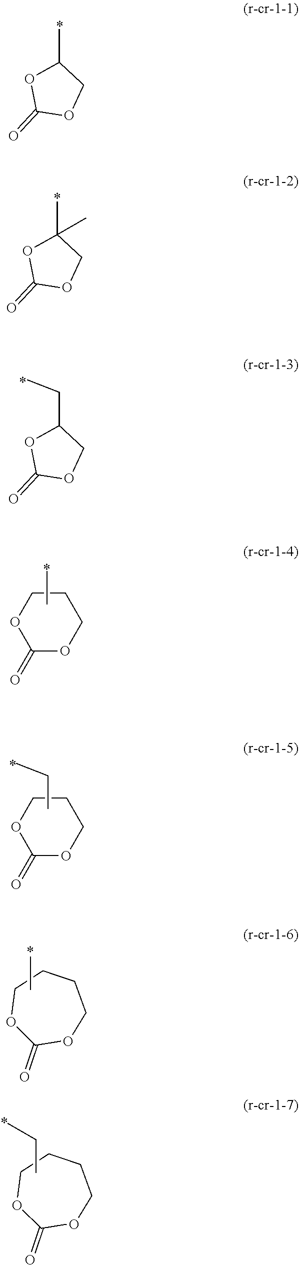

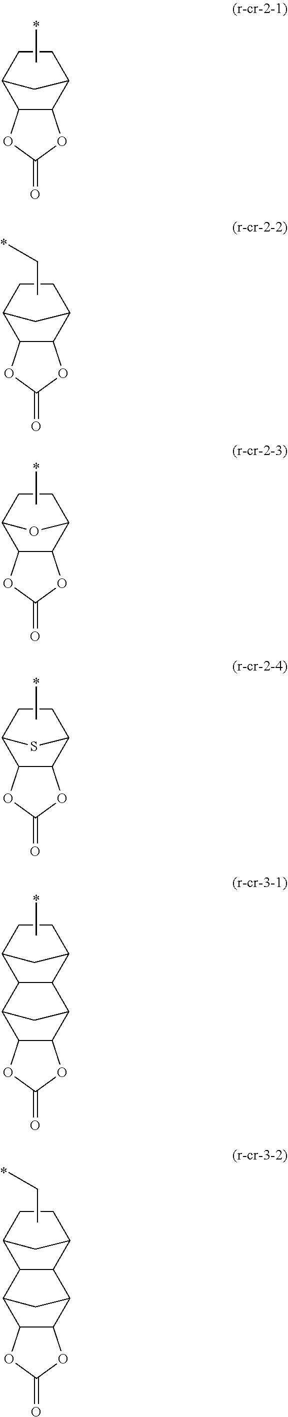

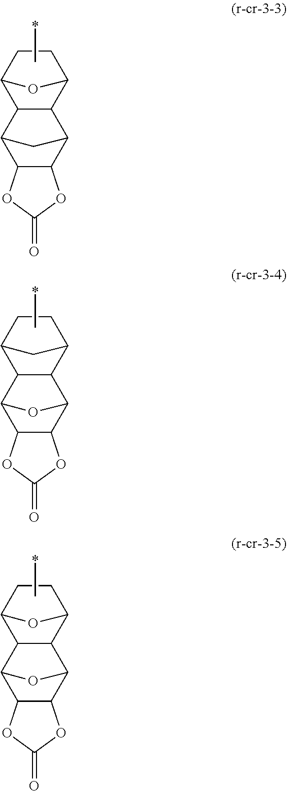

As the structural unit (a2), a structural unit derived from acrylic acid ester in which the hydrogen atom bonded to the carbon atom at the α-position may be substituted with a substituent is preferable.

Specific preferable examples of such a structural unit (a2) include a structural unit represented by General Formula (a2-1) shown below.

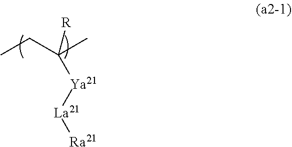

In the formula, R represents a hydrogen atom, an alkyl group having 1 to 5 carbon atoms, or a halogenated alkyl group having 1 to 5 carbon atoms. Ya²¹ represents a single bond or a divalent linking group. La²¹ represents —O—, —COO—, —CON(R′)—, —OCO—, —CONHCO— or —CONHCS—. R′ represents a hydrogen atom or a methyl group; provided that, in a case where La²¹ represents —O—, Ya²¹ does not represents —CO—. Ra²¹ represents a lactone-containing cyclic group, a carbonate-containing cyclic group, or a —SO₂-containing cyclic group.]

In Formula (a2-1), R has the same definition as described above. R represents preferably a hydrogen atom, an alkyl group having 1 to 5 carbon atoms, or a fluorinated alkyl group having 1 to 5 carbon atoms and particularly preferably a hydrogen atom or a methyl group from the viewpoint of industrial availability.

In Formula (a2-1), the divalent linking group as Ya²¹ is not particularly limited, and preferable examples thereof include a divalent hydrocarbon group which may have a substituent and a divalent linking group having hetero atoms. Descriptions of the divalent hydrocarbon group which may have a substituent and the divalent linking group containing a hetero atom in Ya²¹ are respectively the same as those of the divalent hydrocarbon group which may have a substituent and the divalent linking group containing a hetero atom in Ya^{x1} in General Formula (a10-1).

As Ya²¹, a single bond, an ester bond [—C(═O)—O—], an ether bond (—O—), a linear or branched alkylene group, or a combination of these is preferable.

In Formula (a2-1), Ra²¹ represents a lactone-containing cyclic group, a —SO₂-containing cyclic group, or a carbonate-containing cyclic group.

Preferable examples of the lactone-containing cyclic group, the —SO₂-containing cyclic group, and the carbonate-containing cyclic group as Ra²¹ include groups represented by General Formulae (a2-r-1) to (a2-r-7), groups represented by General Formulae (a5-r-1) to (a5-r-4), and groups represented by General Formulae (ax3-r-1) to (ax3-r-3).

Among the examples, Ra²¹ represents preferably a lactone-containing cyclic group or a —SO₂-containing cyclic group and more preferably a group represented by General Formula (a2-r-1), (a2-r-2), (a2-r-6) or (a5-r-1). Specifically, a group represented by any of chemical Formulae (r-1c-1-1) to (r-1c-1-7), (r-1c-2-1) to (r-1c-2-18), (r-1c-6-1), (r-s1-1-1), and (r-s1-1-18) is still more preferable.

Structural Unit (a3):

In addition to the structural unit (a01), the structural unit (a02), and the structural unit (a03), the component (A1) may further include a structural unit (a3) containing a polar group-containing aliphatic hydrocarbon group (where structural units corresponding to the structural unit (a01), the structural unit (a02), the structural unit (a03), the structural unit (a1), or the structural unit (a2) being excluded).

The structural unit (a3) is not particularly limited as long as the structural unit contains a polar group-containing aliphatic hydrocarbon group, and an optional structural unit may be used.

The structural unit (a3) is a structural unit derived from acrylic acid ester in which the hydrogen atom bonded to the carbon atom at the α-position may be substituted with a substituent, and a structural unit containing a polar group-containing aliphatic hydrocarbon group is preferable.

Preferable examples of structural units (a3) include a structural unit represented by Formula (a3-1), a structural unit represented by Formula (a3-2), and a structural unit represented by Formula (a3-3).

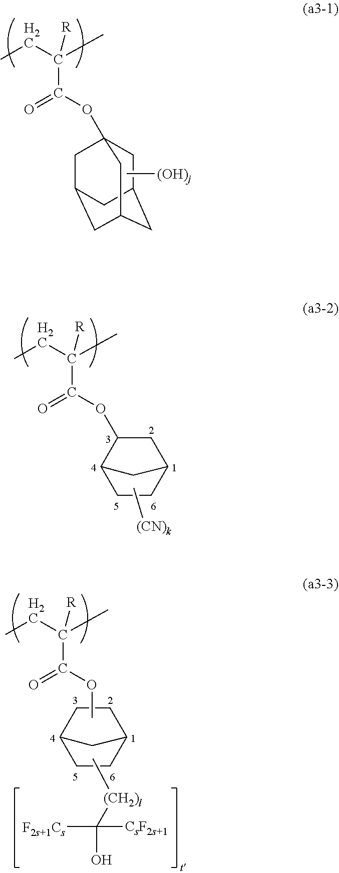

[In the formulae, R has the same definition as described above, j represents an integer of 1 to 3, k represents an integer of 1 to 3, t′ represents an integer of 1 to 3, 1 represents an integer of 1 to 5, and s represents an integer of 1 to 3.]

In Formula (a3-1), j represents preferably 1 or 2 and more preferably 1. In a case where j represents 2, it is preferable that the hydroxyl groups are bonded to the third and fifth positions of the adamantyl group. In a case where j represents 1, it is preferable that the hydroxyl group is bonded to the third position of the adamantyl group.

j represents preferably 1, and it is particularly preferable that the hydroxyl group is bonded to the third position of the adamantyl group.

In Formula (a3-2), k represents preferably 1. The cyano group is preferably bonded to the fifth or sixth position of the norbomyl group.

In Formula (a3-3), t′ represents preferably 1. l represents preferably 1. s represents preferably 1. Further, it is preferable that a 2-norbomyl group or 3-norbomyl group is bonded to the terminal of the carboxy group of the acrylic acid. The fluorinated alkyl alcohol is preferably bonded to the fifth or sixth position of the norbomyl group.

Structural Unit (a9):

The structural unit (a9) is a structural unit represented by General Formula (a9-1).

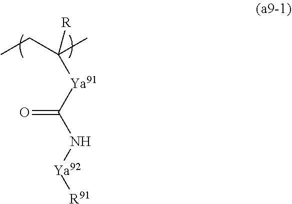

[In the formulae, R represents a hydrogen atom, an alkyl group having 1 to 5 carbon atoms, or a halogenated alkyl group having 1 to 5 carbon atoms, Ya⁹¹ is a single bond or a divalent linking group, Ya⁹² is a divalent linking group, and R⁹¹ is a hydrocarbon group which may have a substituent.]

In Formula (a9-1), R has the same definition as described above.

R represents preferably a hydrogen atom, an alkyl group having 1 to 5 carbon atoms, or a fluorinated alkyl group having 1 to 5 carbon atoms and particularly preferably a hydrogen atom or a methyl group from the viewpoint of industrial availability.

In Formula (a9-1), examples of divalent linking groups in Ya⁹¹ include the same divalent linking groups as those in Ya^{x1} in General Formula (a10-1). Among them, Ya⁹¹ is preferably a single bond.

In Formula (a9-1), examples of divalent linking groups in Ya⁹² include the same divalent linking groups as those of Ya^{xl} in General Formula (a10-1).

In the divalent linking group in Ya⁹², the divalent hydrocarbon group which may have a substituent is preferably a linear or branched aliphatic hydrocarbon group.

In a case where Ya⁹² represents a divalent linking group, preferable examples of the divalent linking group containing a hetero atom include —O—, —C(═O)—O—, —C(═O)—, —O—C(═O)—O—, —C(═O)—NH—, —NH—, —NH—C(═NH)— (H may be substituted with a substituent such as an alkyl group, an acyl group, or the like), —S—, —S(═O)₂—, —S(═O)₂—O—, —C(═S)—, and a group represented by General Formula: —Y²¹—O—Y²²—, —Y²¹—O—, —Y²¹—C(═O)—O—, —C(═O)—O—Y²¹—, —[Y²¹—C(═O)—O]_{m′}—Y²²—, or —Y²¹—O—C(═O)—Y²²— or [in the formulae, Y²¹ and Y²² each independently represent a divalent hydrocarbon group which may have a substituent, O represents an oxygen atom, and m′ represents an integer of 0 to 3]. Among them, —C(═O)— and —C(═S)— are preferable.

In Formula (a9-1), examples of hydrocarbon groups in R⁹¹ include an alkyl group, a monovalent alicyclic hydrocarbon group, an aryl group, an aralkyl group, and the like.

The alkyl group in R⁹¹ preferably has 1 to 8 carbon atoms, more preferably has 1 to 6 carbon atoms, and still more preferably has 1 to 4 carbon atoms, and it may be linear or branched. Specifically, preferable examples thereof include a methyl group, an ethyl group, a propyl group, a butyl group, a hexyl group, an octyl group, and the like.

The monovalent alicyclic hydrocarbon group in R⁹¹ preferably has 3 to 20 carbon atoms and more preferably has 3 to 12 carbon atoms, and it may be polycyclic or monocyclic. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclobutane, cyclopentane and cyclohexane. As the polycyclic alicyclic hydrocarbon group, a group in which one or more hydrogen atoms have been removed from a polycycloalkane is preferable. As the polycycloalkane, a group having 7 to 12 carbon atoms is preferable. Specific examples of the polycycloalkane include adamantane, norbomane, isobomane, tricyclodecane, and tetracyclododecane.

The aryl group in R⁹¹ preferably has 6 to 18 carbon atoms, more preferably has 6 to 10 carbon atoms, and specifically, it particularly preferably has a phenyl group.

The aralkyl group in R⁹¹ is preferably an aralkyl group in which an alkylene group having 1 to 8 carbon atoms is bonded to the above-mentioned “aryl group in R⁹¹,” is more preferably an aralkyl group in which an alkylene group having 1 to 6 carbon atoms is bonded to the above-mentioned “aryl group in R⁹¹,” and is particularly preferably an aralkyl group in which an alkylene group having 1 to 4 carbon atoms is bonded to the above-mentioned “aryl group in R⁹¹.”

In the hydrocarbon group in R⁹¹, part or all of hydrogen atoms of the hydrocarbon group are preferably substituted by fluorine atoms, and 30% to 100% of hydrogen atoms of the hydrocarbon group are more preferably substituted by fluorine atoms. Among them, a perfluoroalkyl group in which all hydrogen atoms of the alkyl group mentioned above are substituted by fluorine atoms is particularly preferable.

The hydrocarbon group in R⁹¹ may have a substituent. Examples of substituents thereof include a halogen atom, an oxo group (═O), a hydroxyl group (—OH), an amino group (—NH₂), —SO₂—NH₂, and the like. In addition, a part of carbon atoms constituting the hydrocarbon group may be substituted by a substituent containing a hetero atom. Examples of substituents thereof which contains a hetero atom include —O—, —NH—, —N═, —C(═O)—O—, —S—, —S(═O)₂—, —S(═O)₂—O—.

In R⁹¹, examples of hydrocarbon groups having a substituent include lactone-containing cyclic groups respectively represented by General Formulae (a2-r-1) to (a2-r-7).

In addition, in R⁹¹, examples of hydrocarbon groups having a substituent include —SO₂-containing cyclic groups represented by General Formulae (a5-r-1) to (a5-r-4), a substituted aryl group and a monovalent heterocyclic group represented by the following chemical formula, and the like.

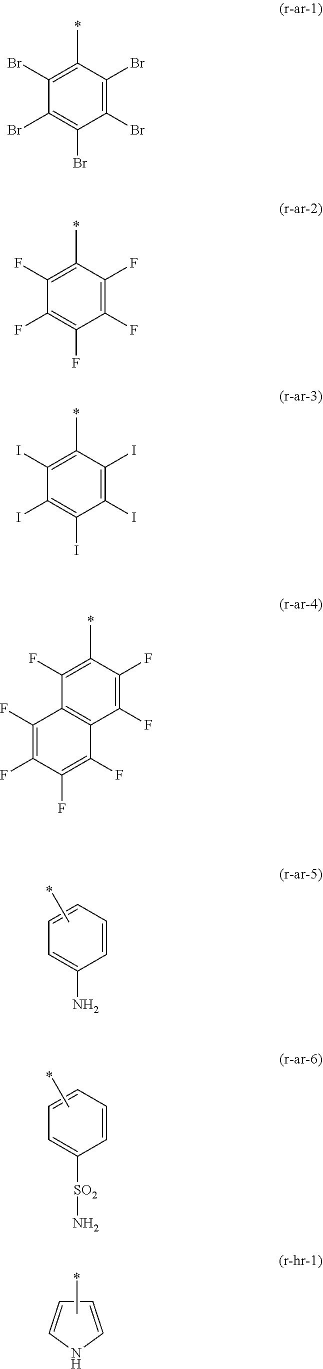

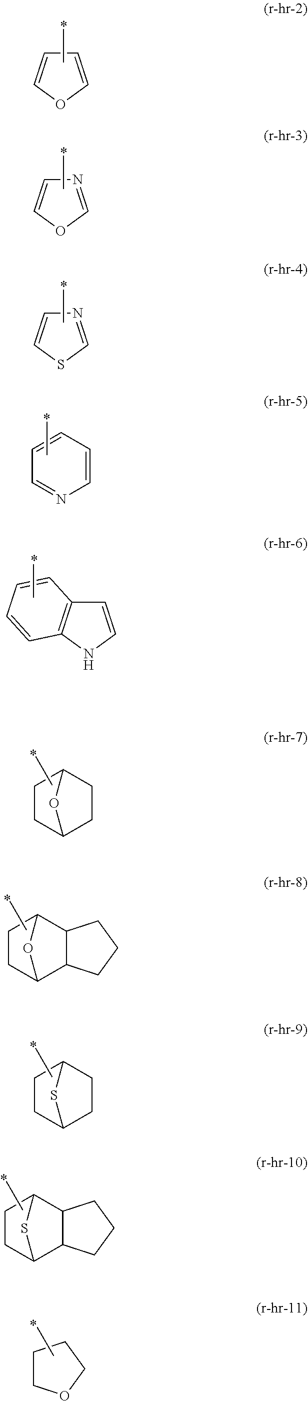

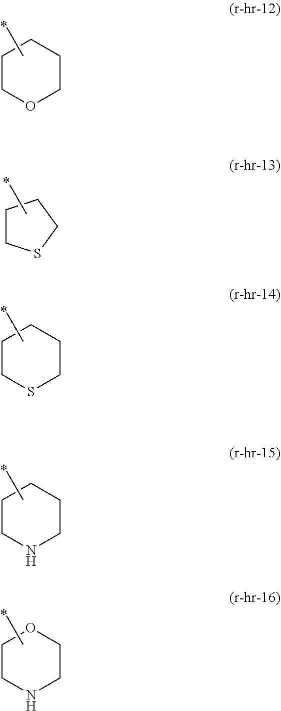

Among the structural units (a9), a structural unit represented by General Formula (a9-1-1) is preferable.

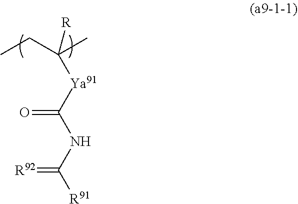

[In the formula, R is as defined above, Ya⁹¹ is a single bond or a divalent linking group, R⁹¹ is a hydrocarbon group which may have a substituent, and R⁹² is an oxygen atom or a sulfur atom.]

In General Formula (a9-1-1), descriptions of Ya⁹¹, R⁹¹, and R are the same as described above.

In addition, R⁹² is an oxygen atom or a sulfur atom.

Specific examples of structural units represented by Formula (a9-1) or General Formula (a9-1-1) are shown below. In the formula described below”, R^{α} represents a hydrogen atom, a methyl group, or a trifluoromethyl group.

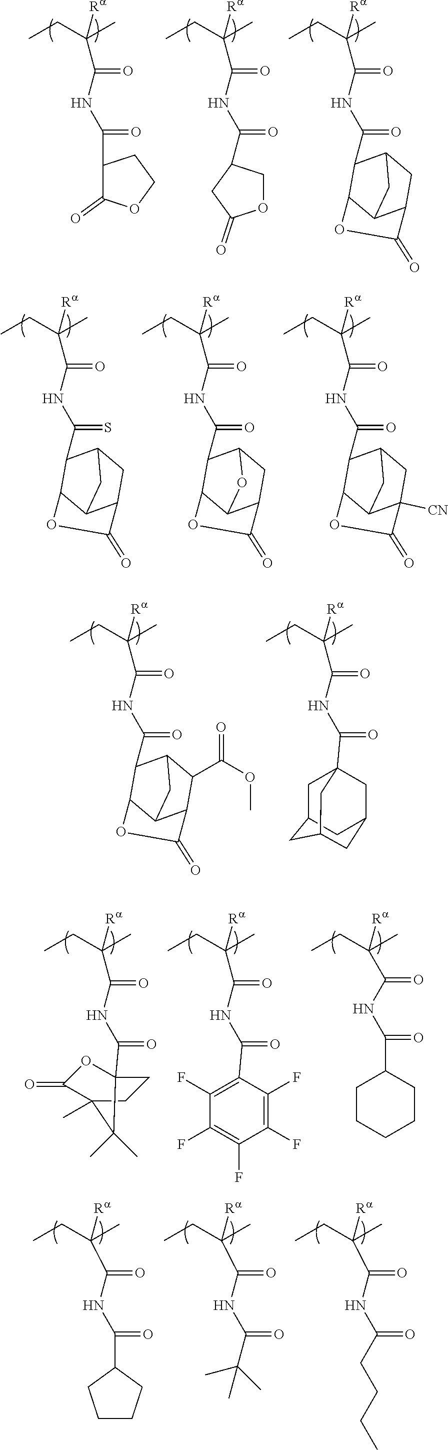

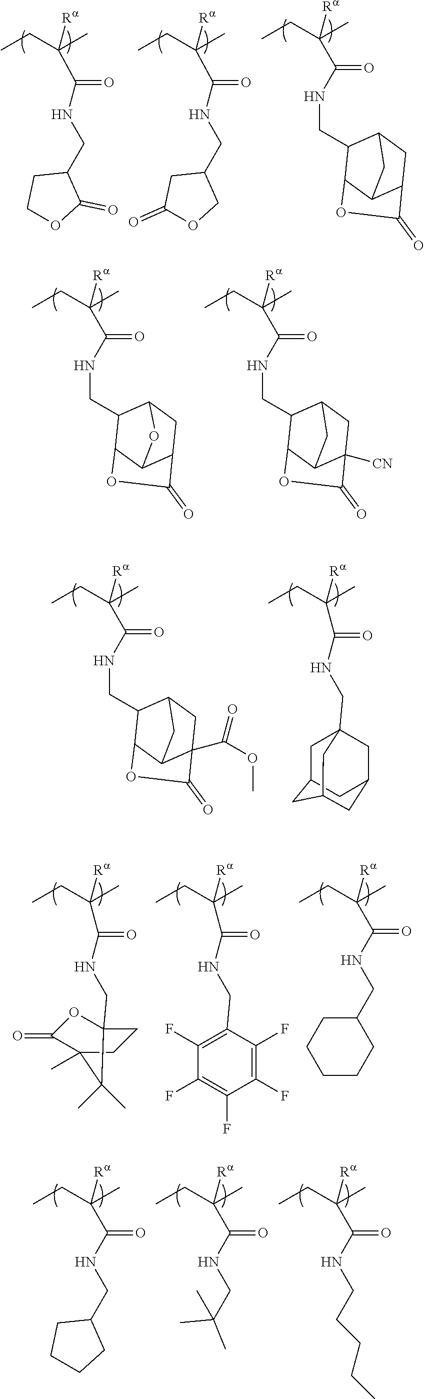

As the component (A1) contained in the resist composition, one kind thereof may be used, or two or more kinds thereof may be used in combination.

In the resist composition of the present embodiment, the resin component that is the component (A1) has the structural unit (a01), the structural unit (a02), and the structural unit (a03), and one kind of polymer may be used alone, or two or more kinds thereof may be used in combination.

Preferable examples of components (A1) include a component having a copolymer having the structural unit (a01), the structural unit (a02), and the structural unit (a03) (hereinafter, this copolymer will be referred to as the “component (A1-1)”). In addition, examples of components (A1) include a component having a polymer having the structural unit (a01) and other structural units as necessary, a polymer having the structural unit (a02) and other structural units as necessary, and a mixed resin including a polymer having the structural unit (a03) and other structural units as necessary.

Among them, the component (A1) contained in the resist composition is more preferably a component containing the component (A1-1).

Preferable examples of components (A1-1) include a polymer compound composed of repeating structures of the structural unit (a01), the structural unit (a02), and the structural unit (a03); and a polymer compound composed of repeating structures of the structural unit (a01), the structural unit (a02), the structural unit (a03), and other structural units (a polymer compound having repeating structures of the structural unit (a01), the structural unit (a02), the structural unit (a03), and the structural unit (a2), and the like).

The component (A1) can be produced by dissolving a monomer for deriving each structural unit in a polymerization solvent, and adding radical polymerization initiators such as azobisisobutyronitrile (AIBN) and dimethyl azobisisobutyrate (for example, V-601 and the like) thereto to perform polymerization. Alternatively, such a component (A1) can be produced by dissolving a precursor monomer for deriving the structural unit (a0-1), a monomer for deriving the structural unit (a0-2), and, as necessary, monomers for deriving structural units other than the above structural units in a polymerization solvent, adding a radical polymerization initiator as described above thereto to perform polymerization, and then performing a deprotection reaction. In the polymerization, a —C(CF₃)₂—OH group may be introduced to the terminal by using, for example, a chain transfer agent such as HS—CH₂—CH₂—CH₂—C(CF₃)₂—OH in combination.

As described above, a copolymer into which a hydroxyalkyl group, formed by substitution of some hydrogen atoms in the alkyl group with fluorine atoms, has been introduced is effective for reducing development defects and reducing line edge roughness (LER: uneven irregularities of a line side wall).

The weight-average molecular weight (Mw) (in the viewpoint of polystyrene determined by gel permeation chromatography (GPC)) of the component (A1) is not particularly limited, but is preferably in a range of 1,000 to 50,000, more preferably in a range of 2,000 to 30,000, and particularly preferably in a range of 3,000 to 20,000.

In a case where Mw of the component (A1) is equal to or less than the upper limit value within this preferable range, a solubility in a resist solvent which is a sufficient level for the resist composition to be used as a resist is achieved, and in a case where Mw thereof is equal to or more than the lower limit value within this preferable range, dry etching resistance and resist pattern cross-sectional shape are favorable.

A dispersity (Mw/Mn) of the component (A1) is not particularly limited, but it is preferably 1.0 to 4.0, is more preferably 1.0 to 3.0, and is particularly preferably 1.0 to 2.0. In addition, Mn shows a number average molecular weight.

In Regard to Component (A2)

In the resist composition of the present embodiment, a base material component that changes its solubility in a developing solution due to the action of an acid (hereinafter referred to as the “component (A2)”) and that does not correspond to the component (A1) may be used in combination as the component (A).

The (A2) component is not particularly limited, and any component may be selected from a number of known base material components of the related art which is for chemically amplified resist compositions.

As the (A2) component, one kind of high-molecular-weight compound or low-molecular-weight compound may be used alone, or two or more kinds thereof may be used in combination.

A proportion of the component (A1) in the component (A) is preferably 25% by mass or more, is more preferably 50% by mass or more, and is still more preferably 75% by mass or more, and it may be 100% by mass with respect to a total mass of the component (A). In a case where the proportion is 25% by mass or more, a resist pattern having excellent various lithography characteristics such as a high sensitivity, resolution performance, and roughness improvement is easily formed. Such an effect is particularly remarkable in lithography using an electron beam or EUV.

In the resist composition of the present embodiment, the content of the component (A) may be adjusted according to the film thickness of a resist intended to be formed.

<Optional Components>

The resist composition of the present embodiment may further contain components (optional components) other than the above-described component (A).

Examples of such optional components include the following components (B), (D), (E), (F), and (S).

The resist composition of the present embodiment preferably further contains the component (B) in addition to the above-described component (A).

<<Component (B)>>

The component (B) is an acid generator component that generates an acid upon exposure.

The component (B) is not particularly limited, and those which have been proposed as an acid generator for a chemically amplified resist composition in the related art can be used.

Examples of these acid generators are numerous and include onium salt acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

As the onium salt acid generator, a compound represented by General Formula (b-1) (hereinafter, also referred to as “component (b-1)”), a compound represented by General Formula (b-2) (hereinafter, also referred to as “component (b-2)”) or a compound represented by General Formula (b-3) (hereinafter, also referred to as “component (b-3)”) can be used.

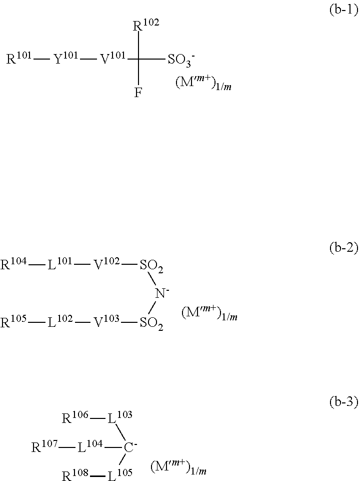

[In the formula, R¹⁰¹ and R¹⁰⁴ to R¹⁰⁸ each independently represent a cyclic group which may have a substituent, a chain-like alkyl group which may have a substituent, or a chain-like alkenyl group which may have a substituent; R¹⁰⁴ and R¹⁰⁵ may be bonded to each other to form a ring; R¹⁰² represents a fluorine atom or a fluorinated alkyl group having 1 to 5 carbon atoms; Y¹⁰¹ is a single bond or a divalent linking group containing an oxygen atom; V¹⁰¹ to V¹⁰³ each independently represent a single bond, an alkylene group, or a fluorinated alkylene group; L¹⁰¹ and L¹⁰² each independently represent a single bond or an oxygen atom; L¹⁰³ to L¹⁰⁵ each independently represent a single bond, —CO— or —SO₂—; and m represents an integer of 1 or more, and M′^{m+} represents an m-valent onium cation.]

{Anion Moiety}

Anion Moiety of Component (b-1)

In General Formula (b-1), R¹⁰¹ represents a cyclic group which may have a substituent, a chain-like alkyl group which may have a substituent, or a chain-like alkenyl group which may have a substituent.

Cyclic Group which May have a Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that does not have aromaticity. The aliphatic hydrocarbon group may be saturated or unsaturated, but in general, the aliphatic hydrocarbon group is preferably saturated.

The aromatic hydrocarbon group as R¹⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group as R¹⁰¹ include benzene, fluorene, naphthalene, anthracene, phenanthrene, biphenyl, or an aromatic hetero ring in which some carbon atoms constituting any of these aromatic rings have been substituted with hetero atoms. Examples of the hetero atom in the aromatic hetero rings include an oxygen atom, a sulfur atom and a nitrogen atom.

Specific examples of the aromatic hydrocarbon group as R¹⁰¹ include a group in which one hydrogen atom has been removed from the above-described aromatic ring (an aryl group such as a phenyl group or a naphthyl group), and a group in which one hydrogen atom in the aromatic ring has been substituted with an alkylene group (an arylalkyl group such as a benzyl group, a phenethyl group, a 1-naphthylmethyl group, a 2-naphthylmethyl group, 1-naphthylethyl group, or a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R¹⁰¹ include aliphatic hydrocarbon groups containing a ring in the structure thereof.

Examples of the aliphatic hydrocarbon group containing a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a monocyclic group or a polycyclic group. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among polycycloalkanes, a polycycloalkane having a bridged ring polycyclic skeleton, such as adamantane, norbomane, isobomane, tricyclodecane, or tetracyclododecane, and a polycycloalkane having a fused ring polycyclic skeleton, such as a cyclic group having a steroid skeleton are preferable.

Among these examples, as the cyclic aliphatic hydrocarbon group as R¹⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbomyl group is particularly preferable, and an adamantyl group is most preferable.

The linear or branched aliphatic hydrocarbon group that may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—].

As the branched aliphatic hydrocarbon group, a branched alkylene group is preferred, and specific examples include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group in the alkylalkylene group, a linear alkyl group having 1 to 5 carbon atoms is preferable.

The cyclic hydrocarbon group as R¹⁰¹ may contain a hetero atom such as a hetero ring. Specific examples thereof include lactone-containing cyclic groups represented by General Formulae (a2-r-1) to (a2-r-7), the —SO₂-containing cyclic group represented by General Formulae (a5-r-1) to (a5-r-4), and other heterocyclic groups represented by Chemical Formulae (r-hr-1) to (r-hr-16).

Examples of the substituent for the cyclic group as R¹⁰¹ include an alkyl group, an alkoxy group, a halogen atom, a halogenated alkyl group, a hydroxy group, a carbonyl group, and a nitro group.

The alkyl group as the substituent is preferably an alkyl group having 1 to 12 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Example of the above-described halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the above-described halogen atoms.

The carbonyl group as the substituent is a group that substitutes a methylene group (—CH₂—) constituting the cyclic hydrocarbon group.

Chain-Like Alkyl Group which May have a Substituent:

The chain-like alkyl group as R¹⁰¹ may be linear or branched.

The linear alkyl group has preferably 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group.

The branched alkyl group has preferably 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have a Substituent:

Such a chain-like alkenyl group as R¹⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

As the substituent for the chain-like alkyl group or alkenyl group as R¹⁰¹, an alkoxy group, a halogen atom, a halogenated alkyl group, a hydroxy group, a carbonyl group, a nitro group, an amino group, a cyclic group as R¹⁰¹ or the like can be used.

Among the examples, as R¹⁰¹, a cyclic group which may have a substituent is preferable, and a cyclic hydrocarbon group which may have a substituent is more preferable. As the substituent, a hydroxy group, a carbonyl group, a nitro group, and an amino group are preferable, and among them, a hydroxy group is more preferable because it is easily distributed on a substrate side in a resist film.

Specific examples of cyclic hydrocarbon groups preferably include a group in which one or more hydrogen atoms have been removed from a phenyl group, a naphthyl group, or a polycycloalkane; lactone-containing cyclic groups represented by Formulae (a2-r-1) to (a2-r-7); the —SO₂-containing cyclic group represented by General Formulae (a5-r-1) to (a5-r-4); and the like.

In General Formula (b-1), Y¹⁰¹ represents a single bond or a divalent linking group containing an oxygen atom.

In a case where Y¹⁰¹ represents a divalent linking group containing an oxygen atom, Y¹⁰¹ may contain an atom other than an oxygen atom. Examples of atoms other than an oxygen atom include a carbon atom, a hydrogen atom, a sulfur atom, and a nitrogen atom.

Examples of divalent linking groups containing an oxygen atom include oxygen-atom-containing linking groups of a non-hydrocarbon system, such as an oxygen atom (ether bond: —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); a combination of the oxygen-atom-containing linking groups of the non-hydrocarbon system and an alkylene group; and the like. A sulfonyl group (—SO₂—) may be further linked to the combination. Examples of the divalent linking group having an oxygen atom include linking groups represented by following General Formulae (y-a1-1) to (y-a1-7).

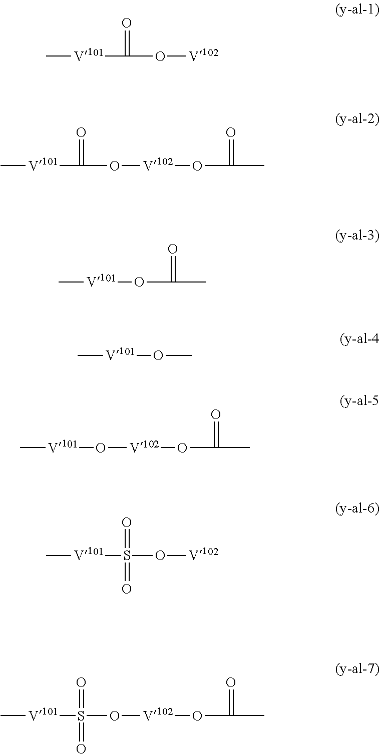

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group in V′¹⁰² is preferably an alkylene group having 1 to 30 carbon atoms, is more preferably an alkylene group having 1 to 10 carbon atoms, and is even more preferably an alkylene group having 1 to 5 carbon atoms.

The alkylene group in V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, —CH₂CH(CH₃)CH₂CH₂—; and a pentamethylene group [—CH₂CH₂CH₂CH₂CH₂—].

Furthermore, a part of the methylene group in the alkylene group in V′¹⁰¹ or V′¹⁰² may be substituted by a divalent aliphatic cyclic group having 5 to 10 carbon atoms. The aliphatic cyclic group is preferably a divalent group in which one hydrogen atom has further been removed from a cyclic aliphatic hydrocarbon group in Ra′³ in General Formula (a1-r-1) (a monocyclic aliphatic hydrocarbon group, or a polycyclic aliphatic hydrocarbon group), and is more preferably a cyclohexylene group, a 1,5-adamantylene group, or a 2,6-adamantylene group.

Y¹⁰¹ represents preferably a divalent linking group containing an ester bond or a divalent linking group containing an ether bond and more preferably linking groups represented by General Formulae (y-a1-1) to (y-a1-5).

In General Formula (b-1), V¹⁰¹ represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include a group in which some or all hydrogen atoms in the alkylene group as V¹⁰¹ have been substituted with fluorine atoms. Among these examples, as V¹⁰¹, a single bond or a fluorinated alkylene group having 1 to 4 carbon atoms is preferable.

In General Formula (b-1), R¹⁰² represents a fluorine atom or a fluorinated alkyl group having 1 to 5 carbon atoms. R¹⁰² represents preferably a fluorine atom or a perfluoroalkyl group having 1 to 5 carbon atoms and more preferably a fluorine atom.

In a case where Y¹⁰¹ represents a single bond, specific examples of anion moieties of the component (b-1) include a fluorinated alkylsulfonate anion such as a trifluoromethanesulfonate anion or a perfluorobutanesulfonate anion can be exemplified; and in a case where Y¹⁰¹ represents a divalent linking group containing an oxygen atom, examples thereof include anions represented by Formulae (an-1) to (an-3) shown below.

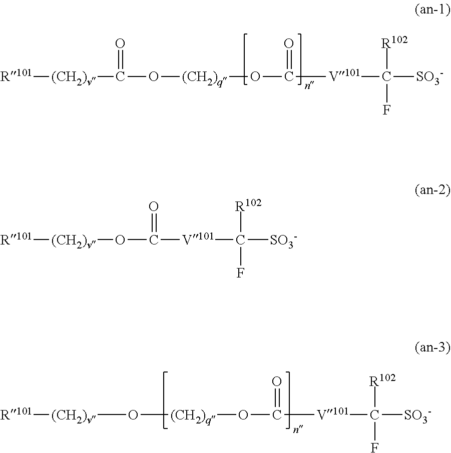

[In the formula, R″¹⁰¹ represents an aliphatic cyclic group which may have a substituent, groups respectively represented by Formulae (r-hr-1) to (r-hr-6), or a chain-like alkyl group which may have a substituent; R″¹⁰² represents an aliphatic cyclic group which may have a substituent, the above-mentioned lactone-containing cyclic groups respectively represented by General Formulae (a2-r-1) to (a2-r-7), or the above-mentioned —SO₂-containing cyclic groups respectively represented by General Formulae (a5-r-1) to (a5-r-4); R″¹⁰³ is an aromatic cyclic group which may have a substituent, an aliphatic cyclic group which may have a substituent, or a chain-like alkenyl group which may have a substituent; V″¹⁰¹ is a single bond, an alkylene group having 1 to 4 carbon atoms, or a fluorinated alkylene group having 1 to 4 carbon atoms; R¹⁰² represents a fluorine atom or a fluorinated alkyl group having 1 to 5 carbon atoms; and v″′s each independently are an integer of 0 to 3, q″′s each independently are an integer of 1 to 20, and n″ is 0 or 1.]

As the aliphatic cyclic group as R″¹⁰¹, R″¹⁰², and R′¹⁰³ which may have a substituent, the same groups as the cyclic aliphatic hydrocarbon group as R¹⁰¹ described above are preferable.

Examples of substituents thereof include the same as those exemplified as the substituents by which a cyclic aliphatic hydrocarbon group in R¹⁰¹ is substituted. Among them, a hydroxy group, a carbonyl group, a nitro group, and an amino group are preferable, and among them, a hydroxy group is more preferable because it is easily distributed on a substrate side in a resist film.

As the aromatic cyclic group as R″¹⁰³ which may have a substituent, the same groups as the aromatic hydrocarbon group for the cyclic hydrocarbon group represented by R¹⁰¹ described above are preferable. Examples of substituents thereof include the same as those exemplified as the substituents by which an aromatic hydrocarbon group in R¹⁰¹ is substituted.

The chain-like alkyl group which may have a substituent in R″¹⁰¹ is preferably a group exemplified as the chain-like alkyl group in R¹⁰¹. The chain alkenyl group which may have a substituent in R″¹⁰³ is preferably a group exemplified as the chain alkenyl group in R¹⁰¹.

In Formulae (an-1) to (an-3), V″¹⁰¹ is a single bond, an alkylene group having 1 to 4 carbon atoms, or a fluorinated alkylene group having 1 to 4 carbon atoms. V″¹⁰¹ is preferably a single bond, an alkylene group having 1 carbon atom (a methylene group), or a fluorinated alkylene group having 1 to 3 carbon atoms.

In Formulae (an-1) to (an-3), R¹⁰² represents a fluorine atom or a fluorinated alkyl group having 1 to 5 carbon atoms. In R¹⁰², a perfluoroalkyl group having 1 to 5 carbon atoms is preferably a fluorine atom, and is more preferably a fluorine atom.

In Formulae (an-1) to (an-3), v″ is an integer of 0 to 3 and is preferably 0 or 1. q″ is an integer of 1 to 20, is preferably an integer of 1 to 10, is more preferably an integer of 1 to 5, is still more preferably 1, 2, or 3, and is particularly preferably 1 or 2. n″ is 0 or 1.

Anion Moiety of Component (b-2)

In General Formula (b-2), R¹⁰⁴ and R¹⁰⁵ each independently represent a cyclic group which may have a substituent, a chain-like alkyl group which may have a substituent or a chain-like alkenyl group which may have a substituent, and has the same definition as that for R¹⁰¹ in General Formula (b-1). Here, R¹⁰⁴ and R¹⁰⁵ may be bonded to each other to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group has preferably 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ is small because the solubility in a solvent for a resist is also excellent in the range of the number of carbon atoms. Further, in the chain-like alkyl group as R¹⁰⁴ and R¹⁰⁵, it is preferable that the number of hydrogen atoms substituted with fluorine atoms is as large as possible because the acid strength increases and the transparency to high energy radiation of 200 nm or less or electron beams is improved.

The proportion of fluorine atoms in the chain-like alkyl group, that is, the fluorination ratio is preferably in a range of 70% to 100% and more preferably in a range of 90% to 100%, and it is most preferable that the chain-like alkyl group is a perfluoroalkyl group in which all hydrogen atoms are substituted with fluorine atoms.

In General Formula (b-2), V¹⁰² and V¹⁰³ each independently represent a single bond, an alkylene group, or a fluorinated alkylene group, and has the same definition as that for V¹⁰¹ in General Formula (b-1).

In General Formula (b-2), L¹⁰¹ and L¹⁰² each independently represent a single bond or an oxygen atom.

Anion Moiety of Component (b-3)

In General Formula (b-3), R¹⁰⁶ to R¹⁰⁸ each independently represent a cyclic group which may have a substituent or a chain-like alkyl group which may have a substituent or a chain-like alkenyl group which may have a substituent, and has the same definition as that for R¹⁰¹ in General Formula (b-1).

L¹⁰³ to L¹⁰⁵ each independently represent a single bond, —CO—, or —SO₂—.

{Cation Moiety}

In Formulae (b-1), (b-2), and (b-3), m is an integer of 1 or more, M′^{m+} is an m-valent onium cation. Preferable examples thereof include sulfonium cation and iodonium cation. Examples thereof include organic cations respectively represented by General Formulae (ca-1) to (ca-4).

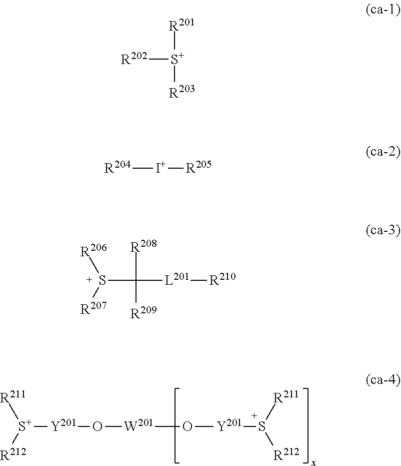

[In the formula, R²⁰¹ to R²⁰⁷, R²¹¹, and R²¹² each independently represent an aryl group that may have a substituent, an alkyl group that may have a substituent, or an alkenyl group that may have a substituent; R²⁰¹ to R²⁰³, R²⁰⁶ and R²⁰⁷, and R²¹¹ and R²¹² each respectively may be bonded to each other to form a ring together with a sulfur atom in the formula; R²⁰⁸ and R²⁰⁹ each independently represent a hydrogen atom or an alkyl group having 1 to 5 carbon atoms, or may be bonded to each other to form a ring together with a sulfur atom in the formula; R²¹⁰ represents an aryl group that may have a substituent, an alkyl group that may have a substituent, an alkenyl group that may have a substituent, or an —SO₂-containing cyclic group that may have a substituent; L²⁰¹ represents —C(═O)— or —C(═O)—O—; a plurality of Y²⁰¹'s each independently represent an arylene group, an alkylene group, or an alkenylene group; x is 1 or 2; and W²⁰¹ represents a (x+1)-valent linking group.]

Examples of aryl groups in R²⁰¹ to R²⁰⁷, R²¹¹, and R²¹² include an aryl group having 6 to 20 carbon atoms, and a phenyl group or a naphthyl group is preferable.

The alkyl group as R²⁰¹ to R²⁰⁷, R²¹¹, and R²¹² is a chain-like or cyclic alkyl group, and the number of carbon atoms thereof is preferably in a range of 1 to 30. The alkenyl group as R²⁰¹ to R²⁰⁷, R²¹¹, and R²¹² preferably has 2 to 10 carbon atoms.

Examples of substituents which R²⁰¹ to R²⁰⁷, R²¹¹, and R²¹² include an alkyl group, a halogen atom, a halogenated alkyl group, a carbonyl group, a cyano group, an amino group, an aryl group, and groups represented by General Formulae (ca-r-1) to (ca-r-7).

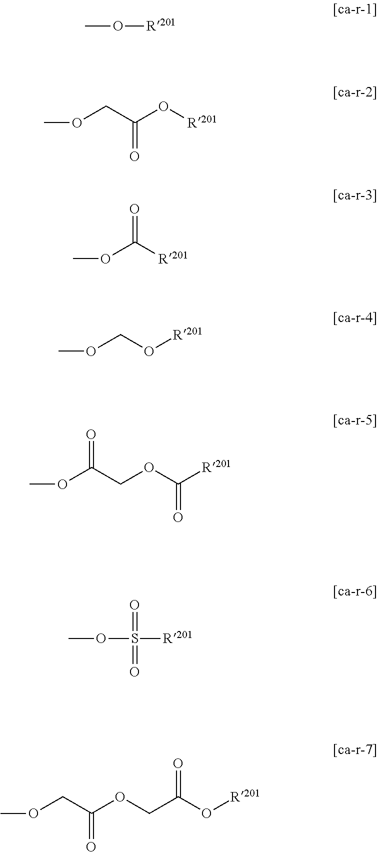

[In the formulae, each R′²⁰¹ independently represents a hydrogen atom, a cyclic group which may have a substituent, a chain-like alkyl group which may have a substituent, or a chain-like alkenyl group which may have a substituent.]

As a cyclic group which may have a substituent of R′²⁰¹, a chain-like alkyl group which may have a substituent, or a chain-like alkenyl group which may have a substituent, the same groups as those described for R¹⁰¹ in General Formula (b-1) are exemplified, and as a cyclic group which may have a substituent, or a chain-like alkyl group which may have a substituent, the same groups as those described for the acid dissociable group represented by General Formula (a1-r-2) are exemplified.

In a case where R²⁰¹ to R²⁰³, R²⁰⁶ and R²⁰⁷, and R²¹¹ and R²¹² are bonded to one another to form a ring with a sulfur atom in the formula, these groups may be bonded via a hetero atom such as a sulfur atom, an oxygen atom or a nitrogen atom, or a functional group such as a carbonyl group, —SO—, —SO₂—, —SO₀₃—, —COO—, —CONH— or —N(R_{N})— (here, R_{N} represents an alkyl group having 1 to 5 carbon atoms). As a ring to be formed, a ring containing the sulfur atom in the formula in the ring skeleton thereof is preferably a 3- to 10-membered ring and particularly preferably a 5- to 7-membered ring including the sulfur atom. Specific examples of the ring to be formed include a thiophene ring, a thiazole ring, a benzothiophene ring, a thianthrene ring, a benzothiophene ring, a dibenzothiophene ring, a 9H-thioxanthene ring, a thioxanthone ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ each represents an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂-containing cyclic group which may have a substituent.

Examples of the aryl group as R²¹⁰ include an unsubstituted aryl group having 6 to 20 carbon atoms, and a phenyl group or a naphthyl group is preferable.

As the alkyl group as R²¹⁰, a chain-like or cyclic alkyl group having 1 to 30 carbon atoms is preferable.

The alkenyl group as R²¹⁰ preferably has 2 to 10 carbon atoms.

As the —SO₂-containing cyclic group which may have a substituent in R²¹⁰, a “—SO₂-containing polycyclic group” is preferable, and a group represented by General Formula (a5-r-1) is more preferable.

Y²⁰¹'s each independently represent an arylene group, an alkylene group, or an alkenylene group.

Examples of arylene groups in Y²⁰¹ include a group in which one hydrogen atom has been removed from the aryl group exemplified as the aromatic hydrocarbon group in R¹⁰¹ in General Formula (b-1) to be described later.

Examples of alkylene groups and alkenylene groups in Y²⁰¹ include groups in which one hydrogen atom has been removed from the groups exemplified as the chain-like alkyl group and chain-like alkenyl group in R¹⁰¹ in General Formula (b-1) to be described later.

In Formula (ca-4), x is 1 or 2.

W²⁰¹ represents a (x+1)-valent linking group, that is, a divalent or trivalent linking group.

As the divalent linking group represented by W²⁰¹, a divalent hydrocarbon group which may have a substituent is preferable, and as examples thereof, the same divalent hydrocarbon groups which may have a substituent as those described above represented by Ya²¹ in General Formula (a2-1) can be exemplified. The divalent linking group as W²⁰¹ may be linear, branched or cyclic, and cyclic is more preferable. Among these, an arylene group having two carbonyl groups, each bonded to the terminal thereof is preferable. Examples of the arylene group include a phenylene group, and a naphthylene group, and a phenylene group is particularly preferable.

As the trivalent linking group as W²⁰¹, a group in which one hydrogen atom has been removed from the above-described divalent linking group as W²⁰¹ and a group in which the divalent linking group has been bonded to another divalent linking group can be exemplified. The trivalent linking group as W²⁰¹ is preferably a group in which two carbonyl groups are bonded to an arylene group.

Specific examples of preferable cations represented by Formula (ca-1) include cations represented by Chemical Formulae (ca-1-1) to (ca-1-78) and (ca-1-101) to (ca-1-149) to be described later.

In the following Chemical Formulae, g1 represents the number of repetitions, and g1 is an integer of 1 to 5. g2 represents the number of repetitions, and g2 is an integer of 0 to 20. g3 represents the number of repetitions, and g3 is an integer of 0 to 20.

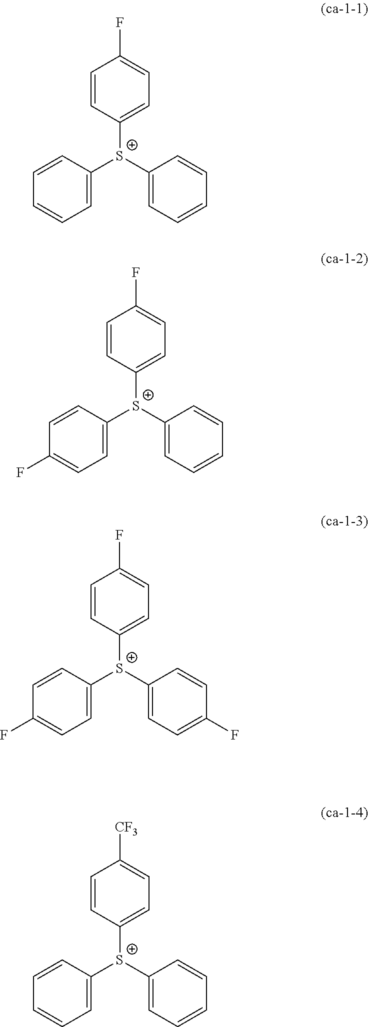 [SMILES: Fc1ccc([S+](c2ccccc2)c2ccccc2)cc1 ; Fc1ccc([S+](c2ccccc2)c2ccc(F)cc2)cc1 ; Fc1ccc([S+](c2ccc(F)cc2)c2ccc(F)cc2)cc1 ; FC(F)(F)c1ccc([S+](c2ccccc2)c2ccccc2)cc1]

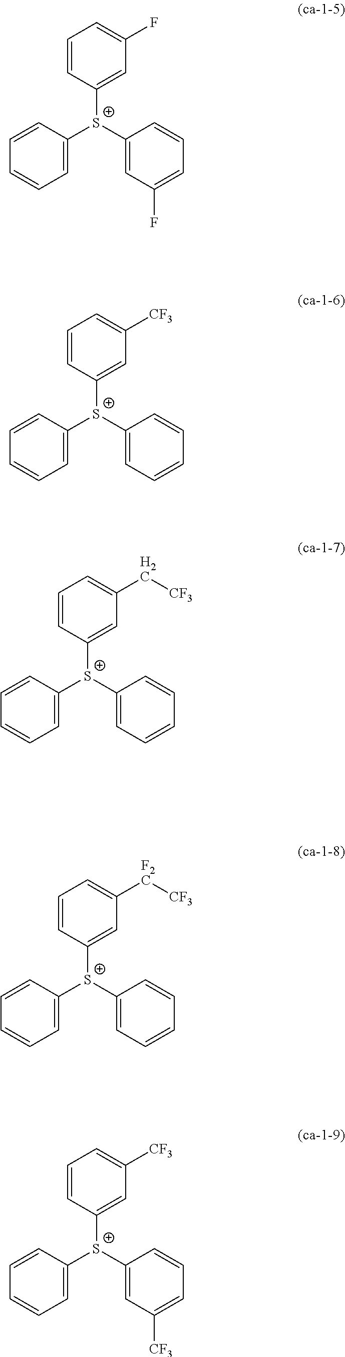 [SMILES: Fc1cccc([S+](c2ccccc2)c2cccc(F)c2)c1 ; FC(F)(F)c1cccc([S+](c2ccccc2)c2ccccc2)c1 ; FC(F)(F)Cc1cccc([S+](c2ccccc2)c2ccccc2)c1 ; FC(F)(F)C(F)(F)c1cccc([S+](c2ccccc2)c2ccccc2)c1 ; FC(F)(F)c1cccc([S+](c2ccccc2)c2cccc(C(F)(F)F)c2)c1]

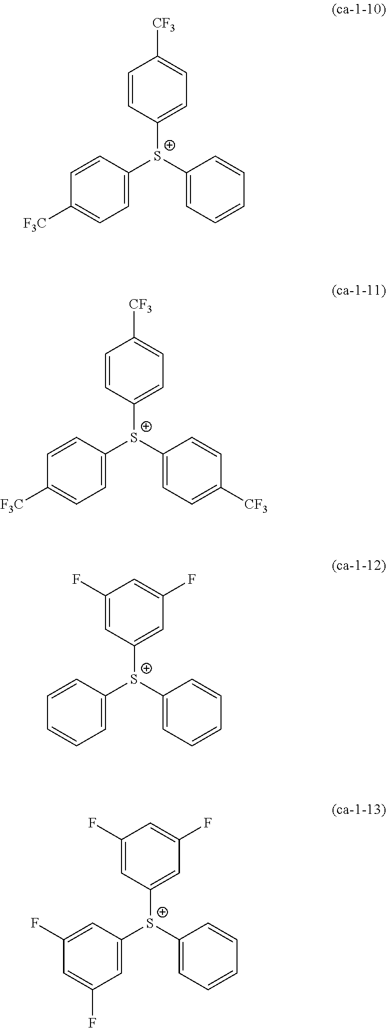 [SMILES: FC(F)(F)c1ccc([S+](c2ccccc2)c2ccc(C(F)(F)F)cc2)cc1 ; FC(F)(F)c1ccc([S+](c2ccc(C(F)(F)F)cc2)c2ccc(C(F)(F)F)cc2)cc1 ; Fc1cc(F)cc([S+](c2ccccc2)c2ccccc2)c1 ; Fc1cc(F)cc([S+](c2ccccc2)c2cc(F)cc(F)c2)c1]

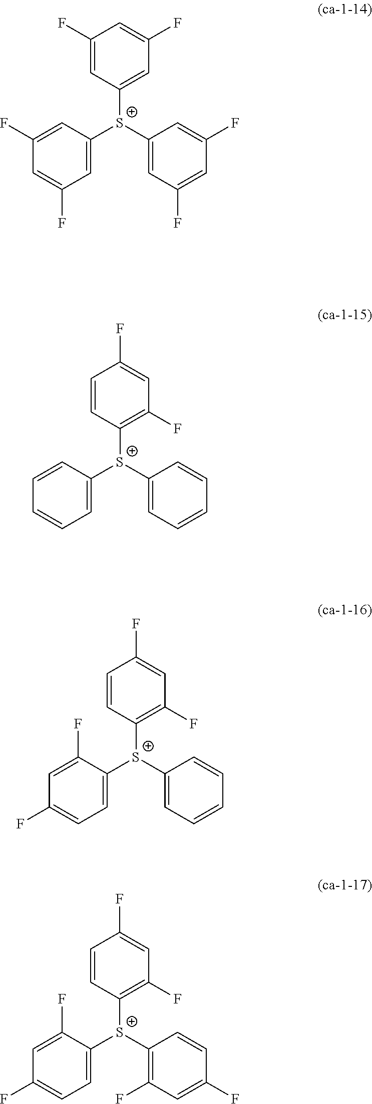 [SMILES: Fc1cc(F)cc([S+](c2cc(F)cc(F)c2)c2cc(F)cc(F)c2)c1 ; Fc1ccc([S+](c2ccccc2)c2ccccc2)c(F)c1 ; Fc1ccc([S+](c2ccccc2)c2ccc(F)cc2F)c(F)c1 ; Fc1ccc([S+](c2ccc(F)cc2F)c2ccc(F)cc2F)c(F)c1]

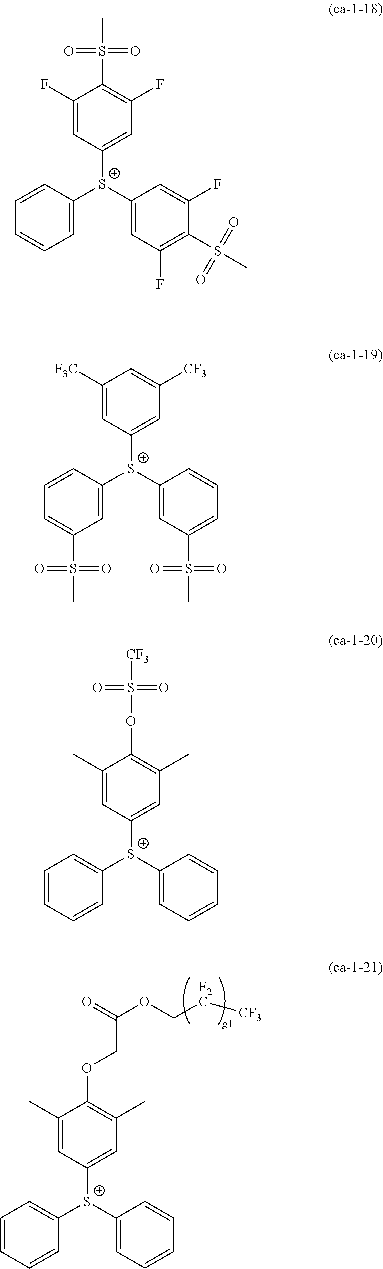

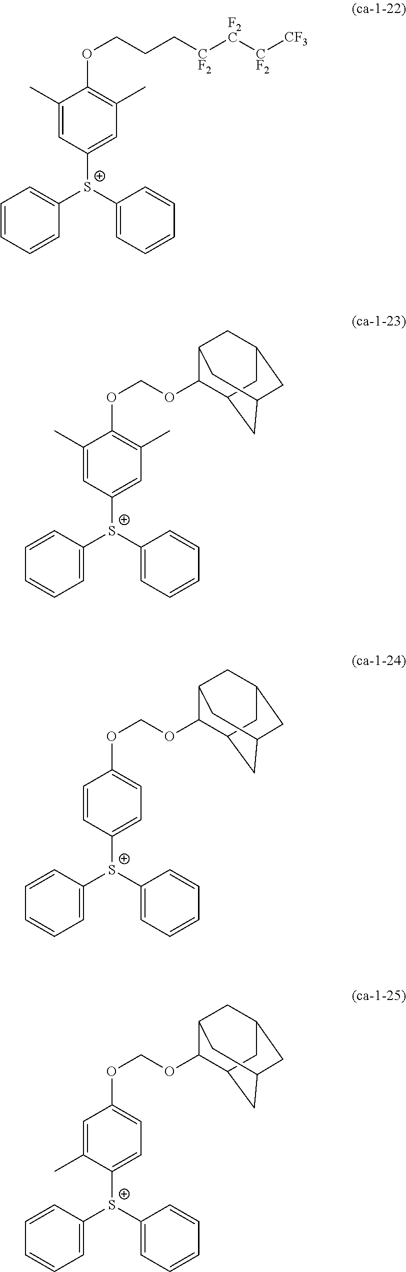 [SMILES: Cc1cc([S+](c2ccccc2)c2ccccc2)cc(C)c1OCCCC(F)(F)C(F)(F)C(F)(F)C(F)(F)F ; Cc1cc([S+](c2ccccc2)c2ccccc2)cc(C)c1OCOC1C2CC3CC(C2)CC1C3 ; c1ccc([S+](c2ccccc2)c2ccc(OCOC3C4CC5CC(C4)CC3C5)cc2)cc1 ; Cc1cc(OCOC2C3CC4CC(C3)CC2C4)ccc1[S+](c1ccccc1)c1ccccc1]

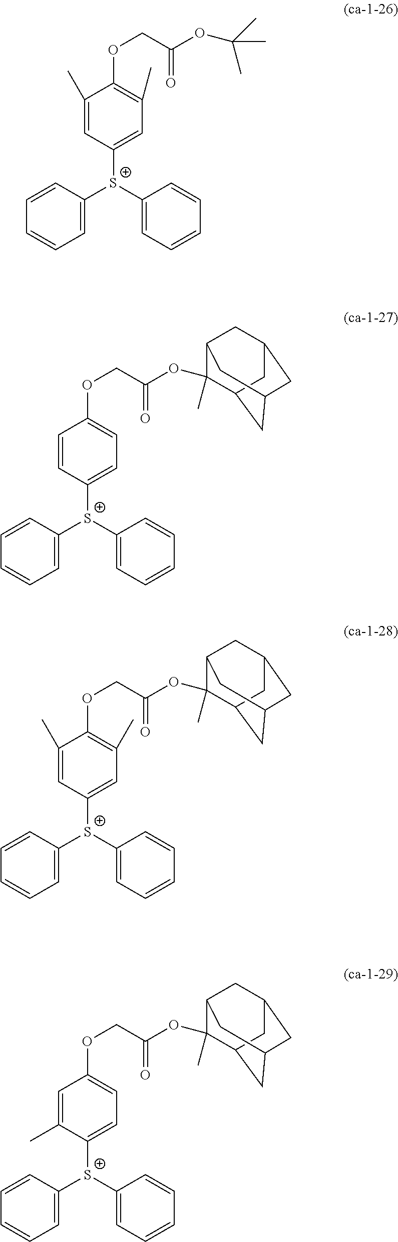 [SMILES: Cc1cc([S+](c2ccccc2)c2ccccc2)cc(C)c1OCC(=O)OC(C)(C)C ; CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3 ; Cc1cc(OCC(=O)OC2(C)C3CC4CC(C3)CC2C4)ccc1[S+](c1ccccc1)c1ccccc1]

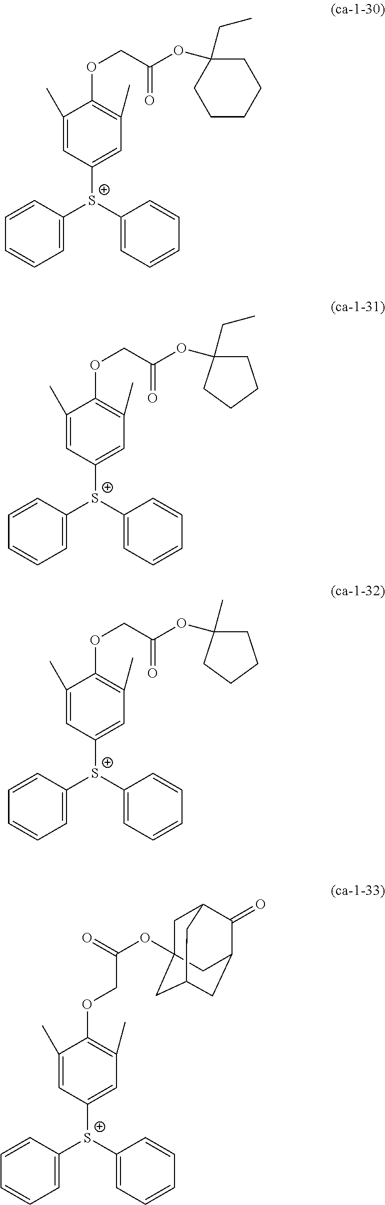 [SMILES: CCC1(OC(=O)COc2c(C)cc([S+](c3ccccc3)c3ccccc3)cc2C)CCCCC1 ; CCC1(OC(=O)COc2c(C)cc([S+](c3ccccc3)c3ccccc3)cc2C)CCCC1 ; Cc1cc([S+](c2ccccc2)c2ccccc2)cc(C)c1OCC(=O)OC1(C)CCCC1 ; Cc1cc([S+](c2ccccc2)c2ccccc2)cc(C)c1OCC(=O)OC12CC3CC(C1)C(=O)C(C3)C2]

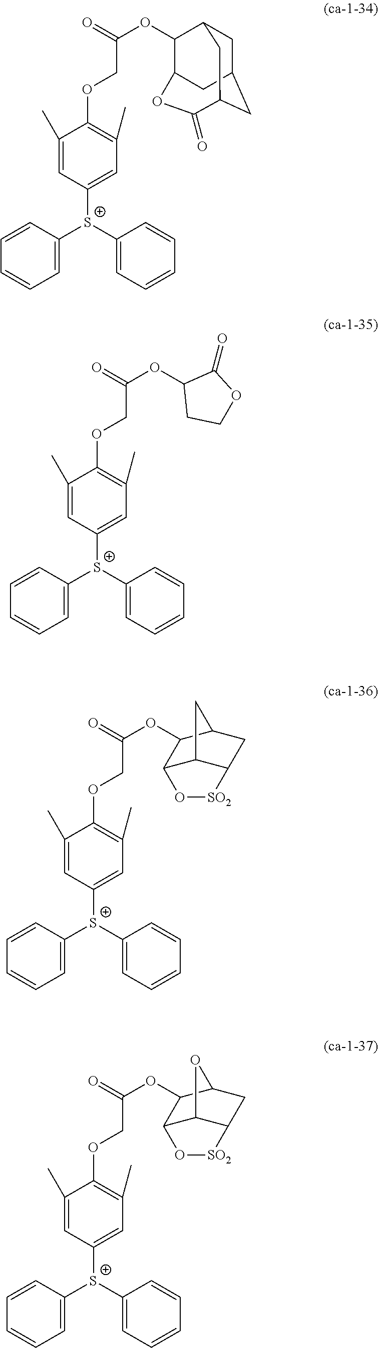 [SMILES: Cc1cc([S+](c2ccccc2)c2ccccc2)cc(C)c1OCC(=O)OC1C2CC3CC(C2)C(=O)OC1C3 ; Cc1cc([S+](c2ccccc2)c2ccccc2)cc(C)c1OCC(=O)OC1CCOC1=O ; Cc1cc([S+](c2ccccc2)c2ccccc2)cc(C)c1OCC(=O)OC1C2CC3C1OS(=O)(=O)C3C2 ; Cc1cc([S+](c2ccccc2)c2ccccc2)cc(C)c1OCC(=O)OC1C2CC3C(O2)C1OS3(=O)=O]

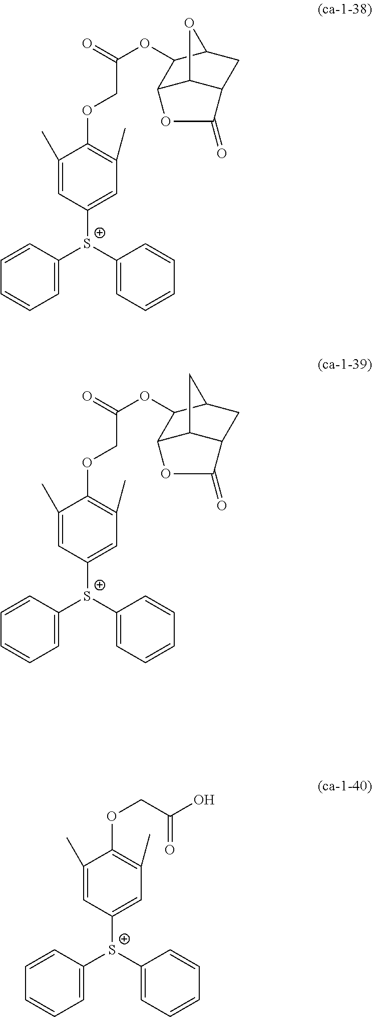 [SMILES: Cc1cc([S+](c2ccccc2)c2ccccc2)cc(C)c1OCC(=O)OC1C2CC3C(=O)OC1C3O2 ; Cc1cc([S+](c2ccccc2)c2ccccc2)cc(C)c1OCC(=O)OC1C2CC3C(=O)OC1C3C2 ; Cc1cc([S+](c2ccccc2)c2ccccc2)cc(C)c1OCC(=O)O]

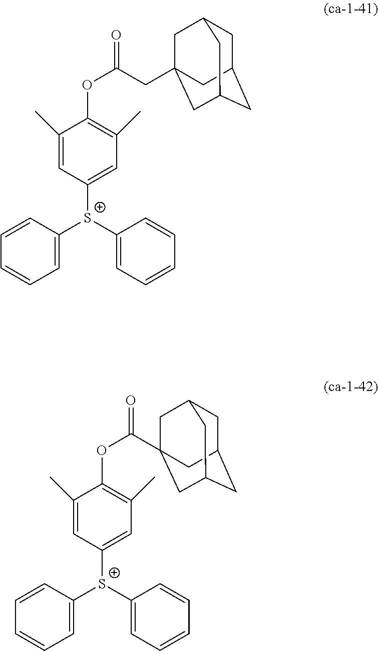 [SMILES: Cc1cc([S+](c2ccccc2)c2ccccc2)cc(C)c1OC(=O)CC12CC3CC(CC(C3)C1)C2 ; Cc1cc([S+](c2ccccc2)c2ccccc2)cc(C)c1OC(=O)C12CC3CC(CC(C3)C1)C2]

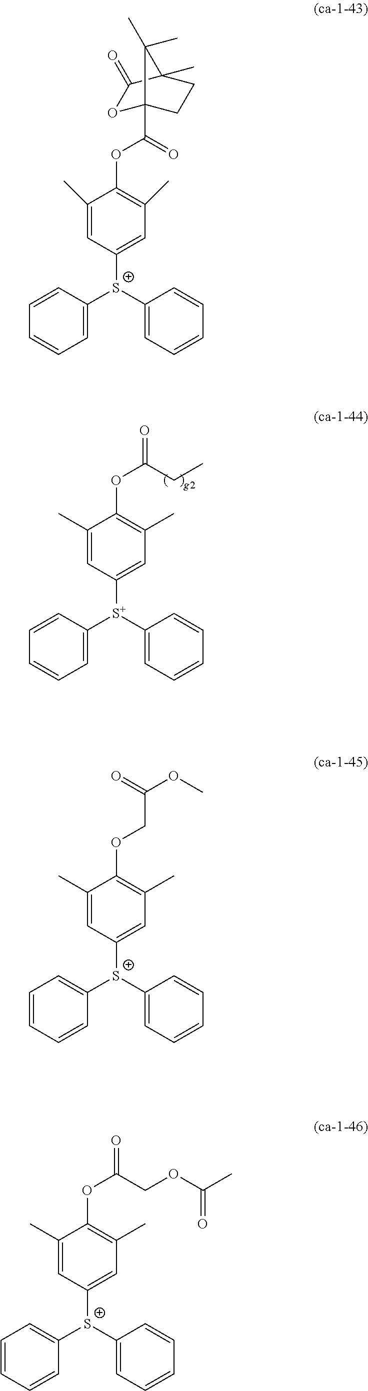

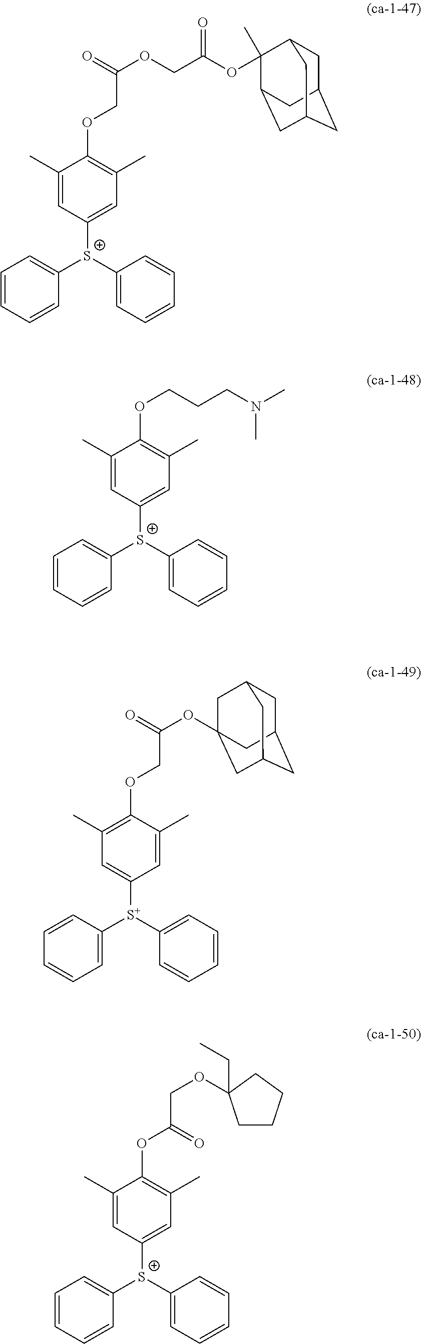 [SMILES: Cc1cc([S+](c2ccccc2)c2ccccc2)cc(C)c1OCC(=O)OCC(=O)OC1(C)C2CC3CC(C2)CC1C3 ; Cc1cc([S+](c2ccccc2)c2ccccc2)cc(C)c1OCCCN(C)C ; Cc1cc([S+](c2ccccc2)c2ccccc2)cc(C)c1OCC(=O)OC12CC3CC(CC(C3)C1)C2 ; CCC1(OCC(=O)Oc2c(C)cc([S+](c3ccccc3)c3ccccc3)cc2C)CCCC1]

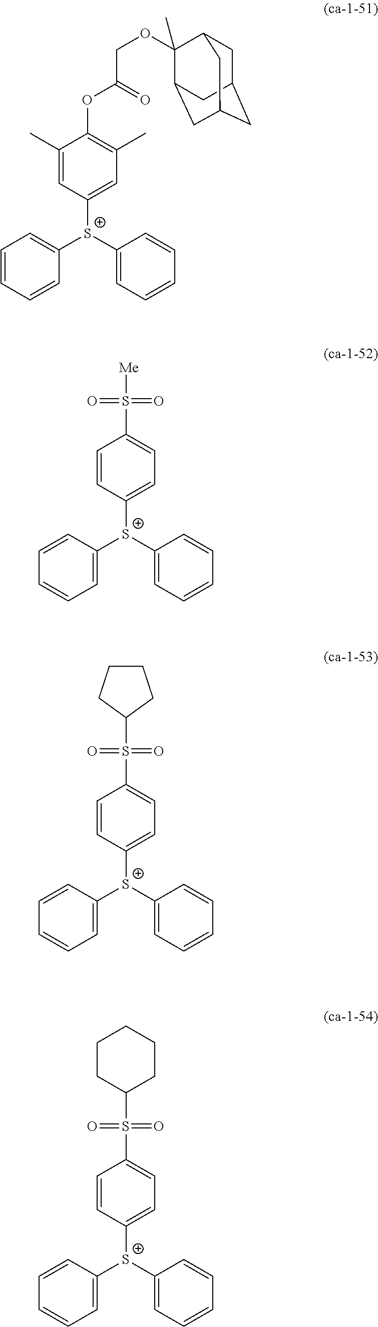 [SMILES: Cc1cc([S+](c2ccccc2)c2ccccc2)cc(C)c1OC(=O)COC1(C)C2CC3CC(C2)CC1C3 ; CS(=O)(=O)c1ccc([S+](c2ccccc2)c2ccccc2)cc1 ; O=S(=O)(c1ccc([S+](c2ccccc2)c2ccccc2)cc1)C1CCCC1 ; O=S(=O)(c1ccc([S+](c2ccccc2)c2ccccc2)cc1)C1CCCCC1]

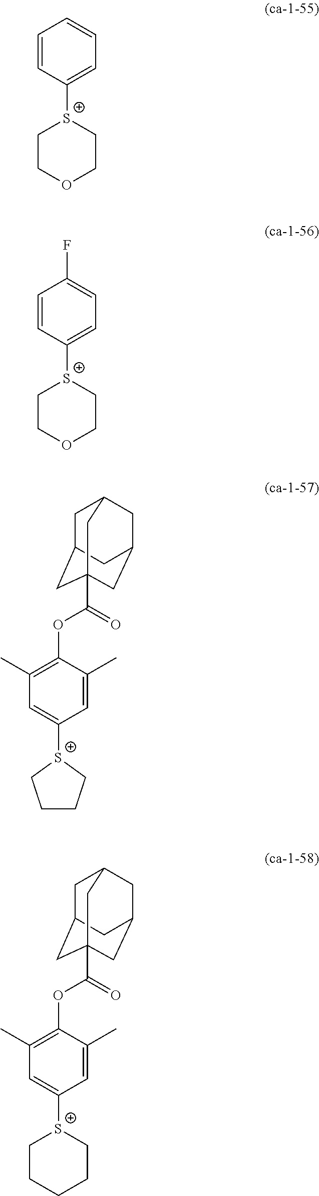 [SMILES: c1ccc([S+]2CCOCC2)cc1 ; Fc1ccc([S+]2CCOCC2)cc1 ; Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2]

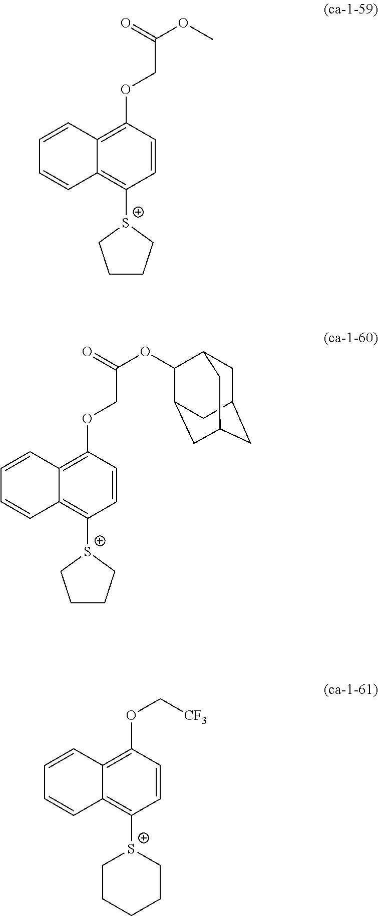 [SMILES: COC(=O)COc1ccc([S+]2CCCC2)c2ccccc12 ; O=C(COc1ccc([S+]2CCCC2)c2ccccc12)OC1C2CC3CC(C2)CC1C3 ; FC(F)(F)COc1ccc([S+]2CCCCC2)c2ccccc12]

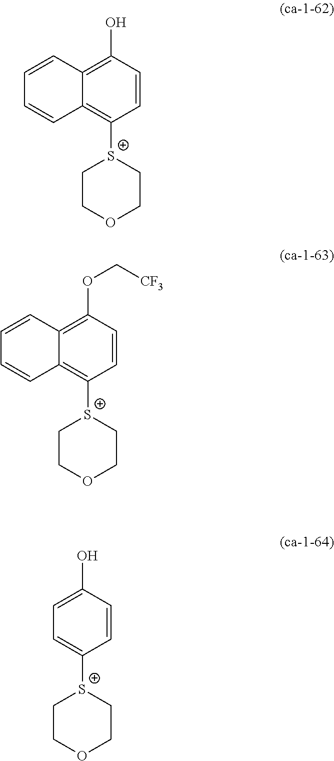 [SMILES: Oc1ccc([S+]2CCOCC2)c2ccccc12 ; FC(F)(F)COc1ccc([S+]2CCOCC2)c2ccccc12 ; Oc1ccc([S+]2CCOCC2)cc1]

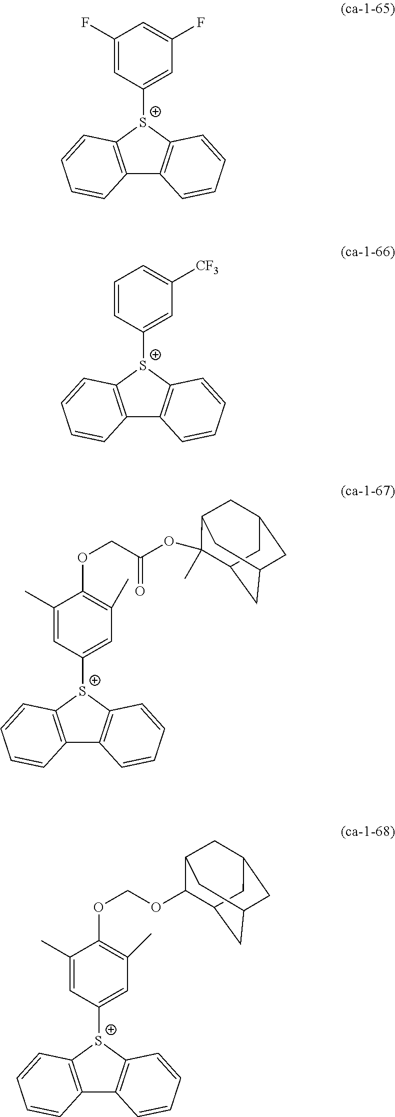 [SMILES: Fc1cc(F)cc(-[s+]2c3ccccc3c3ccccc32)c1 ; FC(F)(F)c1cccc(-[s+]2c3ccccc3c3ccccc32)c1 ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

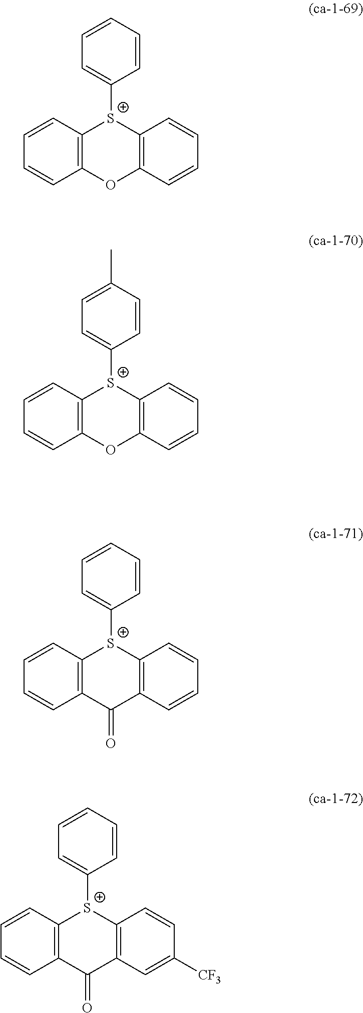 [SMILES: c1ccc([S+]2c3ccccc3Oc3ccccc32)cc1 ; Cc1ccc([S+]2c3ccccc3Oc3ccccc32)cc1 ; O=c1c2ccccc2[s+](-c2ccccc2)c2ccccc12 ; O=c1c2ccccc2[s+](-c2ccccc2)c2ccc(C(F)(F)F)cc12]

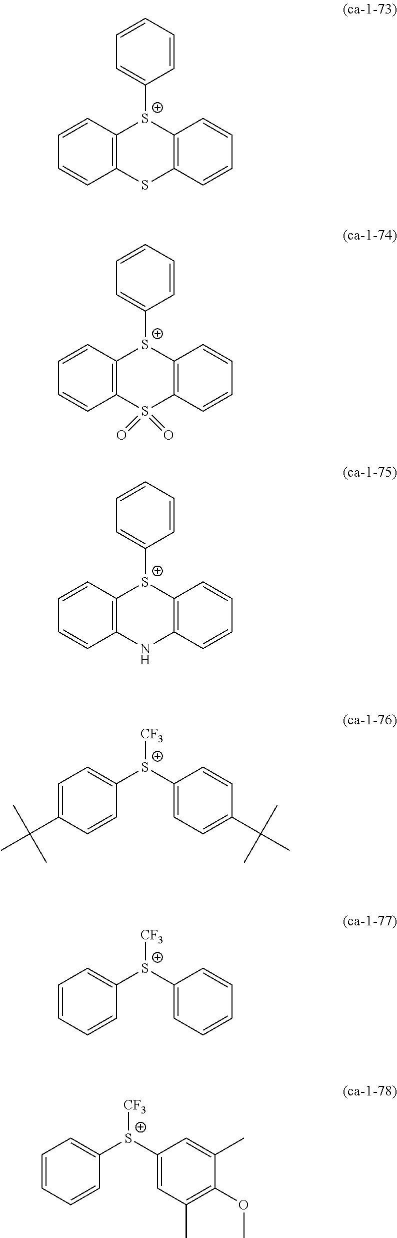 [SMILES: c1ccc([S+]2c3ccccc3Sc3ccccc32)cc1 ; O=S1(=O)c2ccccc2[S+](c2ccccc2)c2ccccc21 ; c1ccc([S+]2c3ccccc3Nc3ccccc32)cc1 ; CC(C)(C)c1ccc([S+](c2ccc(C(C)(C)C)cc2)C(F)(F)F)cc1 ; FC(F)(F)[S+](c1ccccc1)c1ccccc1 ; COc1c(C)cc([S+](c2ccccc2)C(F)(F)F)cc1C]

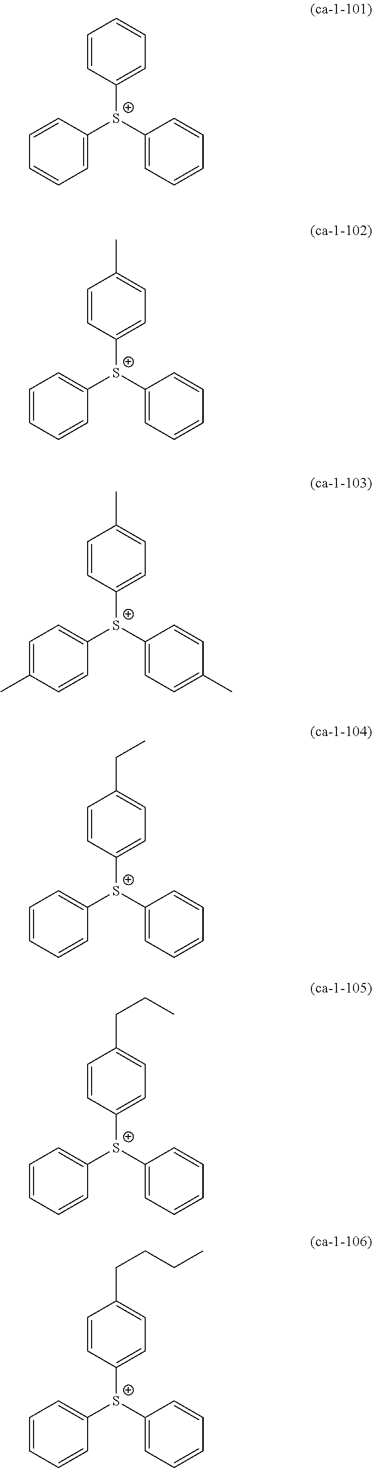

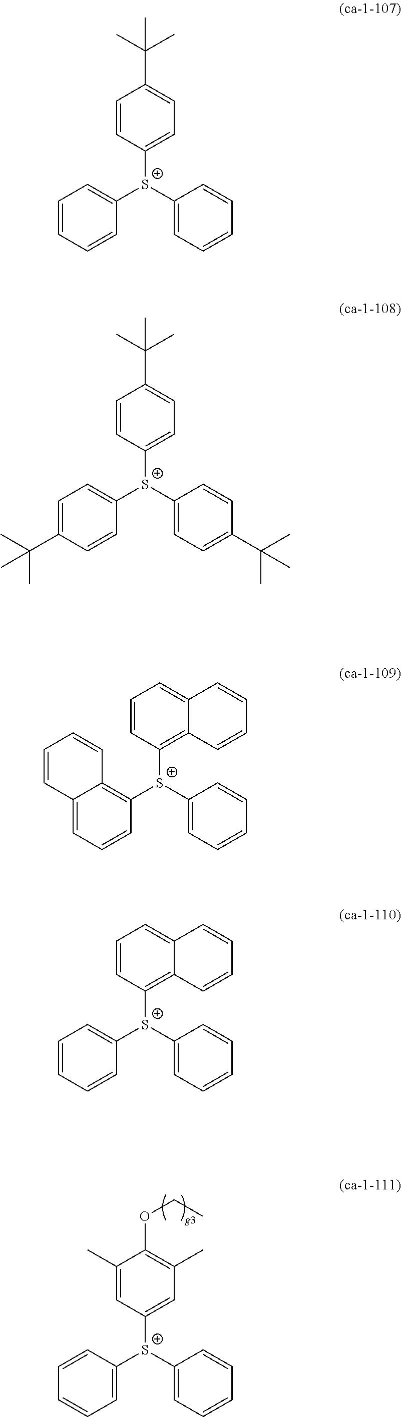

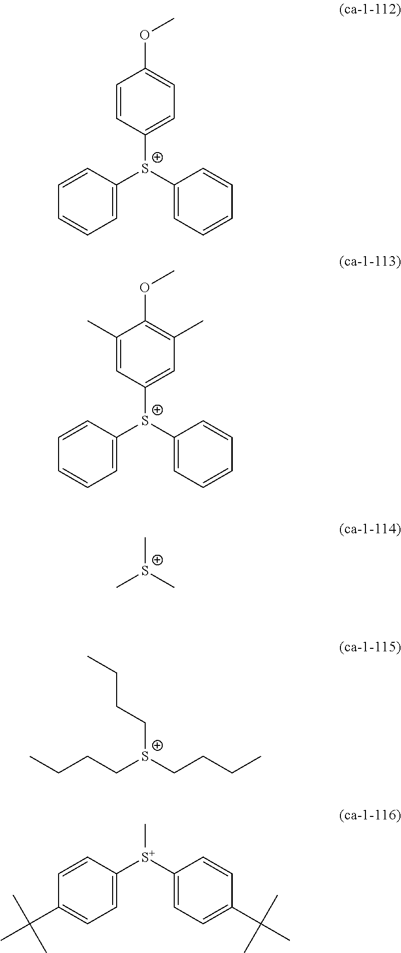

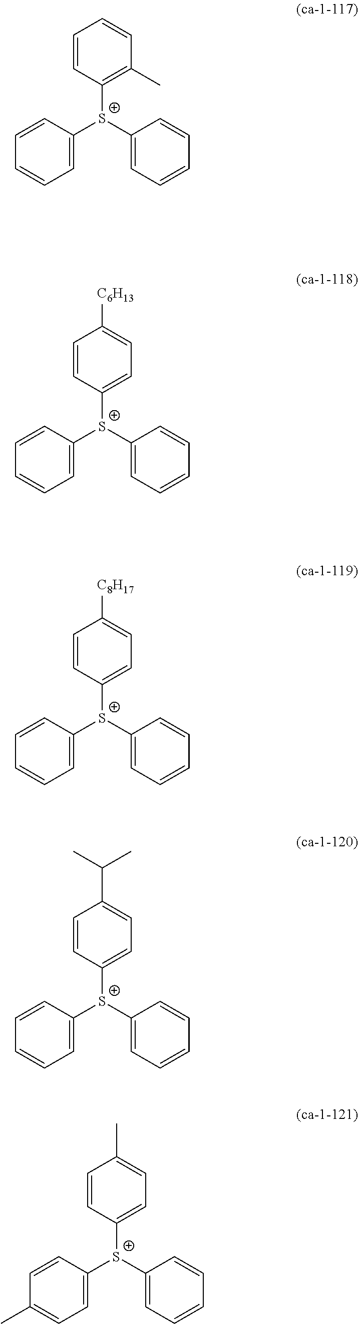

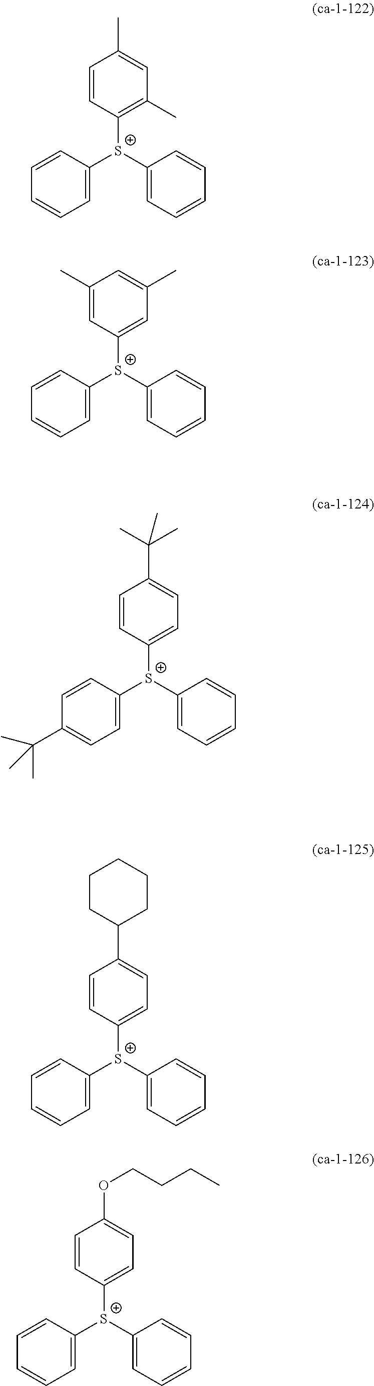 [SMILES: Cc1ccc([S+](c2ccccc2)c2ccccc2)c(C)c1 ; Cc1cc(C)cc([S+](c2ccccc2)c2ccccc2)c1 ; CC(C)(C)c1ccc([S+](c2ccccc2)c2ccc(C(C)(C)C)cc2)cc1 ; c1ccc([S+](c2ccccc2)c2ccc(C3CCCCC3)cc2)cc1 ; CCCCOc1ccc([S+](c2ccccc2)c2ccccc2)cc1]

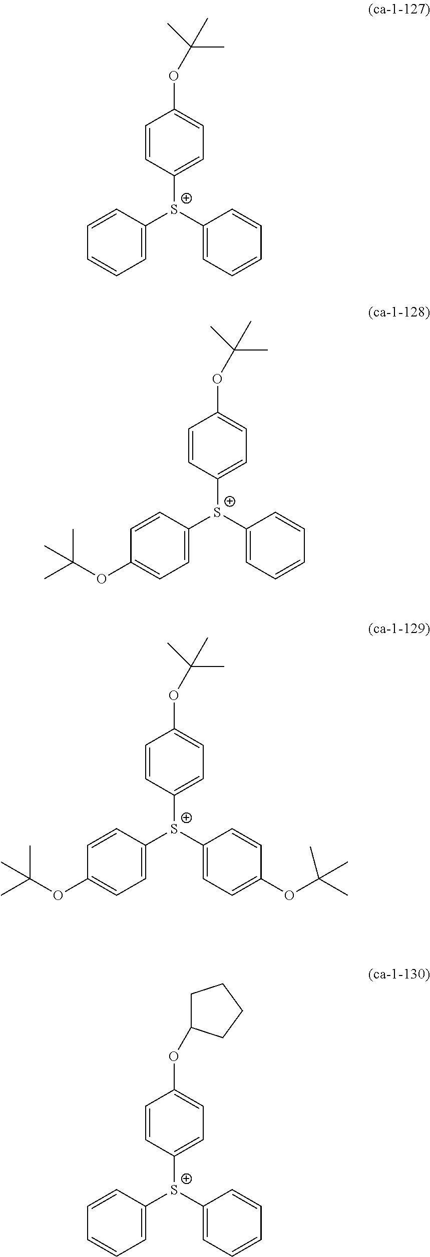 [SMILES: CC(C)(C)Oc1ccc([S+](c2ccccc2)c2ccccc2)cc1 ; CC(C)(C)Oc1ccc([S+](c2ccccc2)c2ccc(OC(C)(C)C)cc2)cc1 ; CC(C)(C)Oc1ccc([S+](c2ccc(OC(C)(C)C)cc2)c2ccc(OC(C)(C)C)cc2)cc1 ; c1ccc([S+](c2ccccc2)c2ccc(OC3CCCC3)cc2)cc1]

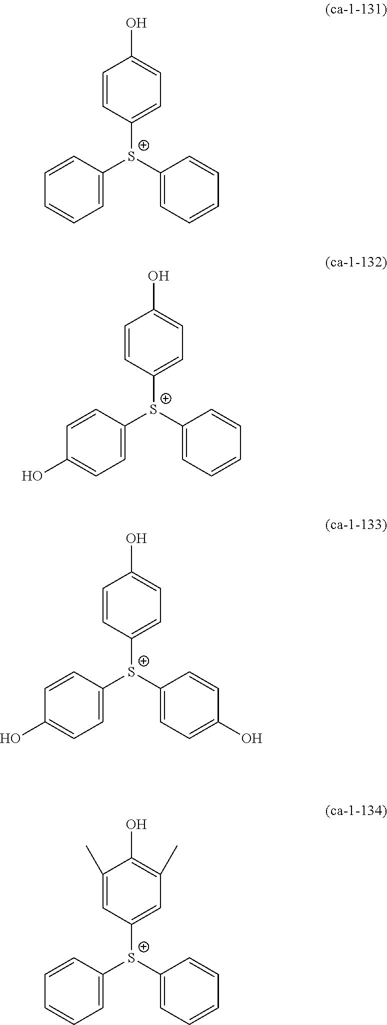 [SMILES: Oc1ccc([S+](c2ccccc2)c2ccccc2)cc1 ; Oc1ccc([S+](c2ccccc2)c2ccc(O)cc2)cc1 ; Oc1ccc([S+](c2ccc(O)cc2)c2ccc(O)cc2)cc1 ; Cc1cc([S+](c2ccccc2)c2ccccc2)cc(C)c1O]

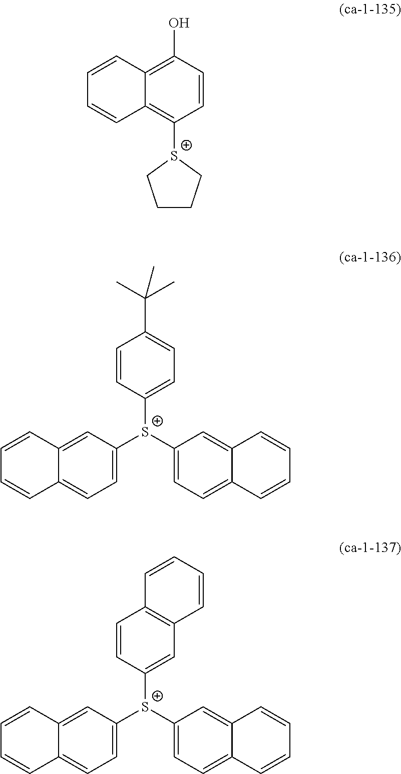 [SMILES: Oc1ccc([S+]2CCCC2)c2ccccc12 ; CC(C)(C)c1ccc([S+](c2ccc3ccccc3c2)c2ccc3ccccc3c2)cc1 ; c1ccc2cc([S+](c3ccc4ccccc4c3)c3ccc4ccccc4c3)ccc2c1]

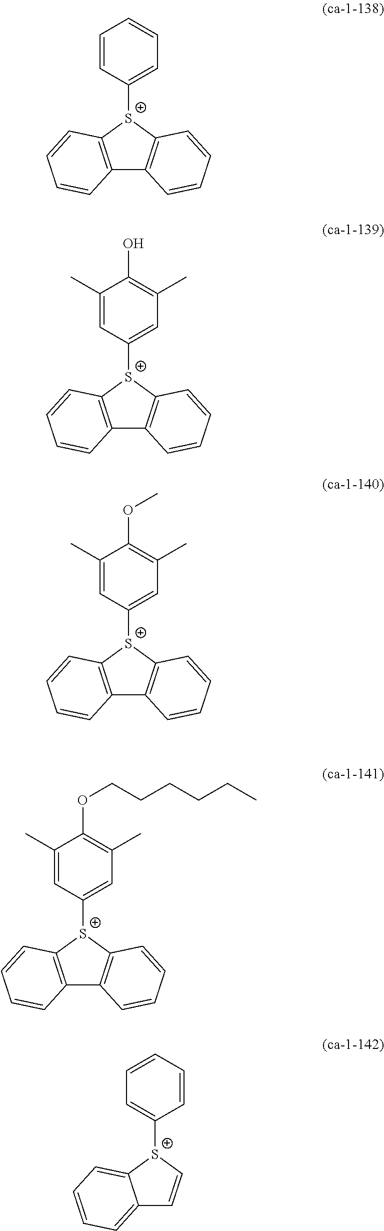 [SMILES: c1ccc(-[s+]2c3ccccc3c3ccccc32)cc1 ; Cc1cc(-[s+]2c3ccccc3c3ccccc32)cc(C)c1O ; COc1c(C)cc(-[s+]2c3ccccc3c3ccccc32)cc1C ; CCCCCCOc1c(C)cc(-[s+]2c3ccccc3c3ccccc32)cc1C ; c1ccc(-[s+]2ccc3ccccc32)cc1]

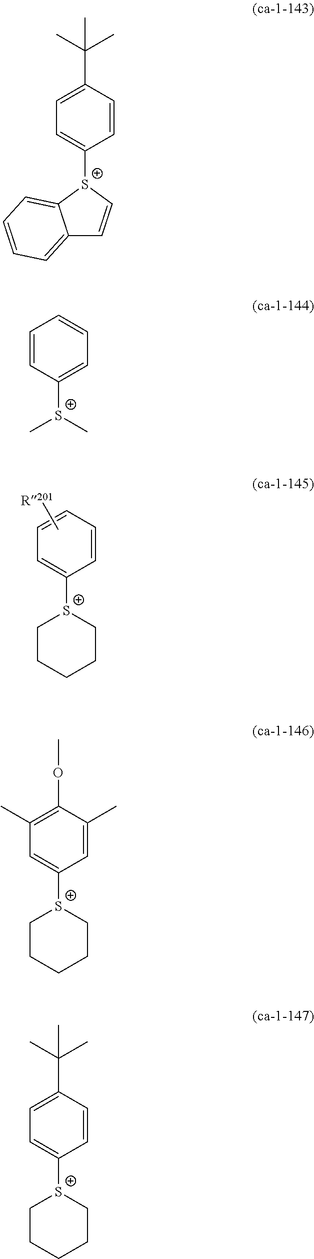

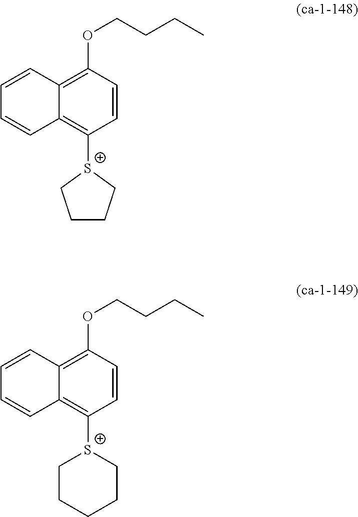 [SMILES: CCCCOc1ccc([S+]2CCCC2)c2ccccc12 ; CCCCOc1ccc([S+]2CCCCC2)c2ccccc12]

[In the formula, R″²⁰¹ is a hydrogen atom or a substituent; and examples of substituents include an alkyl group, a halogen atom, a halogenated alkyl group, a carbonyl group, a cyano group, an amino group, an aryl group, and groups respectively represented by General Formulae (ca-r-1) to (ca-r-7), which are exemplified as the substituents that R²⁰¹ to R²⁰⁷, R²¹¹, and R²¹² may have.]

Specific examples of preferable cations represented by Formula (ca-2) include cations respectively represented by Formulae (ca-2-1) to (ca-2-2), a diphenyliodonium cation, and a bis(4-tert-butylphenyl)iodonium cation.

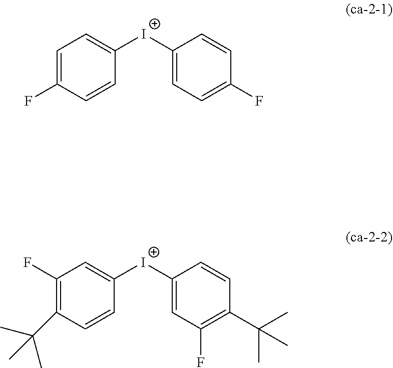 [SMILES: Fc1ccc([I+]c2ccc(F)cc2)cc1 ; CC(C)(C)c1ccc([I+]c2ccc(C(C)(C)C)c(F)c2)cc1F]

Specific examples of preferable cations represented by Formula (ca-3) include cations represented by Formulae (ca-3-1) and (ca-3-7) shown below.

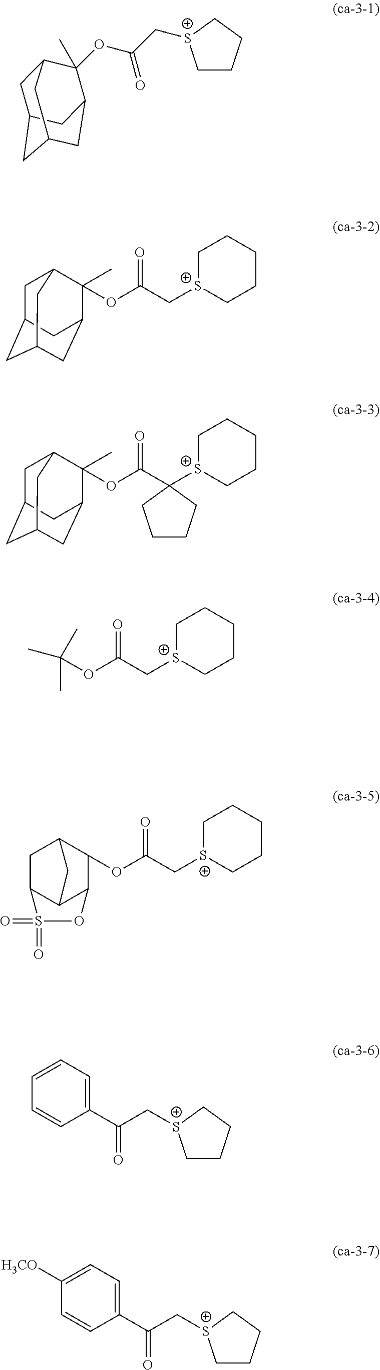

Specific examples of preferable cations represented by Formula (ca-4) include cations represented by Formulae (ca-4-1) and (ca-4-2) shown below.

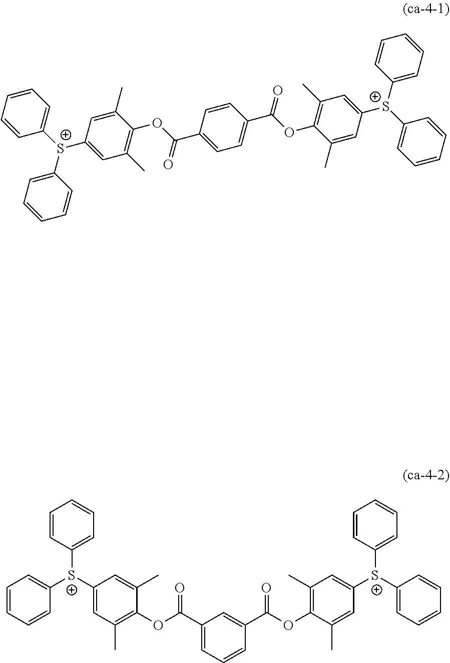 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Among them, the cation moiety ((M^{m+})_{1/m}) is preferably a cation represented by General Formula (ca-1), and is more preferably cations respectively represented by Chemical Formulae (ca-1-1) to (ca-1-78) and (ca-1-101) to (ca-1-149).

As an onium salt-based acid generator in the present embodiment, the component (b-1) is particularly preferable among the components (b-1), (b-2), and (b-3).

In the resist composition of the present embodiment, one kind of the component (B) may be used alone, or two or more kinds thereof may be used in combination.

In the resist composition contains the component (B), the content of the component (B) in the resist composition is preferably 10 parts by mass or more, more preferably in a range of 15 to 60 parts by mass, and still more preferably in a range of 20 to 50 parts by mass with respect to 100 parts by mass of the component (A).

By setting the content of the component (B) to be in the above-described range, pattern formation is sufficiently performed.

<<Component (D)>>

In addition to the component (A), or in addition to the component (A) and the component (B), the resist composition in the present embodiment may contain a base component (hereinafter referred to as the “component (D)”). The component (D) acts as a quencher (an acid diffusion control agent) which traps the acid generated in the resist composition upon exposure.

Examples of components (D) include a nitrogen-containing organic compound (D1) (hereinafter referred to as the “component (D1)”), a photodegradable base (D2) that loses acid diffusion controllability by being decomposed upon exposure and that does not correspond to the component (D1) (hereinafter referred to as the “component (D2)”), and the like.

In a case where a resist composition containing the component (D) is obtained, the contrast between exposed portions and unexposed portions of the resist film can be further improved at the time of formation of a resist pattern.

In Regard to Component (D1)

The component (D1) is a base component and is a nitrogen-containing organic compound component that acts as an acid diffusion control agent in the resist composition.

The component (D1) is not particularly limited as long as it acts as an acid diffusion control agent, and examples thereof include aliphatic amines and aromatic amines.

Among the aliphatic amines, secondary aliphatic amines and tertiary aliphatic amines are preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group having 12 or less carbon atoms (alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris {2-(2-methoxyethoxy)ethoxy)ethyl}amine, tris {2-(2-methoxyethoxymethoxy)ethyl}amine, tris {2-(1-methoxyethoxy)ethyl}amine, tris {2-(1-ethoxyethoxy)ethyl}amine, tris {2-(1-ethoxypropoxy)ethyl}amine, tris[2-{2-(2-hydroxyethoxy)ethoxy}ethyl]amine and triethanolamine triacetate, and triethanolamine triacetate is preferable.

Examples of aromatic amines include 4-dimethylaminopyridine, pyrrole, indole, pyrazole, imidazole and derivatives thereof as well as tribenzylamine, aniline compounds, N-tert-butoxycarbonylpyrrolidine, and the like.

One kind of the component (D1) may be used alone, or two or more kinds thereof may be used in combination.

Among them, the component (D1) is preferably an aromatic amine, and is more preferably an aniline compound. Examples of aniline compounds include 2,6-diisopropylaniline, N,N-dimethylaniline, N,N-dibutylaniline, N,N-dihexylaniline, and the like.

In Regard to Component (D2)

The component (D2) is not particularly limited as long as it decomposes upon exposure and loses acid diffusion controllability, and it is preferably one or more kinds of compounds selected from the group consisting of a compound represented by General Formula (d2-1) (hereinafter referred to as the “component (d2-1)”), a compound represented by General Formula (d2-2) (hereinafter referred to as the “component (d2-2)”), and a compound represented by General Formula (d2-3) (hereinafter referred to as the “component (d2-3)”).

At exposed portions of the resist film, the components (d2-1) to (d2-3) are decomposed and then lose the acid diffusion controllability (basicity), and therefore the components (d2-1) to (d2-3) cannot act as a quencher, whereas at unexposed portions of the resist film, the components (d2-1) to (d2-3) acts as a quencher.

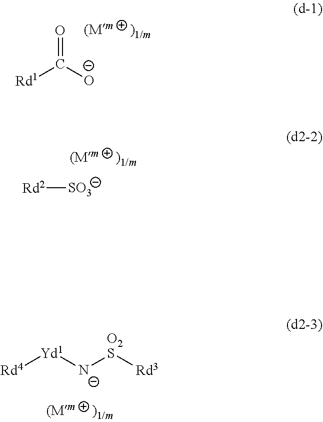

[In the formula, R^{d1} to R^{d4} represents a cyclic group which may have a substituent, a chain-like alkyl group which may have a substituent, or a chain-like alkenyl group which may have a substituent; where, the carbon atom adjacent to an S atom in Rd² in General Formula (d2-2) has no fluorine atom bonded thereto; Yd¹ is a single bond or a divalent linking group; and m is an integer of 1 or more, and M′^{m+}'s each independently are an m-valent onium cation.]

{Component (d2-1)}

Anion Moiety

In Formula (d2-1), Rd¹ represents a cyclic group which may have a substituent, a chain-like alkyl group which may have a substituent or a chain-like alkenyl group which may have a substituent, and examples thereof are the same as those described above as R¹⁰¹ in General Formula (b-1).

Among them, as Rd¹, an aromatic hydrocarbon group which may have a substituent, an aliphatic cyclic group which may have a substituent and a chain-like alkyl group which may have a substituent are preferable.

Examples of the substituent that these groups may have a hydroxyl group, an oxo group, an alkyl group, an aryl group, a fluorine atom, a fluorinated alkyl group, a lactone-containing cyclic group represented by any of General Formulae (a2-r-1) to (a2-r-7), an ether bond, an ester bond, and a combination thereof. In a case where an ether bond or an ester bond is included as the substituent, the substituent may be bonded via an alkylene group, and a linking group represented by any of General Formulae (y-a1-1) to (y-a1-5) is preferable as the substituent in this case.

Preferable examples of the aromatic hydrocarbon group include a phenyl group, a naphthyl group, and a polycyclic structure (such as a polycyclic structure composed of a ring structure of a bicyclooctane skeleton and other ring structures) containing a bicyclooctane skeleton.

As the aliphatic cyclic group, groups in which one or more hydrogen atoms have been removed from a polycycloalkane such as adamantane, norbornane, isobomane, tricyclodecane or tetracyclododecane are more preferable.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may contain an atom other than a fluorine atom. Examples of the atom other than a fluorine atom include an oxygen atom, a sulfur atom, and a nitrogen atom.

As Rd¹, a fluorinated alkyl group in which some or all hydrogen atoms constituting a linear alkyl group have been substituted with fluorine atoms is preferable, and a fluorinated alkyl group in which all of the hydrogen atoms constituting a linear alkyl group have been substituted with fluorine atoms (a linear perfluoroalkyl group) is particularly preferable.

Specific examples of preferable anion moieties for the component (d2-1) are shown below.

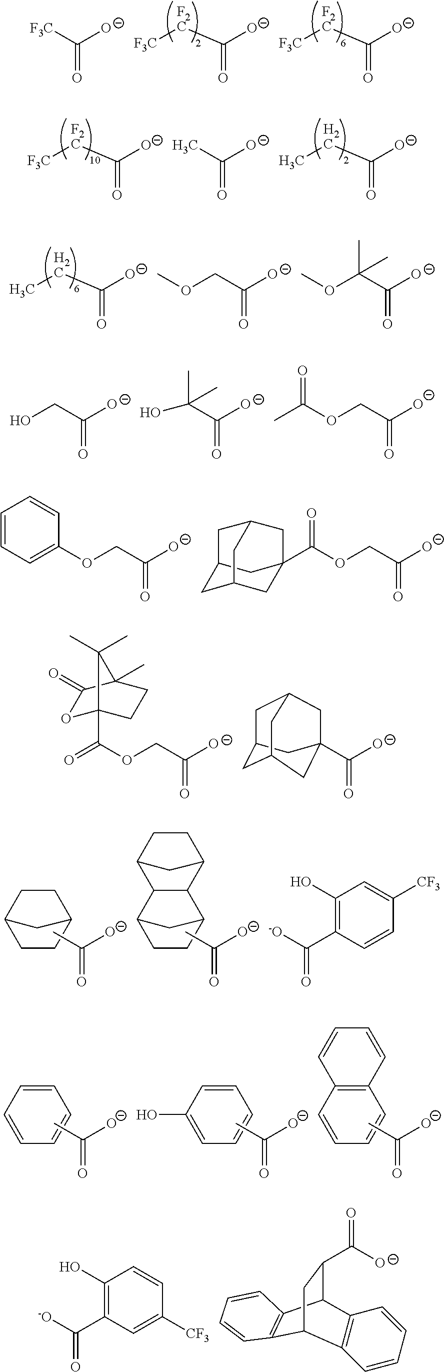

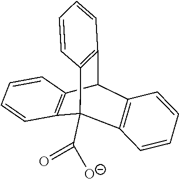 [SMILES: O=C([O-])C12c3ccccc3C(c3ccccc31)c1ccccc12]

Cation Moiety

In Formula (d2-1), M′^{m+} is an m-valent onium cation. 5 As the onium cation as M′^{m+}, the same cations as those represented by General Formulae (ca-1) to (ca-4) are preferably exemplified, a cation represented by the above-described General Formula (ca-1) is more preferable, and cations represented General Formula (ca-1-1) to (ca-1-78) and (ca-1-101) to (ca-1-149) are still more preferable.

One kind of the component (d2-1) may be used alone or two or more kinds thereof may be used in combination.

{Component (d2-2)}

Anion Moiety

In Formula (d2-2), Rd² represents a cyclic group which may have a substituent, a chain-like alkyl group which may have a substituent or a chain-like alkenyl group which may have a substituent, and examples thereof are the same as those described above as R¹⁰¹ in General Formula (b-1).

Here, the carbon atom adjacent to the S atom in Rd² has no fluorine atom bonded thereto (the carbon atom adjacent to the sulfur atom in Rd² is not substituted with a fluorine). As a result, the anion of the component (d2-2) becomes an appropriately weak acid anion, thereby improving the quenching ability of the component (D2).

As Rd², a chain-like alkyl group which may have a substituent or an aliphatic cyclic group which may have a substituent is preferable. The chain-like alkyl group has preferably 1 to 10 carbon atoms and more preferably 3 to 10 carbon atoms. As the aliphatic cyclic group, a group in which one or more hydrogen atoms have been removed from adamantane, norbornane, isobomane, tricyclodecane, or tetracyclododecane (which may have a substituent) and a group in which one or more hydrogen atoms have been removed from camphor are more preferable.

The hydrocarbon group as Rd² may have a substituent. As the substituent, the same groups as the substituents which may be included in the hydrocarbon group (such as an aromatic hydrocarbon group, an aliphatic cyclic group, or a chain-like alkyl group) as Rd¹ in Formula (d2-1) can be exemplified.

Specific examples of preferable anion moieties for the component (d2-2) are shown below.

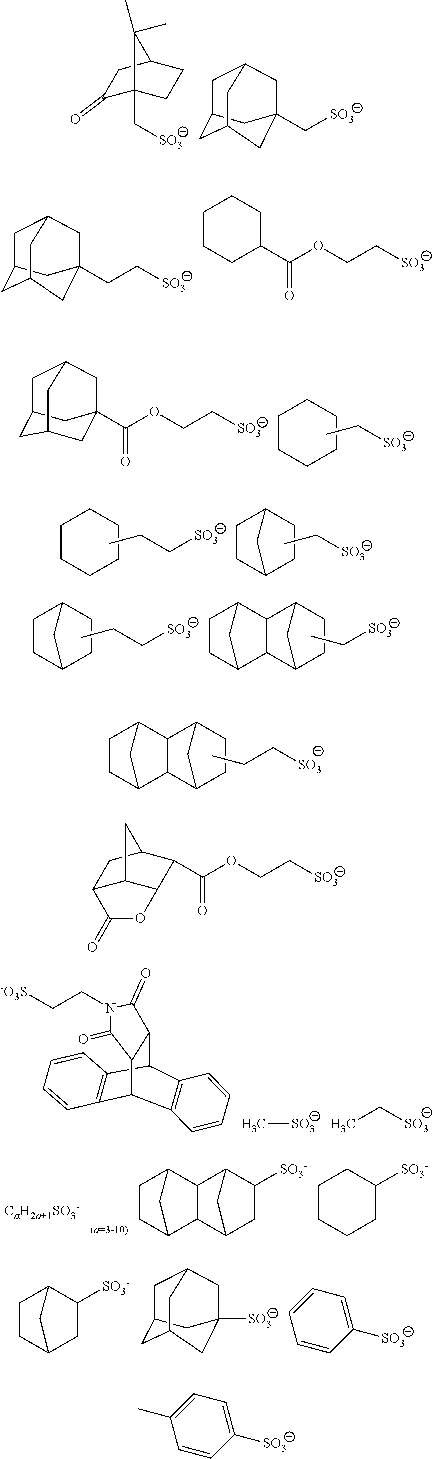

Cation Moiety

In Formula (d2-2), M′^{m+} is an m-valent onium cation, which is the same as M′^{m+} in Formula (d2-1).

One kind of the component (d2-2) may be used alone or two or more kinds thereof may be used in combination.

{Component (d2-3)}

Anion Moiety

In Formula (d2-3), Rd³ represents a cyclic group which may have a substituent, a chain-like alkyl group which may have a substituent, or a chain-like alkenyl group which may have a substituent, and the same groups as those described above as R¹⁰¹ in General Formula (b-1) are exemplified, and a cyclic group containing a fluorine atom, a chain-like alkyl group, or a chain-like alkenyl group is preferable. Among these, a fluorinated alkyl group is preferable, and the same fluorinated alkyl groups as those described above as Rd¹ are more preferable.

In Formula (d2-3), Rd⁴ represents a cyclic group which may have a substituent, a chain-like alkyl group which may have a substituent or a chain-like alkenyl group which may have a substituent, and examples thereof are the same as those described above as R¹⁰¹ in General Formula (b-1).

Among these, an alkyl group which may have a substituent, an alkoxy group which may have a substituent, an alkenyl group which may have a substituent, or a cyclic group which may have a substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. Some hydrogen atoms in the alkyl group as Rd⁴ may be substituted with a hydroxyl group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

Examples of the alkenyl group as Rd⁴ are the same groups as those exemplified as the alkenyl group represented by R¹⁰¹ in General Formula (b-1), and a vinyl group, a propenyl group (an allyl group), a 1-methylpropenyl group, and a 2-methylpropenyl group are preferable. These groups may have an alkyl group having 1 to 5 carbon atoms or a halogenated alkyl group having 1 to 5 carbon atoms as a substituent.

As the cyclic group as Rd⁴, the same groups as those described above as R¹⁰¹ in General Formula (b-1) can be exemplified. Among these, as the cyclic group, an alicyclic group in which one or more hydrogen atoms have been removed from a cycloalkane such as cyclopentane, cyclohexane, adamantane, norbornane, isobomane, tricyclodecane or tetracyclododecane or an aromatic group such as a phenyl group or a naphthyl group is preferable. In a case where Rd⁴ represents an alicyclic group, the resist composition can be satisfactorily dissolved in an organic solvent, thereby improving the lithography characteristics.

In Formula (d2-3), Yd¹ represents a single bond or a divalent linking group. The divalent linking group as Yd¹ is not particularly limited, and examples thereof include a divalent hydrocarbon group (an aliphatic hydrocarbon group or an aromatic hydrocarbon group) which may have a substituent and a divalent linking group containing a hetero atom. Examples thereof include are the same as those described above as the divalent hydrocarbon group which may have a substituent and the divalent linking group containing a hetero atom, which are explained above as the divalent linking group as Ya^{x1} in Formula (a10-1).

As Yd¹, a carbonyl group, an ester bond, an amide bond, an alkylene group, or a combination of these is preferable. As the alkylene group, a linear or branched alkylene group is more preferable, and a methylene group or an ethylene group is still more preferable.

Specific examples of preferable anion moieties for the component (d2-3) are shown below.

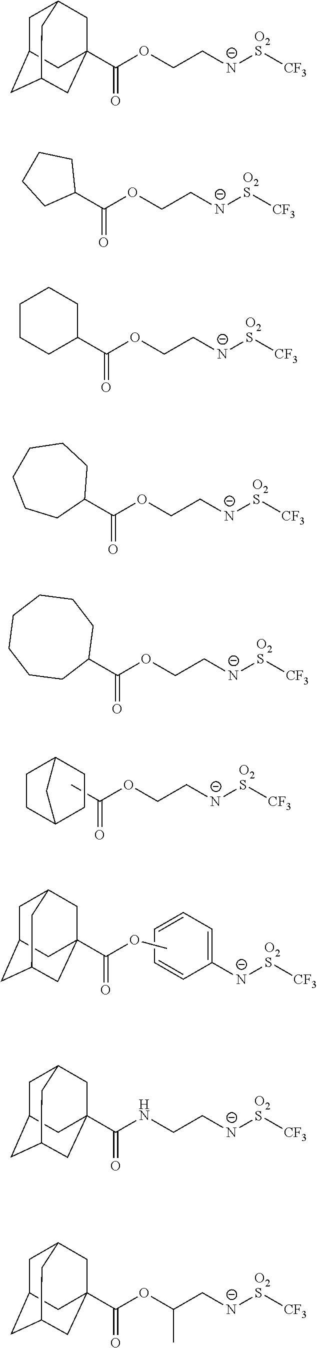

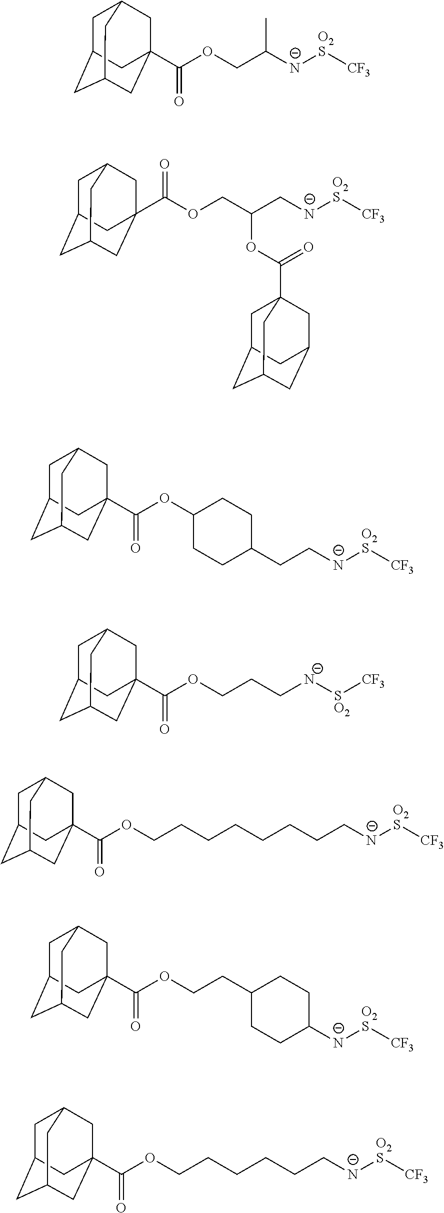

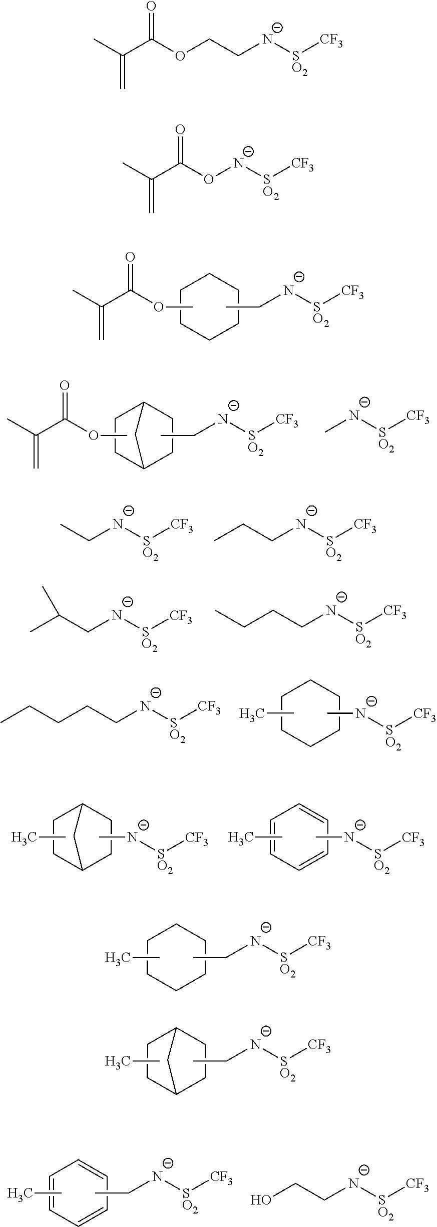

Cation Moiety

In Formula (d2-3), M′^{m+} is an m-valent onium cation, which is the same as M′^{m+} in Formula (d2-1).

One kind of the component (d2-3) may be used alone or two or more kinds thereof may be used in combination.

As the component (D2), only one of the above-described components (d2-1) to (d2-3) or a combination of two or more kinds thereof may be used.

In a case where the resist composition contains the component (D2), the content of the component (D2) in the resist composition is preferably within a range of 0.05 to 35 parts by mass, more preferably within a range of 0.1 to 25 parts by mass, still more preferably within a range of 0.5 to 20 parts by mass, and particularly preferably within a range of 1 to 15 parts by mass with respect to 100 parts by mass of the component (A). In a case where the content of the component (D2) is equal to or more than the preferable lower limit value, in particular, excellent lithography characteristics and an excellent resist pattern shape can be more reliably obtained. Meanwhile, in a case where the content thereof is equal to or less than the upper limit value, it is possible to balance it with other components, and thereby various lithography characteristics become favorable.

Method of Producing Component (D2):

The production methods of the components (d2-1) and (d2-2) are not particularly limited, and the components (d2-1) and (d2-2) can be produced by known methods.

Further, the method of producing the component (d2-3) is not particularly limited, and the component (d2-3) can be produced in the same manner as disclosed in United States Patent Application, Publication No. 2012-0149916.

Among them, as the component (D) of the resist composition in the present embodiment, the component (D2) is preferable, and the component (d2-1) is more preferable.

<<Component (E): At Least One Compound Selected from the Group Consisting of Organic Carboxylic Acids and Phosphorus Oxo Acids, and Derivatives Thereof>>

For the purpose of preventing any deterioration in sensitivity, and improving the resist pattern shape and the post exposure temporal stability, the resist composition of the present embodiment may contain at least one compound (E) (hereinafter referred to as the component (E)) selected from the group consisting of organic carboxylic acids and phosphorus oxo acids, and derivatives thereof as an optional component.

Preferable examples of organic carboxylic acids include acetic acid, malonic acid, citric acid, malic acid, succinic acid, benzoic acid, salicylic acid, and the like.

Examples of phosphorus oxo acids include phosphoric acid, phosphonic acid, and phosphinic acid. Among these, phosphonic acid is particularly preferable.

Examples of phosphorus oxo acid derivatives include esters in which a hydrogen atom in the above-described oxo acids is substituted with a hydrocarbon group.

Examples of the hydrocarbon group include an alkyl group having 1 to 5 carbon atoms and an aryl group having 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate, and dibenzyl phosphonate.

Examples of phosphinic acid derivatives include phosphinic acid esters and phenylphosphinic acid.

In the resist composition of the present embodiment, one kind of the component (E) may be used alone, or two or more kinds thereof may be used in combination.

In a case where the resist composition contains the component (E), the content of the component (E) is typically in a range of 0.01 to 5 parts by mass, with respect to 100 parts by mass of the component (A).

<<Component (F): Fluorine Additive Component>>

The resist composition in the present embodiment may contain a fluorine additive component (hereinafter referred to as the “component (F)”) in order to impart water repellency to a resist film or improve lithography characteristics.

As the component (F), a fluorine-containing polymer compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be exemplified.

Specific examples of the component (F) include polymers having a structural unit (f1) represented by Formula (f1-1) shown below. As the polymer, a polymer (homopolymer) formed of only a structural unit (f1) represented by Formula (f1-1) shown below; a copolymer of the structural unit (f1) and the structural unit (a4); a copolymer of the structural unit (f1) and the structural unit (a1); and a copolymer of the structural unit (f1), a structural unit derived from acrylic acid or methacrylic acid, and the above-described structural unit (a1) are preferable. The above-described structural unit (a1) copolymerized with the structural unit (f1) is preferably a structural unit derived from 1-ethyl-1-cyclooctyl(meth)acrylate, or a structural unit derived from 1-methyl-1-adamantyl(meth)acrylate.

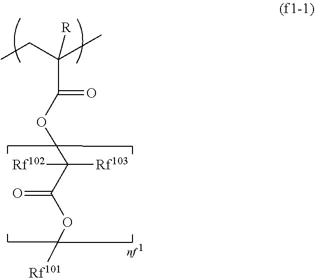

[In the formula, R is as defined above, Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer of 0 to 5, and Rf¹⁰¹ represents an organic group containing a fluorine atom.]

In Formula (f1-1), R bonded to the carbon atom at the α-position is as defined above. As R, a hydrogen atom or a methyl group is preferable.

In Formula (f1-1), examples of the halogen atom as Rf¹⁰² and Rf¹⁰³ include a fluorine atom, a chlorine atom, a bromine atom, and an iodine atom, and a fluorine atom is particularly preferable. Examples of the alkyl group having 1 to 5 carbon atoms as Rf¹⁰² and Rf¹⁰³ include those described above as the alkyl group having 1 to 5 carbon atoms as R, and a methyl group or an ethyl group is preferable. Specific examples of the halogenated alkyl group having 1 to 5 carbon atoms as Rf¹⁰² and Rf¹⁰³ include groups in which some or all hydrogen atoms of the alkyl groups of 1 to 5 carbon atoms have been substituted with halogen atoms.

Examples of the halogen atom include a fluorine atom, a chlorine atom, a bromine atom and an iodine atom, and a fluorine atom is particularly preferable. Among these examples, as Rf¹⁰² and Rf¹⁰³, a hydrogen atom, a fluorine atom, or an alkyl group having 1 to 5 carbon atoms is preferable, and a hydrogen atom, a fluorine atom, a methyl group, or an ethyl group is more preferable.

In Formula (f1-1), nf¹ represents an integer of 0 to 5, preferably an integer of 0 to 3, and more preferably an integer of 0 or 1.

In Formula (f1-1), Rf¹⁰¹ represents an organic group containing a fluorine atom, and is preferably a hydrocarbon group containing a fluorine atom.

The hydrocarbon group containing a fluorine atom may be linear, branched, or cyclic, and has preferably 1 to 20 carbon atoms, more preferably 1 to 15 carbon atoms, and particularly preferably 1 to 10 carbon atoms.

Among these, as Rf¹⁰¹, a fluorinated hydrocarbon group having 1 to 6 carbon atoms is preferable, and a trifluoromethyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃ are particularly preferable.

The weight-average molecular weight (Mw) (in the viewpoint of polystyrene determined by gel permeation chromatography) of the component (F) is preferably in a range of 1,000 to 50,000, more preferably in a range of 5,000 to 40,000, and most preferably in a range of 10,000 to 30,000. In a case where Mw thereof is equal to or less than the upper limit value within this range, a solubility in a solvent for resist which is a sufficient level for the resist composition to be used as a resist is achieved, and in a case where Mw thereof is equal to or more than the lower limit value within this range, dry etching resistance and resist pattern cross-sectional shape are favorable.

Further, the dispersity (Mw/Mn) of the component (F) is preferably in a range of 1.0 to 5.0, more preferably in a range of 1.0 to 3.0, and most preferably in a range of 1.0 to 2.5.

In the resist composition in the present embodiment, one kind of the component (F) may be used alone, or two or more kinds thereof may be used in combination.

In a case where the resist composition contains the component (F), the content of the component (F) is typically in a range of 0.5 to 10 parts by mass, with respect to 100 parts by mass of the component (A).

<<Component (S): Organic Solvent Component>>

The resist composition in the present embodiment may be produced by dissolving the resist materials in an organic solvent component (hereinafter, referred to as a “component (S)”).

The component (S) may be any organic solvent component which can dissolve the respective components to be used to obtain a uniform solution, and optional organic solvent component can be appropriately selected from those which have been conventionally known as solvents for a chemically amplified resist composition and then used.

Examples of the component (S) include lactones such as γ-butyrolactone; ketones such as acetone, methyl ethyl ketone, cyclohexanone, methyl-n-pentyl ketone, methyl isopentyl ketone, 2-heptanone, ethylene carbonate, and propylene carbonate; polyhydric alcohols such as ethylene glycol, diethylene glycol, propylene glycol, and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (such as monomethylether, monoethylether, monopropylether, or monobutylether) or monophenylether of any of these polyhydric alcohols or compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO).

In the resist composition in the present embodiment, one kind of the component (S) may be used alone, or two or more kinds thereof may be used in the form of a mixed solvent.

Among them, PGMEA, PGME, γ-butyrolactone, propylene carbonate, EL, and cyclohexanone are preferable.

In addition, a mixed solvent in which PGMEA is mixed with a polar solvent is also preferable. The mixing ratio (mass ratio) of the mixed solvent can be appropriately determined, taking into consideration the compatibility of the PGMEA with the polar solvent, but is preferably in the range of 1:9 to 9:1 and more preferably in a range of 2:8 to 8:2.

More specifically, in a case where EL or cyclohexanone is mixed as the polar solvent, the PGMEA:EL or cyclohexanone mass ratio is preferably in a range of 1:9 to 9:1 and more preferably in a range of 2:8 to 8:2. Alternatively, in a case where PGME is mixed as the polar solvent, the PGMEA:PGME mass ratio is preferably in a range of 1:9 to 9:1, more preferably in a range of 2:8 to 8:2, and still more preferably in a range of 3:7 to 7:3. Furthermore, a mixed solvent of PGMEA, PGME and cyclohexanone is also preferable.

Further, as the component (S), a mixed solvent of at least one of PGMEA and EL, and at least one selected from γ-butyrolactone and propylene carbonate is also preferable. The mass ratio (former:latter) of such a mixed solvent is preferably within a range of 60:40 to 99:1, and is more preferably within a range of 70:30 to 95:5.

The amount of the component (S) used is not particularly limited, and is appropriately adjusted to a concentration which enables coating of a coating solution to a substrate according to the coating film thickness. In general, the component (S) is used in an amount such that the solid content concentration of the resist composition becomes in the range of 0.1% to 20% by mass and preferably in a range of 0.2% to 15% by mass.

The resist composition in the present embodiment may contain miscible additives such as additive resins, dissolution inhibitors, plasticizers, stabilizers, colorants, halation prevention agents, and dyes for improving the performance of the resist film, as appropriate.

In addition, the resist composition of the present embodiment may be prepared by dissolving the above-mentioned resist material in the component (S), and then removing impurities using a polyimide porous film, a polyamideimide porous film, or the like. For example, the resist composition may be filtered using a filter made of a polyimide porous film, a filter made of a polyamideimide porous film, a filter made of a polyimide porous film and a polyamideimide porous film, or the like. Examples of polyimide porous films and polyamideimide porous films include those described in Japanese Unexamined Patent Application, First Publication No. 2016-155121.

The resist composition of the present embodiment contains the above-described component (A), and the above-mentioned optional components as necessary.

Preferable examples thereof include a resist composition containing the component (A) and the component (B). More preferable examples thereof include a resist composition containing the component (A), the component (B), and the component (D).

As described above, the resist composition of the present embodiment contains the above-described resin component (A1). The resin component (A1) has a structural unit (a01) having a specific acid dissociable group having high reactivity with respect to an acid. Furthermore, the resin component (A1) has a structural unit (a02) having high affinity with respect to a developing solution and a rinse solution, and a structural unit (a03) that has an aromatic ring hydroxy group that functions as a proton source and thus can improve sensitivity by improving an amount of acid generated. In addition, because the structural unit (a01), the structural unit (a02), and the structural unit (a03) all have appropriate bulkiness, Tg of the resin component (a polymer compound) having the structural unit (a01), the structural unit (a02), and the structural unit (a03) is improved, and thereby acid diffusion is favorably controlled.

For this reason, it is estimated that, according to the resist composition of the present embodiment, it is possible to favorably control acid diffusion and improve affinity with respect to a developing solution, and thereby all of a sensitivity, roughness reduction performance, and resolution performance are further improved.

(Method of Forming a Resist Pattern)

A method of forming a resist pattern according to the second aspect of the present invention includes a step of forming a resist film on a support using the resist composition according to the embodiment described above; a step of exposing the resist film; and a step of developing the exposed resist film to form a resist pattern.

According to the embodiment of the method of forming a resist pattern, a method of forming a resist pattern by performing processes as described below is exemplified.

First, a resist composition according to the embodiment is applied to a support using a spinner or the like, and a baking treatment (post applied bake (PAB)) is conducted at a temperature condition of 80 to 150° C. for 40 to 120 seconds and preferably 60 to 90 seconds, to form a resist film.

Following selective exposure of the thus formed resist film, by exposure through a mask having a predetermined pattern formed thereon (mask pattern) using an exposure apparatus such as an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment. The developing treatment is conducted using an alkali developing solution in a case of an alkali developing process, and a developing solution containing an organic solvent (organic developing solution) in a case of a solvent developing process.

After the developing treatment, it is preferable to conduct a rinse treatment. The rinse treatment is preferably a water rinsing using pure water in a case of an alkali developing process, and a rinse treatment using a rinse solution containing an organic solvent in a case of a solvent developing process.

In a case of a solvent developing process, after the developing treatment or the rinse treatment, the developing solution or the rinse solution remaining on the pattern can be removed by a treatment using a supercritical fluid.

After the developing treatment or the rinse treatment, drying is conducted. As desired, baking treatment (post bake) may be conducted following the developing treatment.

In this manner, a resist pattern can be formed.

The support is not particularly limited and a conventionally known support can be used. For example, substrates for electronic components, and such substrates having predetermined wiring patterns formed thereon can be used. More specific examples thereof include a substrate made of a metal such as silicon wafer, copper, chromium, iron, or aluminum; and a glass substrate. Preferable materials for the wiring pattern include copper, aluminum, nickel, and gold.

Further, as the support, any one of the above-described supports provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper-layer resist film) are provided on a substrate, and a resist pattern formed on the upper-layer resist film is used as a mask to conduct patterning of the lower-layer organic film. This method is considered as being capable of forming a pattern with a high aspect ratio. That is, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiation such as an ArF excimer laser, a KrF excimer laser, an F₂ excimer laser, extreme ultraviolet (EUV) rays, vacuum ultraviolet (VUV) rays, electron beams (EB), X-rays, and soft X-rays. The resist composition is highly useful for KrF excimer laser, ArF excimer laser, and EB or EUV, is further highly useful for ArF excimer laser, and EB or EUV, and is particularly highly useful for EB or EUV. That is, the method of forming a resist pattern of the present embodiment is a particularly useful method in a case where a step of exposing a resist film has an operation of exposing the resist film to extreme ultraviolet (EUV) rays or electron beam (EB).

The exposure of the resist film can be a general exposure (dry exposure) conducted in air or an inert gas such as nitrogen, or liquid immersion lithography.

In the liquid immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium is preferably a solvent having a refractive index larger than the refractive index of air but smaller than the refractive index of the resist film to be exposed. The refractive index of such a solvent is not particularly limited as long as the refractive index is within the above range.

Examples of the solvent having a refractive index that is larger than the refractive index of air but smaller than the refractive index of the resist film include water, fluorine-based inert liquids, silicon-based solvents, and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, and the boiling point is preferably in a range of 70° to 180° C. and more preferably in a range of 80° to 160° C. A fluorine-based inert liquid having a boiling point in the above-described range is preferable since the removal of the immersion medium after the exposure can be conducted by a simple method.

As a fluorine-based inert liquid, a perfluoroalkyl compound in which all of the hydrogen atoms of the alkyl group are substituted with fluorine atoms is particularly preferable. Examples of these perfluoroalkyl compounds include perfluoroalkylether compounds and perfluoroalkylamine compounds.

Specifically, an example of a perfluoroalkylether compound is perfluoro(2-butyl-tetrahydrofuran) (boiling point of 102° C.), and an example of a perfluoroalkylamine compound is perfluorotributylamine (boiling point of 174° C.).

As the immersion medium, water is preferable in the viewpoint of cost, safety, environment issue and versatility.

As an example of the alkali developing solution used in developing treatment in an alkali developing process, an aqueous solution of 0.1 to 10 mass % tetramethylammonium hydroxide (TMAH) can be exemplified.

As the organic solvent contained in the organic developing solution used in a solvent developing process, any of the conventional organic solvents can be used which are capable of dissolving the component (A) (component (A) prior to exposure) and be suitably selected from well-known organic solvents. Specific examples of the organic solvent include polar solvents such as ketone-based solvents, ester-based solvents, alcohol-based solvents, nitrile-based solvents, amide-based solvents, ether-based solvents, and hydrocarbon solvents.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxyl group in the structure thereof. An “alcoholic hydroxyl group” indicates a hydroxyl group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Among organic solvents, some organic solvents have a plurality of the functional groups which characterizes the above-described solvents in the structure thereof. In such a case, the organic solvent can be classified as any type of the solvent having the characteristic functional group. For example, diethylene glycol monomethylether can be classified as an alcohol-based solvent or an ether-based solvent. A hydrocarbon solvent includes a hydrocarbon which may be halogenated, and does not have any substituent other than a halogen atom. Examples of the halogen atom include a fluorine atom, a chlorine atom, a bromine atom and an iodine atom, and a fluorine atom is preferable.

As the organic solvent contained in the organic developing solution, among these, a polar solvent is preferable, and ketone-based solvents, ester-based solvents, and nitrile-based solvents are preferable.

Examples of ketone-based solvents include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone, and methyl amyl ketone (2-heptanone). Among these examples, as a ketone-based solvent, methyl amyl ketone (2-heptanone) is preferable.

Examples of ester-based solvents include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these examples, as an ester-based solvent, butyl acetate is preferable.

Examples of nitrile-based solvents include acetonitrile, propionitrile, valeronitrile, and butyronitrile.

As desired, the organic developing solution may have a known additive blended. Examples of the additive include surfactants. The surfactant is not particularly limited, and for example, an ionic or non-ionic fluorine and/or silicon-based surfactant can be used.

As the surfactant, a non-ionic surfactant is preferable, and a non-ionic fluorine-based surfactant or a non-ionic silicon-based surfactant is more preferable.

In a case where a surfactant is added, the amount thereof based on the total amount of the organic developing solution is generally 0.001% to 5% by mass, preferably 0.005% to 2% by mass, and more preferably 0.01% to 0.5% by mass.

The developing treatment can be performed by a known developing method. Examples thereof include a method in which the support is immersed in the developing solution for a predetermined time (a dip method), a method in which the developing solution is cast up on the surface of the support by surface tension and maintained for a predetermined period (a puddle method), a method in which the developing solution is sprayed onto the surface of the support (spray method), and a method in which the developing solution is continuously ejected from a developing solution ejecting nozzle while scanning at a constant rate to apply the developing solution to the support while rotating the support at a constant rate (dynamic dispense method).

As the organic solvent contained in the rinse solution used in the rinse treatment after the developing treatment in a case of a solvent developing process, any of the above-described organic solvents contained in the organic developing solution can be used which hardly dissolves the resist pattern. In general, at least one solvent selected from hydrocarbon solvents, ketone-based solvents, ester-based solvents, alcohol-based solvents, amide-based solvents and ether-based solvents is used. Among these, at least one solvent selected from hydrocarbon solvents, ketone-based solvents, ester-based solvents, alcohol-based solvents and amide-based solvents is preferable, at least one solvent selected from alcohol-based solvents and ester-based solvents is more preferable, and an alcohol-based solvent is particularly preferable.

The alcohol-based solvent used for the rinse solution is preferably a monohydric alcohol of 6 to 8 carbon atoms, and the monohydric alcohol may be linear, branched or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above-described examples or water may be mixed together. However, in consideration of the development characteristics, the amount of water in the rinse solution, based on the total amount of the rinse solution is preferably 30% by mass or less, more preferably 10% by mass or less, still more preferably 5% by mass or less, and particularly preferably 3% by mass or less.

As desired, the rinse solution may have a known additive blended. Examples of the additive include surfactants. As the surfactant, the same surfactants as those described above can be exemplified, a non-ionic surfactant is preferable, and a non-ionic fluorine-based surfactant or a non-ionic silicon-based surfactant is more preferable.

In a case where a surfactant is added, the amount thereof based on the total amount of the rinse solution is generally 0.001% to 5% by mass, preferably 0.005% to 2% by mass, and more preferably 0.01% to 0.5% by mass.

The rinse treatment using a rinse solution (washing treatment) can be conducted by a known rinse method. Examples of the method of the rinse treatment include a method in which the rinse solution is continuously applied to the support while rotating it at a constant rate (rotational coating method), a method in which the support is immersed in the rinse solution for a predetermined time (dip method), and a method in which the rinse solution is sprayed onto the surface of the support (spray method).

In the method of forming a resist pattern of the present embodiment described above, because the resist composition according to the first aspect described above is used, when forming a resist pattern, it is possible to form a resist pattern having a high sensitivity and further favorable lithography characteristics (a roughness reduction performance, resolution performance, and the like).

### EXAMPLES

Hereinafter, the present invention will be described in detail based on the examples, but the present invention is not limited to these examples.

### Synthesis Examples 1 to 18: Synthesis Examples of Copolymer (A1-1) to Copolymer (A1-12) and Copolymer (A2-1) to Copolymer (A2-6)

Copolymers were synthesized by radical polymerization of the compounds shown in Table 1 using a predetermined molar ratio.

For each copolymer thus obtained, a copolymer composition ratio of the copolymer obtained by ¹³C-NMR (a ratio of each structural unit in the copolymer (a molar ratio)), a weight-average molecular weight (Mw) in the viewpoint of standard polystyrene obtained by GPC measurement, and a molecular weight dispersity (Mw/Mn) are collectively shown in Table 1.

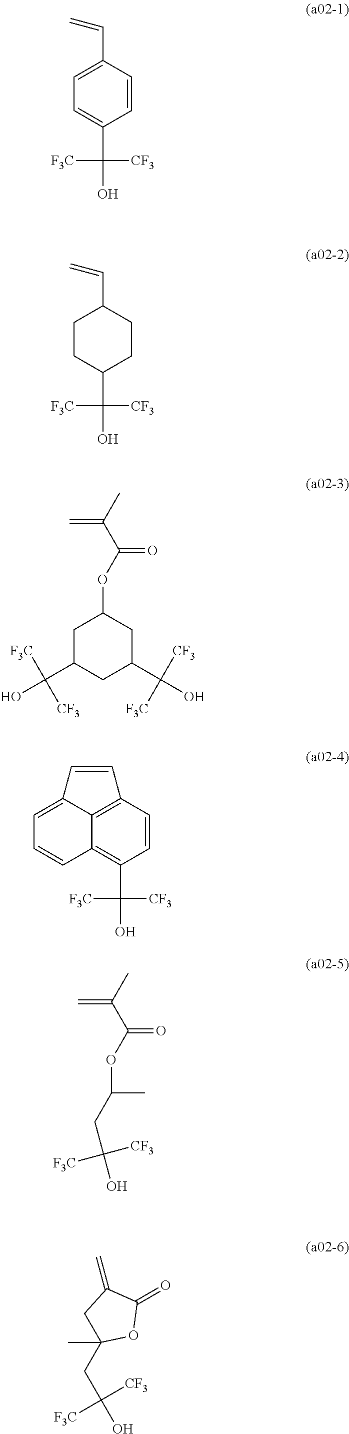

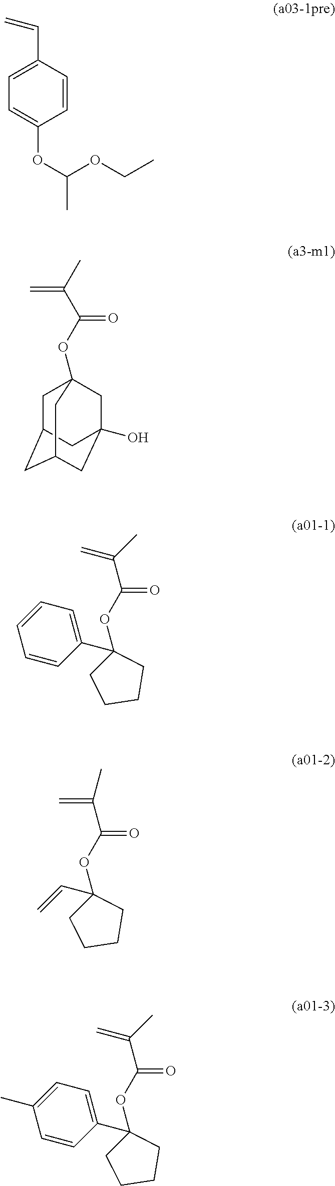

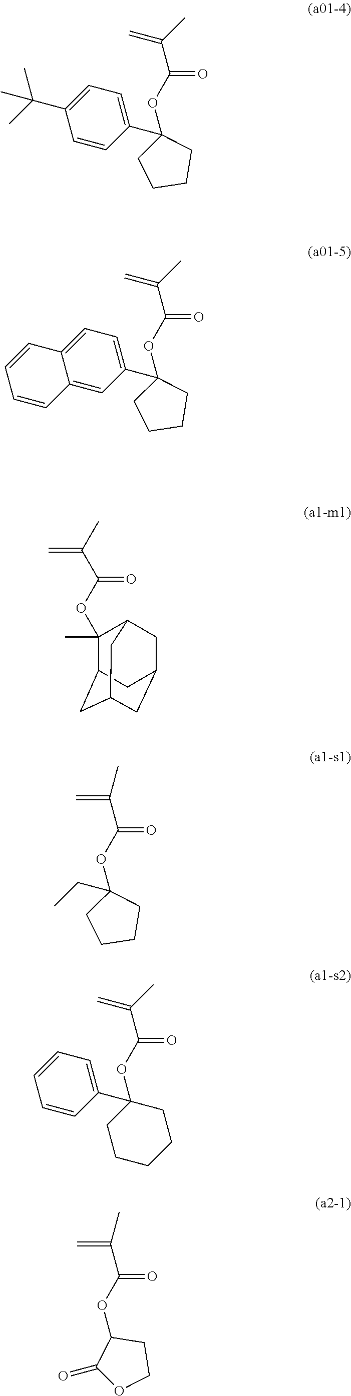

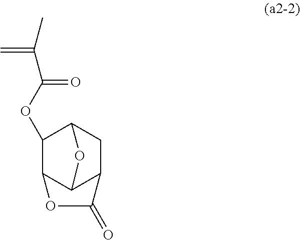

The copolymers (A1-1) to (A1-12) and copolymers (A2-1) to (A2-6) obtained by the above synthesis examples are shown below.

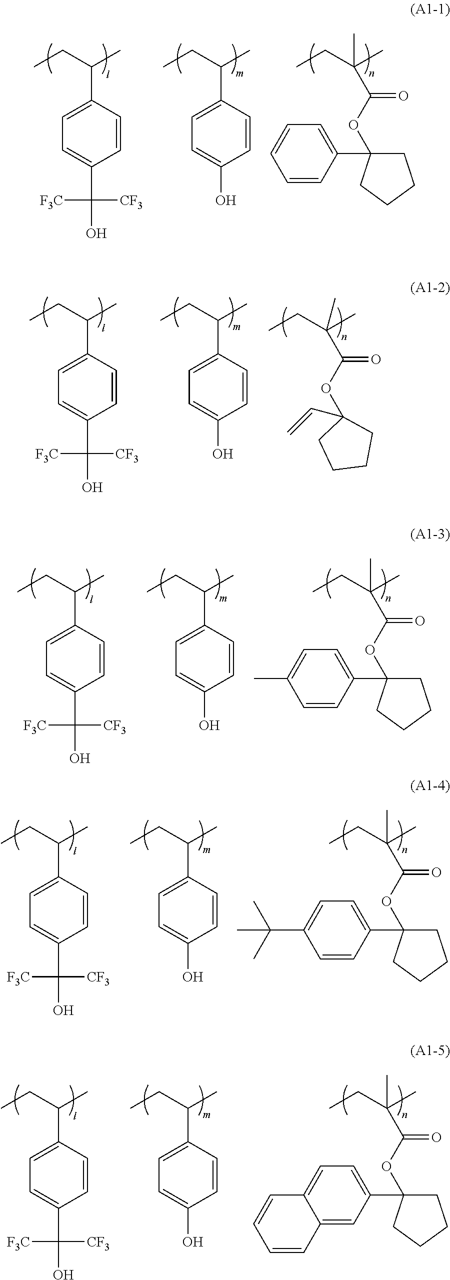

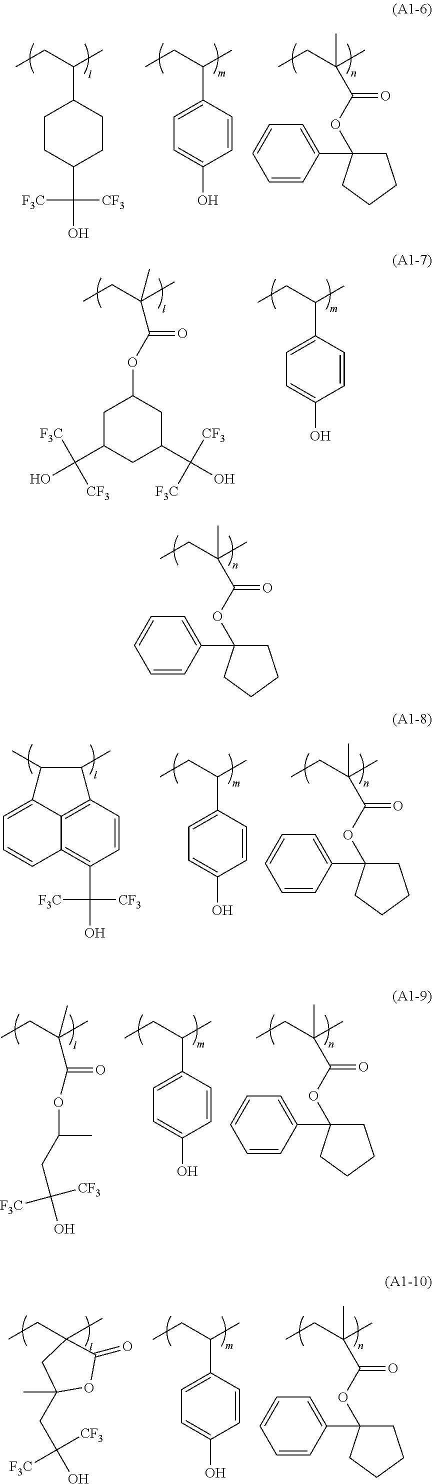

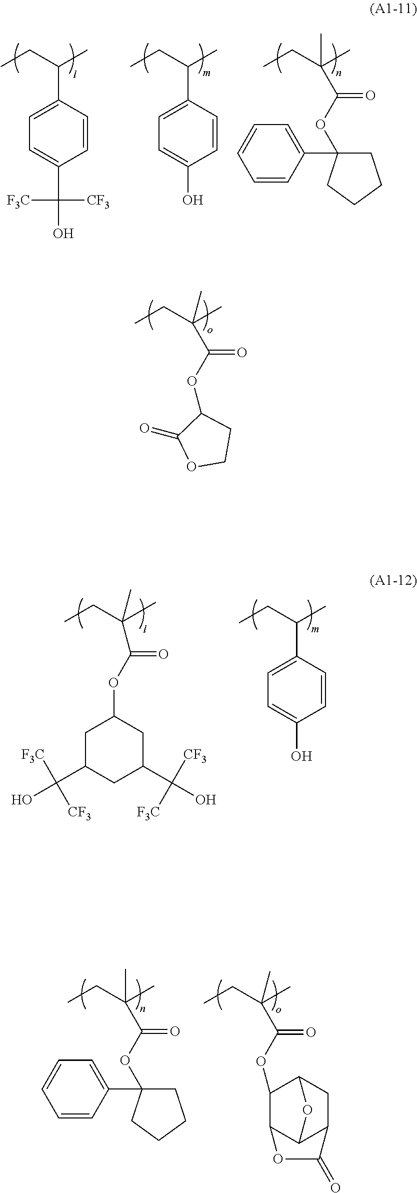

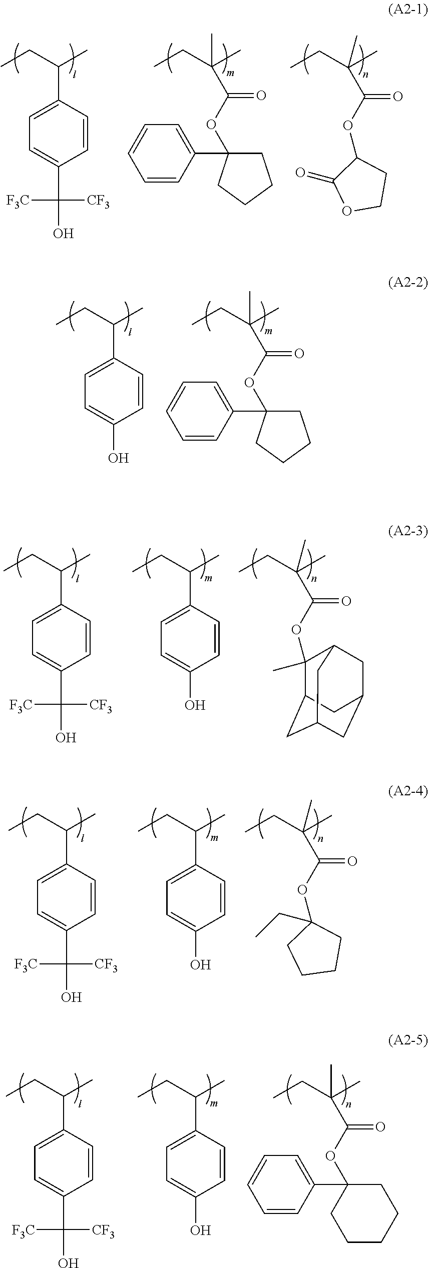

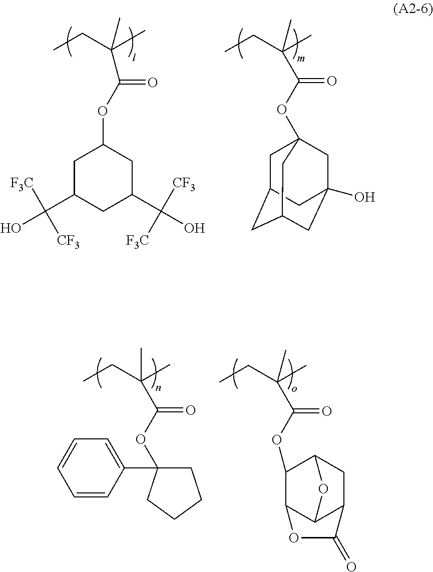

The structural unit which is represented by Chemical Formula (a03-1) and constitutes the above-mentioned copolymer is a structural unit derived from a monomer represented by Chemical Formula (a03-1pre).

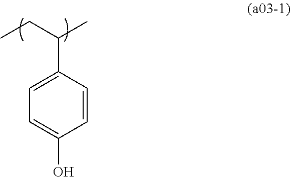

TABLE 1

| | | Copolymer composition | Weight-average | Molecular |
|---|---|---|---|---|
| | | ratio of copolymer | molecular weight | weight dispersity |
| | Copolymer | (molar ratio) | (Mw) | (Mw/Mn) |
| Synthesis example 1 | (A1-1) | (a02-1)/(a03-1)/(a01-1) = 10/40/50 | 7,000 | 1.6 |
| Synthesis example 2 | (A1-2) | (a02-1)/(a03-1)/(a01-2) = 10/40/50 | 7,000 | 1.6 |
| Synthesis example 3 | (A1-3) | (a02-1)/(a03-1)/(a01-3) = 10/40/50 | 7,000 | 1.6 |
| Synthesis example 4 | (A1-4) | (a02-1)/(a03-1)/(a01-4) = 10/40/50 | 7,000 | 1.6 |
| Synthesis example 5 | (A1-5) | (a02-1)/(a03-1)/(a01-5) = 10/40/50 | 7,000 | 1.6 |
| Synthesis example 6 | (A1-6) | (a02-2)/(a03-1)/(a01-1) = 10/40/50 | 7,000 | 1.6 |
| Synthesis example 7 | (A1-7) | (a02-3)/(a03-1)/(a01-1) = 10/40/50 | 7,000 | 1.6 |
| Synthesis example 8 | (A1-8) | (a02-4)/(a03-1)/(a01-1) = 10/40/50 | 7,000 | 1.6 |
| Synthesis example 9 | (A1-9) | (a02-5)/(a03-1)/(a01-1) = 10/40/50 | 7,000 | 1.6 |
| Synthesis example 10 | (A1-10) | (a02-6)/(a03-1)/(a01-1) = 10/40/50 | 7,000 | 1.6 |
| Synthesis example 11 | (A1-11) | (a02-1)/(a03-1)/(a01-1)/(a2-1) = 10/20/50/20 | 7,000 | 1.6 |
| Synthesis example 12 | (A1-12) | (a02-3)/(a03-1)/(a01-1)/(a2-2) = 10/20/50/20 | 7,000 | 1.6 |
| Synthesis example 13 | (A2-1) | (a02-1)/(a01-1)/(a2-1) = 10/50/40 | 7,000 | 1.6 |
| Synthesis example 14 | (A2-2) | (a03-1)/(a01-1) = 50/50 | 7,000 | 1.6 |
| Synthesis example 15 | (A2-3) | (a02-1)/(a03-1)/(a1-m1) = 10/40/50 | 7,000 | 1.6 |
| Synthesis example 16 | (A2-4) | (a02-1)/(a03-1)/(a1-s1) = 10/40/50 | 7,000 | 1.6 |
| Synthesis example 17 | (A2-5) | (a02-1)/(a03-1)/(a1-s2) = 10/40/50 | 7,000 | 1.6 |
| Synthesis example 18 | (A2-6) | (a02-3)/(a3-m1)/(a01-1)/(a2-2) = 10/20/50/20 | 7,000 | 1.6 |

### Preparation of Resist Composition

### Examples 1 to 12 and Comparative Examples 1 to 6

The components shown in Tables 2 and 3 were mixed and dissolved, and thereby resist compositions of respective examples were prepared.

TABLE 2

| | Component (A) | | | | |
|---|---|---|---|---|---|
| | Component (A1) | Component (A2) | Component (B) | Component (D) | Component (S) |
| Example 1 | (A1)-1 | — | (B)-1 | (D)-1 | (S)-1 |
| | [100] | | [14.0] | [5.0] | [6881] |
| Example 2 | (A1)-2 | — | (B)-1 | (D)-1 | (S)-1 |
| | [100] | | [14.0] | [5.0] | [6881] |
| Example 3 | (A1)-3 | — | (B)-1 | (D)-1 | (S)-1 |
| | [100] | | [14.0] | [5.0] | [6881] |
| Example 4 | (A1)-4 | — | (B)-1 | (D)-1 | (S)-1 |
| | [100] | | [14.0] | [5.0] | [6881] |
| Example 5 | (A1)-5 | — | (B)-1 | (D)-1 | (S)-1 |
| | [100] | | [14.0] | [5.0] | [6881] |
| Example 6 | (A1)-6 | — | (B)-1 | (D)-1 | (S)-1 |
| | [100] | | [14.0] | [5.0] | [6881] |
| Example 7 | (A1)-7 | — | (B)-1 | (D)-1 | (S)-1 |
| | [100] | | [14.0] | [5.0] | [6881] |
| Example 8 | (A1)-8 | — | (B)-1 | (D)-1 | (S)-1 |
| | [100] | | [14.0] | [5.0] | [6881] |
| Example 9 | (A1)-9 | — | (B)-1 | (D)-1 | (S)-1 |
| | [100] | | [14.0] | [5.0] | [6881] |
| Example 10 | (A1)-10 | — | (B)-1 | (D)-1 | (S)-1 |
| | [100] | | [14.0] | [5.0] | [6881] |
| Example 11 | (A1)-11 | — | (B)-1 | (D)-1 | (S)-1 |
| | [100] | | [14.0] | [5.0] | [6881] |
| Example 12 | (A1)-12 | — | (B)-1 | (D)-1 | (S)-1 |
| | [100] | | [14.0] | [5.0] | [6881] |

TABLE 3

| | Component (A) | | | | |
|---|---|---|---|---|---|
| | Component (A1) | Component (A2) | Component (B) | Component (D) | Component (S) |
| Comparative | — | (A2)-1 | (B)-1 | (D)-1 | (s)-1 |
| Example 1 | | [100] | [14.0] | [5.0] | [6881] |
| Comparative | — | (A2)-2 | (B)-1 | (D)-1 | (S)-1 |
| Example 2 | | [100] | [14.0] | [5.0] | [6881] |
| Comparative | — | (A2)-3 | (B)-1 | (D)-1 | (S)-1 |
| Example 3 | | [100] | [14.0] | [5.0] | [6881] |
| Comparative | — | (A2)-4 | (B)-1 | (D)-1 | (S)-1 |
| Example 4 | | [100] | [14.0] | [5.0] | [6881] |
| Comparative | — | (A2)-5 | (B)-1 | (D)-1 | (S)-1 |
| Example 5 | | [100] | [14.0] | [5.0] | [6881] |
| Comparative | — | (A2)-6 | (B)-1 | (D)-1 | (S)-1 |
| Example 6 | | [100] | [14.0] | [5.0] | [6881] |

In Tables 2 and 3, each abbreviation has the following meaning. The numerical values in the parentheses are blending amounts (parts by mass).

(A1)-1 to (A1)-12: The above-mentioned copolymers (A1-1) to (A1-12).

(A2)-1 to (A2)-6: The above-mentioned copolymers (A2-1) to (A2-6).

(B)-1: An acid generator composed of a compound represented by Chemical Formula (B-1).

(D)-1: An acid diffusion control agent composed of a compound represented by Chemical Formula (D-1).

(S)-1: A mixed solvent of propylene glycol monomethyl ether acetate/propylene glycol monomethyl ether=6/4 (mass ratio).

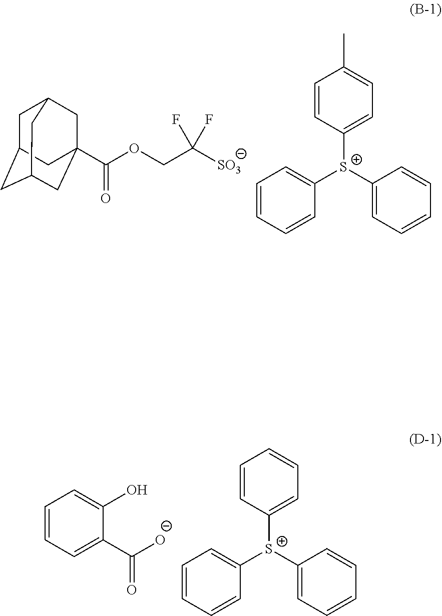

<Formation of Resist Pattern>

An 8-inch silicon substrate treated with hexamethyldisilazane (HMDS) was coated with each of the resist compositions of each of the examples using a spinner, subjected to pre-baked (PAB) treatment on a hot plate at a temperature of 110° C. for 60 seconds, and dried, and thereby a resist film having a thickness of 50 nm was formed.

Next, using an electron beam lithography device, JEOL-JBX-9300FS (manufactured by JEOL Ltd.), lithography (exposure) was performed on the resist film to make a target size a 1:1 line and space pattern with a line width of 50 nm (hereinafter, the “LS pattern”) at an acceleration voltage of 100 kV. Thereafter, post exposure bake (PEB) treatment was performed at 110° C. for 60 seconds.

Next, at 23° C., an aqueous solution of 2.38 mass % tetramethylammonium hydroxide (TMAH), “NMD-3” (trade name, manufactured by TOKYO OHKA KOGYO CO., LTD.) was used to perform alkali development for 60 seconds.

Thereafter, water rinsing was performed for 15 seconds using pure water.

As a result, a 1:1 LS pattern with a line width of 50 nm was formed.

[Evaluation of Optimum Exposure Amount (Eop)]

An optimum exposure amount Eop (μC/cm²) at which the LS pattern of the target size is formed by the above-described <Formation of resist pattern> was obtained. This is shown in Tables 4 and 5 as “Eop (μC/cm²).”

[Evaluation of Resolution Performance]

A limit resolution in the Eop, specifically, the minimum dimension of the pattern that could be resolved without being diminished when forming an LS pattern by gradually increasing an exposure amount from an optimum exposure amount Eop was obtained using a scanning electron microscope, S-9380 (manufactured by Hitachi High-Technologies Corporation). This is shown in Tables 4 and 5 as “Resolution performance (nm).”

[Evaluation of Line Width Roughness (LWR)]

With respect to the LS pattern formed in the above-described <Formation of resist pattern>, 3σ, which is a measure indicating LWR, was obtained. This is shown in Tables 4 and 5 as “LWR (nm).”

Regarding “3σ,” using a scanning electron microscope (an acceleration voltage 800V, trade name: S-9380, manufactured by Hitachi High-Technologies Corporation), 400 line positions in a longitudinal direction of the line were measured, and a triple value (3σ) (unit: nm) of the standard deviation (σ) obtained from the measurement results is shown.

This means that as a value of 3σ becomes smaller, roughness of a line side wall becomes smaller, and thereby a LS pattern with a more uniform width could be obtained.

TABLE 4

| | PAB | PEB | Eop | Resolution | LWR |
|---|---|---|---|---|---|
| | (° C.) | (° C.) | [μC/cm²] | [nm] | [nm] |
| Example 1 | 110 | 110 | 69 | 30 | 5.6 |
| Example 2 | 110 | 110 | 71 | 32 | 5.1 |
| Example 3 | 110 | 110 | 66 | 30 | 5.8 |
| Example 4 | 110 | 110 | 64 | 35 | 5.9 |
| Example 5 | 110 | 110 | 60 | 32 | 5.9 |
| Example 6 | 110 | 110 | 71 | 30 | 5.6 |
| Example 7 | 110 | 110 | 68 | 30 | 5.6 |
| Example 8 | 110 | 110 | 69 | 30 | 5.6 |
| Example 9 | 110 | 110 | 69 | 32 | 6.0 |
| Example 10 | 110 | 110 | 70 | 30 | 5.6 |
| Example 11 | 110 | 110 | 80 | 30 | 6.0 |
| Example 12 | 110 | 110 | 79 | 30 | 6.9 |

TABLE 5

| | PAB | PEB | Eop | Resolution | LWR |
|---|---|---|---|---|---|
| | (° C.) | (° C.) | [μC/cm²] | [nm] | [nm] |
| Comparative | 110 | 110 | 93 | 35 | 6.8 |
| Example 1 | | | | | |
| Comparative | 110 | 110 | 63 | 35 | 8.5 |
| Example 2 | | | | | |
| Comparative | 110 | 110 | 90 | 50 | 8.9 |
| Example 3 | | | | | |
| Comparative | 110 | 110 | 81 | 50 | 7.0 |
| Example 4 | | | | | |
| Comparative | 110 | 110 | 75 | 35 | 6.9 |
| Example 5 | | | | | |
| Comparative | 110 | 110 | 103 | 40 | 7.4 |
| Example 6 | | | | | |

Based on the results shown in Tables 4 and 5, it could be confirmed that, according to the resist compositions of the examples, it is possible to form a resist pattern having an excellent sensitivity, roughness reduction performance, and resolution performance in the formation of the resist pattern.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition which generates an acid upon exposure and changes solubility thereof in a developing solution due to an action of the acid, the resist composition comprising:
a resin component (A1) that changes solubility thereof in the developing solution by the action of the acid,
wherein the resin component (A1) has a structural unit (a01) derived from a compound represented by General Formula (a0-1), in which a polymerizable group at a W¹ moiety is converted into a main chain; a structural unit (a02) obtained from a compound represented by General Formula (a0-2), in which a polymerizable group at a W² moiety is converted into a main chain; and a structural unit (a03) derived from a compound represented by General Formula (a0-3), in which a polymerizable group at a W³ moiety is converted into a main chain: 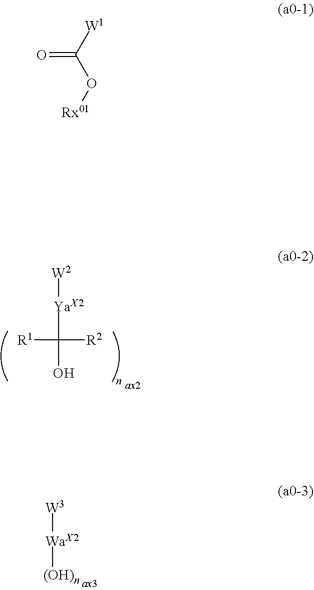
wherein in Formula (a0-1), W¹ is a polymerizable-group-containing group, and Rx⁰¹ is an acid dissociable group represented by General Formula (a01-r-1) or General Formula (a01-r-2); in Formula (a0-2), W² is a polymerizable-group-containing group, Ya^{x2} is a single bond or an (nₐₓ₂+1)-valent linking group, Ya^{x2} and W² may form a fused ring, R¹ is a fluorinated alkyl group having 1 to 12 carbon atoms, R² is a hydrogen atom or an organic group having 1 to 12 carbon atoms which may have a fluorine atom, and nₐₓ₂ is an integer of 1 to 3; and in Formula (a0-3), W³ is a polymerizable-group-containing group, Wa^{x3} is an (nₐₓ₃+1)-valent aromatic hydrocarbon group which may have a substituent, Wa^{x3} and W³ may form a fused ring, and nₐₓ₃ is an integer of 1 to 3, 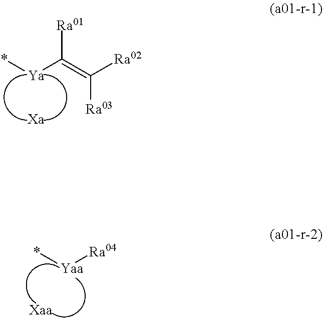
wherein in Formula (a01-r-1), Ya represents a carbon atom, Xa is a group that forms an aliphatic cyclic group together with Ya, some or all of hydrogen atoms included in the aliphatic cyclic group may be substituted, where the aliphatic cyclic group to be formed by Xa and Ya is an aliphatic monocyclic group having 3 to 5 carbon atoms, Ra⁰¹ to Ra⁰³ each independently represent a hydrogen atom, a chain-like monovalent saturated hydrocarbon group having 1 to 10 carbon atoms, or a monovalent aliphatic cyclic saturated hydrocarbon group having 3 to 20 carbon atoms, some or all hydrogen atoms in the chain-like saturated hydrocarbon group and the aliphatic cyclic saturated hydrocarbon group may be substituted, and two or more of Ra⁰¹ to Ra⁰³ may be bonded to one another to form an aliphatic cyclic structure; and in Formula (a01-r-2), Yaa represents a carbon atom, Xaa represents a group that forms an aliphatic cyclic group together with Yaa, some or all of hydrogen atoms included in the aliphatic cyclic group may be substituted, where the aliphatic cyclic group to be formed by Xaa and Yaa is an aliphatic monocyclic group having 3 to 5 carbon atoms, Ra⁰⁴ represents an aromatic hydrocarbon group which may have a substituent, and the symbol “*” represents a bonding site.

2. The resist composition according to claim 1, wherein the structural unit (a02) is a structural unit (a021) derived from a compound represented by General Formula (a0-2-1), in which a polymerizable group at a W² moiety is converted into a main chain, 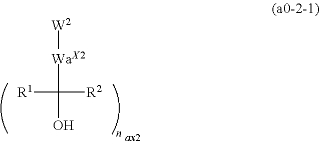
wherein W² is a polymerizable-group-containing group, Wa^{x2} is an (nₐₓ₂+1)-valent cyclic group, W² and Wa^{x2} may form a fused ring, R¹ is a fluorinated alkyl group having 1 to 12 carbon atoms, R² is a hydrogen atom or an organic group having 1 to 12 carbon atoms which may have a fluorine atom, and nₐₓ₂ is an integer of 1 to 3.

3. The resist composition according to claim 1, wherein each of R¹ and R² represents a trifluoromethyl group.

4. A method of forming a resist pattern, comprising:
forming a resist film on a support using the resist composition according to claim 1;
exposing the resist film; and
developing the exposed resist film to form a resist pattern.

5. The method of forming a resist pattern according to claim 4, wherein the resist film is exposed with extreme ultraviolet (EUV) rays or electron beam (EB).
